(19) United States
(12) Patent Application Publication
(10) Pub. No.: US 2025/0116926 A1
(43) Pub. Date: Apr. 10, 2025

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Takayuki Fujiwara, Joetsu-shi (JP)

(73) Assignee: Shin-Etsu Chemical Co., Ltd., Tokyo (JP)

(21) Appl. No.: 18/904,577

(22) Filed: Oct. 2, 2024

(30) Foreign Application Priority Data
Oct. 10, 2023 (JP) 2023-175361

(51) Int. Cl. G03F 7/004; G03F 7/038; G03F 7/039; G03F 7/20

(52) U.S. Cl. CPC G03F 7/0045; G03F 7/0048; G03F 7/0382; G03F 7/0397; G03F 7/2006

(57) ABSTRACT

A resist composition comprising a bisonium salt containing a divalent anion having a sulfonate anion structure having a fluorine atom or a trifluoromethyl group at the position a or β and linked to an aromatic group having an iodine atom or a bromine atom and a carboxylate anion structure bonded to the aromatic group having an iodine atom or a bromine atom, via a linking group having 1 or more carbon atoms, and an onium cation.

### CROSS-REFERENCE TO RELATED APPLICATIONS

This non-provisional application claims priority under 35 U.S.C. § 119 (a) on Patent Application No. 2023-175361 filed in Japan on Oct. 10, 2023, the entire contents of which are hereby incorporated by reference.

### TECHNICAL FIELD

This invention relates to a resist composition and a patterning process using the composition.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation. IMEC in Belgium announced its successful development of 1-nm and 0.7-nm node devices.

As the feature size reduces, image blurs due to acid diffusion become a problem. To insure resolution for fine patterns with a processed size of 45 nm or less, not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

The EUV lithography resist composition must meet high sensitivity, high resolution and low LWR at the same time. As the acid diffusion distance is reduced, line width roughness (LWR) and critical dimension uniformity (CDU) of hole patterns are improved, but sensitivity becomes lower. For example, as the PEB temperature is lowered, the outcome is improved LWR and CDU, but a lower sensitivity. As the amount of quencher added is increased, the outcome is improved LWR and CDU, but a lower sensitivity. It is necessary to overcome the tradeoff relation between sensitivity and LWR.

Patent Documents 1 to 4 disclose a resist composition comprising an onium salt acid generator having an anion having an iodine atom or a bromine atom. The inclusion of iodine atoms that absorb a large amount of EUV or bromine atoms that are efficiently ionized improves the efficiency of decomposition of the acid generator during exposure, resulting in a higher sensitivity. The mount of absorption of photons increases, so that the physical contrast can be enhanced.

According to Non-Patent Document 2, EUV light, whose wavelength is 13.5 nm and an order of magnitude smaller than that of ArF excimer laser light having a wavelength of 193 nm, thus has high energy and is significantly influences by variation in the number of photons. Non-Patent Document 3 indicates that this leads to degradation of LWR. In addition, Non-Patent Document 4 indicates that as the feature size reduces, LWR is degraded by variation in resist components (polymer, PAG, quencher) (resist stochastics).

Patent Document 5 discloses a resist composition comprising a polymer to which an acid generator (photoacid generator (PAG)) and a quencher (photodegradable quencher (PDQ)) are bonded. This is intended to improve LWR and CDU by integrating the polymer, PAG and the quencher to suppress variation in occurrence of these components. Further, Patent Documents 6 and 7 disclose a resist composition comprising an additive to which PAG and a quencher are bonded.

### CITATION LIST

Patent Document 1: JP-A 2018-159744
Patent Document 2: JP-A 2018-5224
Patent Document 3: JP-A 2018-25789
Patent Document 4: JP-A 2019-003175
Patent Document 5: JP-A 2022-115072
Patent Document 6: JP-A 2015-024989
Patent Document 7: WO 2020/158313
Non-Patent Document 1: SPIE Vol. 6520 65203L-1 (2007)
Non-Patent Document 2: SPIE Vol. 3331 535 (1998)
Non-Patent Document 3: SPIE Vol. 7273 727343-1 (2009)
Non-Patent Document 4: SPIE Vol. 9776 97760V-1 (2016)

### SUMMARY OF THE INVENTION

Development of a resist composition having a higher sensitivity over conventional resist compositions and being capable of improving the LWR of line patterns and the CDU of hole patterns is desired.

An object of the present invention is to provide either a positive or negative resist composition which exhibits a higher sensitivity and improved LWR and CDU, and a patterning process using the resist composition.

The inventors have found that in a resist composition comprising, as an acid generator and quencher, a bisonium salt containing a divalent anion having an arylsulfonate anion structure linked to an aromatic group having an iodine atom or a bromine atom and a carboxylate anion structure bonded to the aromatic group having an iodine atom or a bromine atom, via a linking group having 1 or more carbon atoms, and an onium cation, the acid generator is directly excited by exposure to radiation, and the influence of diffusion of secondary electrons is eliminated. The resist composition has a high sensitivity, improved LWR and CDU, a high contrast, excellent resolution, and a wide process margin.

The resist composition is improved in LWR, CDU, and resolution, and has a wide process margin.

In one aspect, the invention provides a resist composition comprising a bisonium salt containing a divalent anion having an arylsulfonate anion structure linked to an aromatic group having an iodine atom or a bromine atom and a carboxylate anion structure bonded to the aromatic group having an iodine atom or a bromine atom, via a linking group having 1 or more carbon atoms, and an onium cation.

In a preferred embodiment, the resist composition has the formula (1).

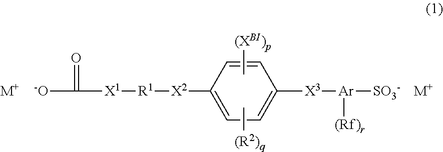

Herein, p is an integer of 1 to 4, q is an integer of 0 to 3, r is an integer of 1 to 6,
X^{BI} is a bromine atom or an iodine atom,
X¹ is a C₁-C₁₈ hydrocarbylene group, which may contain at least one selected from an oxygen atom, a nitrogen atom, a sulfur atom and a halogen atom,
X² is a single bond, an ether bond, an ester bond, a sulfonic acid ester bond, an amide bond, a urethane bond, a urea bond, or a carbonate bond or a C₁-C₆ alkanediyl group, the alkanediyl group may contain at least one selected from an ether bond and an ester bond,
X³ is a single bond, an ether bond, an ester bond, or a C₁-C₆ alkanediyl group, the alkanediyl group may contain at least one selected from an ether bond and an ester bond,
R¹ is a single bond or a C₁-C₁₂ hydrocarbylene group, the hydrocarbylene group may contain at least one selected from an oxygen atom, a nitrogen atom, a sulfur atom and a halogen atom,
with the proviso that —X¹—R¹—X²— has at least one carbon atom,
R² is a hydroxy group, a carboxy group, a fluorine atom, a chlorine atom, an amino group, a C₁-C₂₀ hydrocarbyl group, a C₁-C₂₀ hydrocarbyloxy group, a C₂-C₂₀ hydrocarbyloxycarbonyl group, a C₂-C₂₀ hydrocarbylcarbonyloxy group, —N(R^{2A})—C(═O)—R^{2B}, —N(R^{2A})—C(═O)—O—R^{2B} or —N(R^{2A})—S(═O)₂—R^{2B}, and the hydrocarbyl group, the hydrocarbyloxy group, the hydrocarbyloxycarbonyl group and the hydrocarbylcarbonyloxy group may contain at least one selected from a fluorine atom, a chlorine atom, a bromine atom, an iodine atom, a hydroxy group, an amino group, an ester bond and an ether bond, R^{2A} is a hydrogen atom, or a C₁-C₆ saturated hydrocarbyl group, the saturated hydrocarbyl group may contain a halogen atom, a hydroxy group, a C₁-C₆ saturated hydrocarbyloxy group, a C₂-C₆ saturated hydrocarbylcarbonyl group or a C₂-C₆ saturated hydrocarbylcarbonyloxy group, R^{2B} is a C₁-C₁₆ aliphatic hydrocarbyl group or a C₆-C₁₂ aryl group, which may contain a halogen atom, a hydroxy group, a C₁-C₆ saturated hydrocarbyloxy group, a C₂-C₆ saturated hydrocarbylcarbonyl group or a C₂-C₆ saturated hydrocarbylcarbonyloxy group,
Ar is a C₆-C₁₀ (r+2)-valent aromatic hydrocarbon group,
Rf is a hydrogen atom, a C₁-C₁₀ saturated hydrocarbyl group, a nitro group, a cyano group, a fluorine atom, an iodine atom, a trifluoromethyl group or a trifluoromethoxy group, and
M⁺ is a sulfonium cation or an iodonium cation.

In one embodiment, X¹ is a C₁-C₁₈ hydrocarbylene group containing an iodine atom or a bromine atom.

In one embodiment, the resist composition further comprises a base polymer.

In one embodiment, the base polymer comprises repeat units having the formula (a1) or (a2).

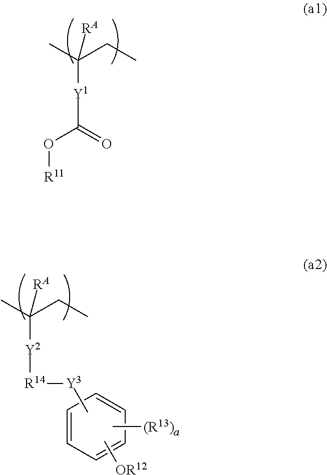

wherein R^{A} is each independently hydrogen or methyl,
Y¹ is a single bond, a phenylene group, a naphthylene group, or a C₁-C₁₂ linking group containing at least one selected from an ester bond, an ether bond and a lactone ring, the phenylene group, the naphthylene group and the linking group may have at least one selected from a hydroxy group, a C₁-C₈ saturated hydrocarbyloxy group and a C₂-C₈ saturated hydrocarbylcarbonyloxy group,
Y² is a single bond or an ester bond,
Y³ is a single bond, an ether bond or an ester bond,
R¹¹ and R¹² are each independently an acid labile group,
R¹³ is a C₁-C₄ saturated hydrocarbyl group, a halogen atom, a C₂-C₅ saturated hydrocarbylcarbonyl group, a cyano group, or C₂-C₅ saturated hydrocarbyloxycarbonyl group,
R¹⁴ is a single bond or a C₁-C₆ alkanediyl group, the alkanediyl group may contain an ether bond or an ester bond, and
a is an integer of 0 to 4.

In one embodiment, the resist composition is a chemically amplified positive resist composition.

In one embodiment, the base polymer does not contain an acid labile group.

In one embodiment, the resist composition is a chemically amplified negative resist composition.

In one embodiment, the resist composition further comprises an organic solvent.

In one embodiment, the resist composition further comprises a quencher.

In one embodiment, the resist composition further comprises an acid generator.

In one embodiment, the resist composition further comprises a surfactant.

In another aspect, the invention provides a pattern forming process comprising the steps of applying the resist composition defined herein onto a substrate to form a resist film thereon, exposing the resist film to high-energy radiation, and developing the exposed resist film in a developer.

In one embodiment, the high-energy radiation is ArF excimer laser having a wavelength 193 nm, KrF excimer laser having a wavelength 248 nm, an electron beam (EB), or EUV having a wavelength 3 to 15 nm.

### Advantageous Effects of Invention

The resist film comprising a bisonium salt containing a divalent anion having an arylsulfonate anion structure linked to an aromatic group having an iodine atom or a bromine atom and a carboxylate anion structure bonded to the aromatic group having an iodine atom or a bromine atom, via a linking group having 1 or more carbon atoms, and an onium cation absorbs a large amount of EUV light, thus is directly excited during exposure, and has reduced acid diffusion. Accordingly, a reduction of resolution due to blur by diffusion of secondary electrons and acid can be prevented. The bisonium salt, which has a configuration in which an acid generator of an onium salt that generates a sulfonic acid and a quencher of an onium salt that generates a carboxylic acid are bonded to arrange the acid generator and the quencher with a constant distance therebetween, thus is improved in the resist stochastics to enable improvement of LWR and CDU. Accordingly, a resist composition having a high sensitivity and improved LWR and CDU is constructed.

### DETAILED DESCRIPTION OF THE INVENTION

### [Resist Composition]

A resist composition of the present invention comprises a bisonium salt containing a divalent anion having an arylsulfonate anion structure linked to an aromatic group having an iodine atom or a bromine atom and a carboxylate anion structure bonded to the aromatic group having an iodine atom or a bromine atom, via a linking group having 1 or more carbon atoms, and an onium cation. The bisonium salt is an acid generator and quencher having both the functions of an acid generator and a quencher, and has reduced acid diffusion and equalized diffusion distances due to a combination of the absorption ability of iodine atoms, the ionization ability of bromine atoms, the high reactivity of fluorosulfonic acid, and the acid diffusion controlling property given by the constant presence of a quencher in the vicinity. This enables improvement of LWR and CDU.

The bisonium salt for use in the present invention exhibits the effect of improving LWR and CDU either in formation of positive patterns and negative patterns by development in an alkali aqueous solution or in formation of negative patterns by development in an organic solvent.

### [Bisonium Salt]

Preferably, the bisonium salt has the formula (1).

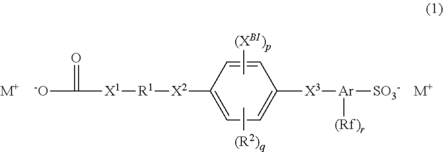

In formula (1), p is an integer of 1 to 4 and q is an integer of 0 to 3. r is an integer of 1 to 6.

In formula (1), X^{BI} is a bromine atom or an iodine atom.

In formula (1), X¹ is a C₁-C₁₈ hydrocarbylene group, which may contain at least one selected from an oxygen atom, a nitrogen atom, a sulfur atom and a halogen atom.

In formula (1), X² is a single bond, an ether bond, an ester bond, a sulfonic acid ester bond, an amide bond, a urethane bond, a urea bond, or a carbonate bond or a C₁-C₆ alkanediyl group, the alkanediyl group may contain at least one selected from an ether bond and an ester bond.

In formula (1), X³ is a single bond, an ether bond, an ester bond, or a C₁-C₆ alkanediyl group, the alkanediyl group may contain at least one selected from an ether bond and an ester bond.

In formula (1), R¹ is a single bond or a C₁-C₁₈ hydrocarbylene group, the hydrocarbylene group may contain at least one selected from an oxygen atom, a nitrogen atom, a sulfur atom and a halogen atom,
with the proviso that —X¹—R¹—X²— has at least one carbon atom.

The hydrocarbyl groups represented by X¹ and R¹ may be saturated or unsaturated and straight, branched or cyclic. Examples thereof include C₁-C₁₂ alkanediyl groups such as methanediyl, ethane-1,1-diyl, ethane-1,2-diyl, 1-methylethane-1,2-diyl, 1-ethylethane-1,2-diyl, propane-1,1-diyl, propane-1,2-diyl, propane-1,3-diyl, 2-methylpropane-1,1-diyl group, butane-1,3-diyl, butane-1,4-diyl, butane-2,3-diyl, 1,1-dimethylpropane-1,3-diyl, 2,2-dimethylpropane-1,3-diyl, pentane-1.5-diyl, hexane-1,6-diyl, heptane-1,7-diyl, octane-1,8-diyl, nonane-1,9-diyl, decane-1,10-diyl, undecane-1,11-diyl, and dodecane-1,12-diyl groups; C₃-C₁₂ cyclic saturated hydrocarbylene groups cyclopentanediyl, cyclohexanediyl, bicyclo[2.2.2]octanediyl, norbornanediyl and adamantanediyl groups; C₂-C₁₂ alkenediyl groups such as ethendiyl, propenediyl and butenediyl groups; C₂-C₁₂ alkynediyl groups such as ethynediyl, propynediyl and butynediyl groups; C₃-C₁₂ cyclic unsaturated aliphatic hydrocarbylene groups such as cyclohexanediyl, bicyclo[2.2.2]octenediyl and norbornenediyl groups; C₆-C₁₂ arylene groups such as phenylene, methylphenylene, ethylphenylene, n-propylphenylene, isopropylphenylene, n-butylphenylene, isobutylpheylene, sec-butylphenylene, isobutylphenylene, tert-butylphenylene, naphthylene, methylnaphthylene and ethylnaphthylene groups; and combinations thereof.

In formula (1), R² is a hydroxy group, a carboxy group, a fluorine atom, a chlorine atom, an amino group, a C₁-C₂₀ hydrocarbyl group, a C₁-C₂₀ hydrocarbyloxy group, a C₂-C₂₀ hydrocarbyloxycarbonyl group, a C₂-C₂₀ hydrocarbylcarbonyloxy group, —N(R^{2A})—C(═O)—R^{2B}, —N(R^{2A})—C(═O)—O—R^{2B} or —N(R^{2A})—S(═O)₂—R^{2B}, and the hydrocarbyl group, the hydrocarbyloxy group, the hydrocarbyloxycarbonyl group and the hydrocarbylcarbonyloxy group may contain at least one selected from a fluorine atom, a chlorine atom, a bromine atom, an iodine atom, a hydroxy group, an amino group, an ester bond and an ether bond. R^{2A} is a hydrogen atom, or a C₁-C₆ saturated hydrocarbyl group, the saturated hydrocarbyl group may contain a halogen atom, a hydroxy group, a C₁-C₆ saturated hydrocarbyloxy group, a C₂-C₆ saturated hydrocarbylcarbonyl group or a C₂-C₆ saturated hydrocarbylcarbonyloxy group, R^{2B} is a C₁-C₁₆ aliphatic hydrocarbyl group or a C₆-C₁₂ aryl group, which may contain a halogen atom, a hydroxy group, a C₁-C₆ saturated hydrocarbyloxy group, a C₂-C₆ saturated hydrocarbylcarbonyl group or a C₂-C₆ saturated hydrocarbylcarbonyloxy group.

In formula (1), Ar is a C₆-C₁₀ (r+2)-valent aromatic hydrocarbon group. Examples of the (r+2)-valent aromatic hydrocarbon group include groups obtained by elimination of (r+2) hydrogen atoms from an aromatic hydrocarbon such as benzene or toluene.

In formula (1), Rf is a hydrogen atom, a C₁-C₁₀ saturated hydrocarbyl group, a nitro group, a cyano group, a fluorine atom, an iodine atom, a trifluoromethyl group or a trifluoromethoxy group.

Examples of the anion in the bisonium salt are shown below, but not limited thereto.

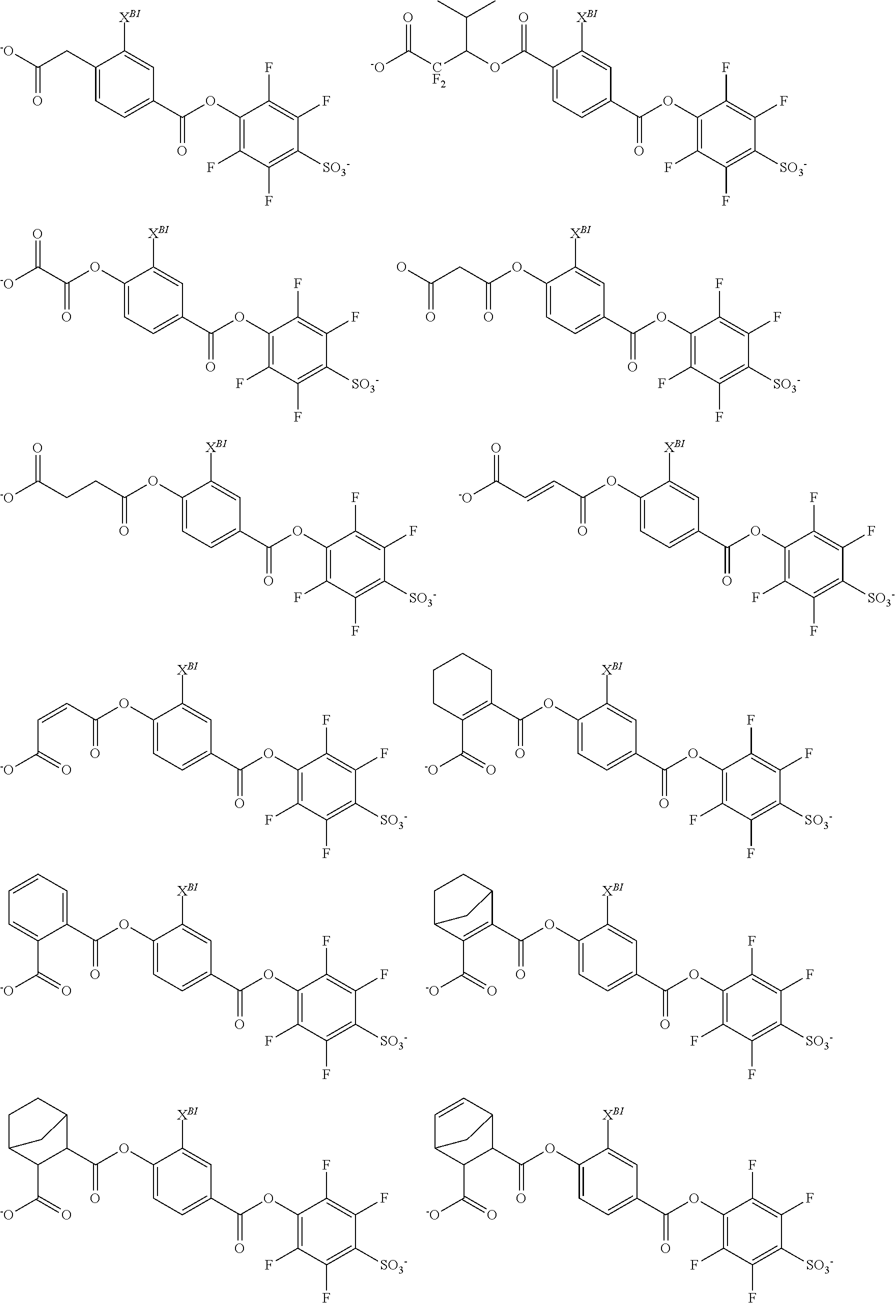

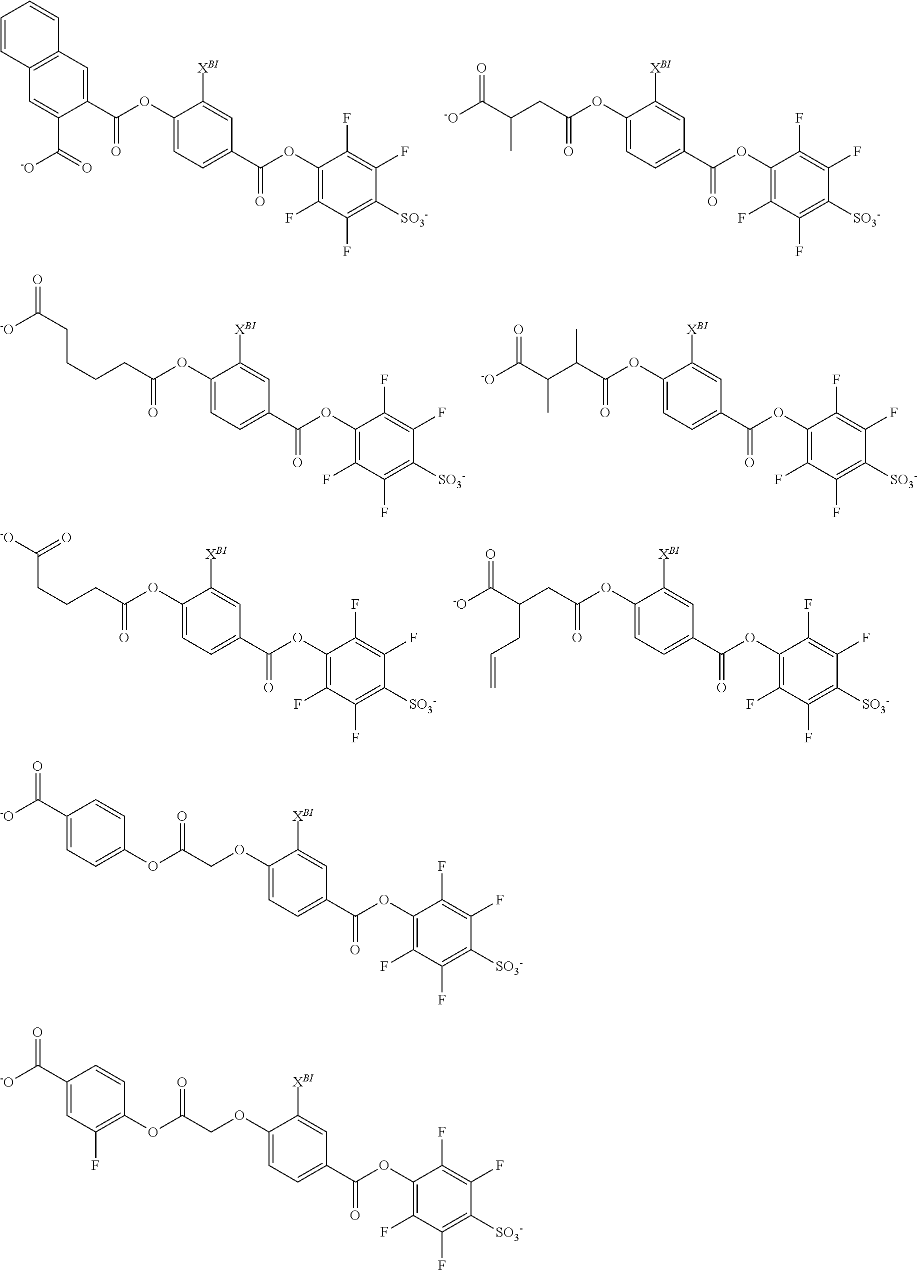

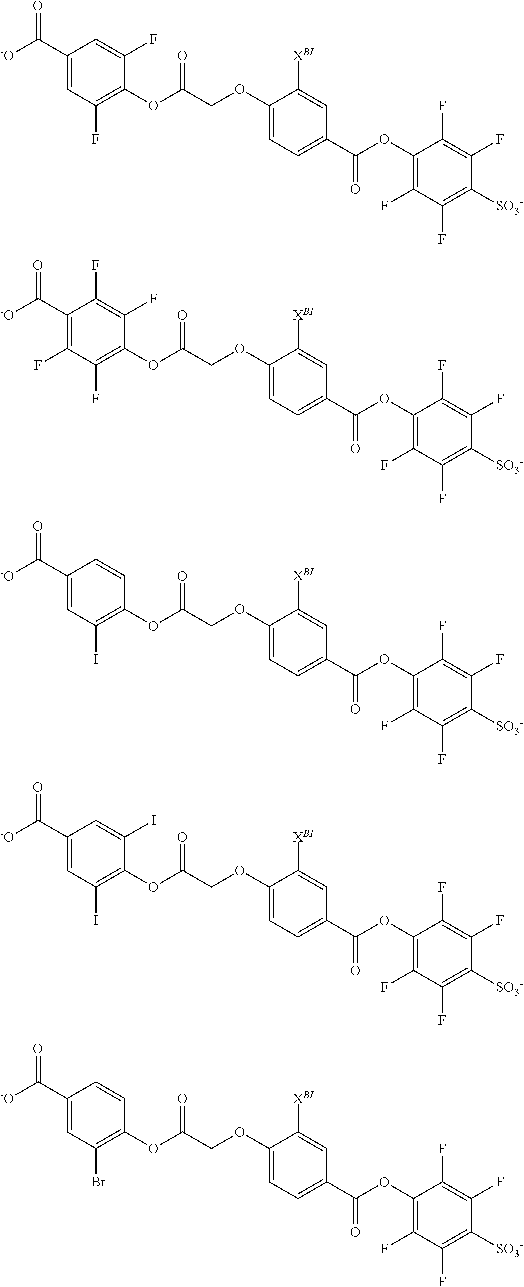

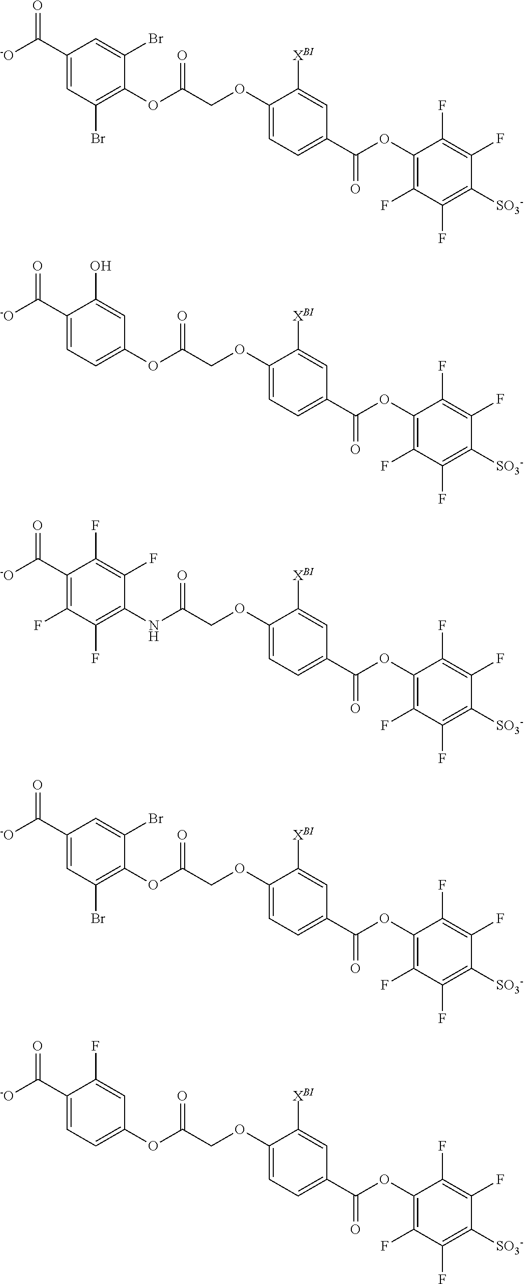

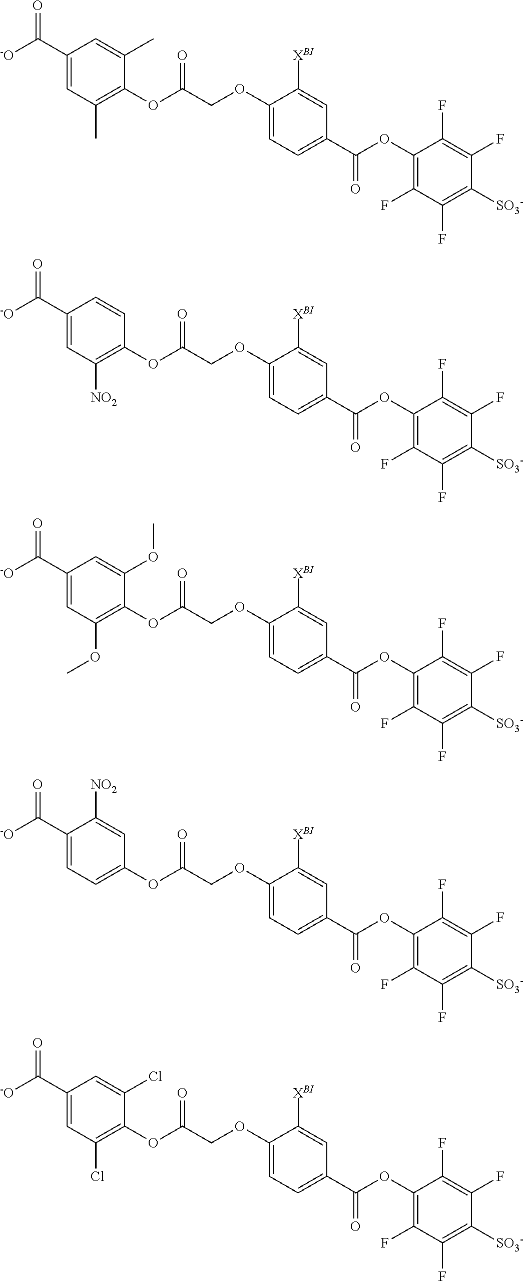

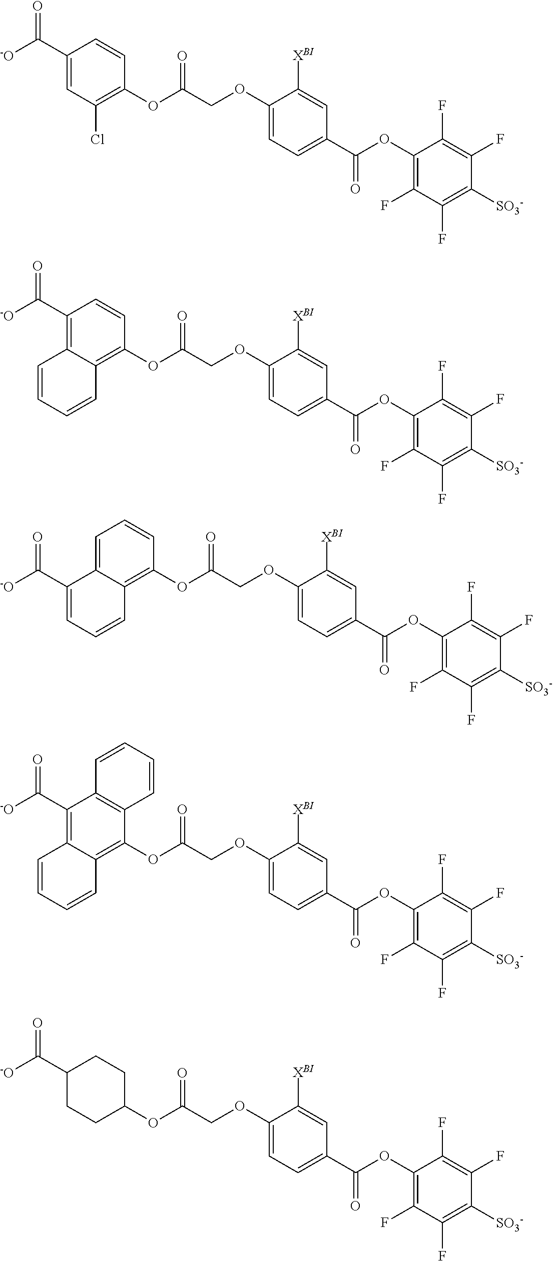

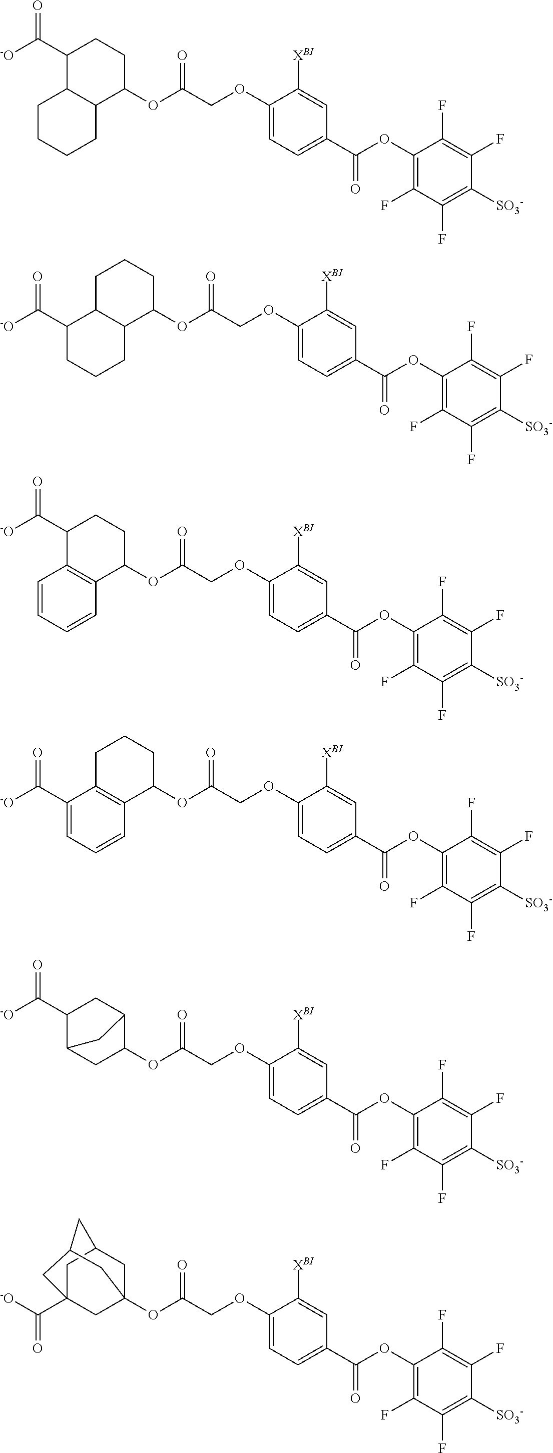

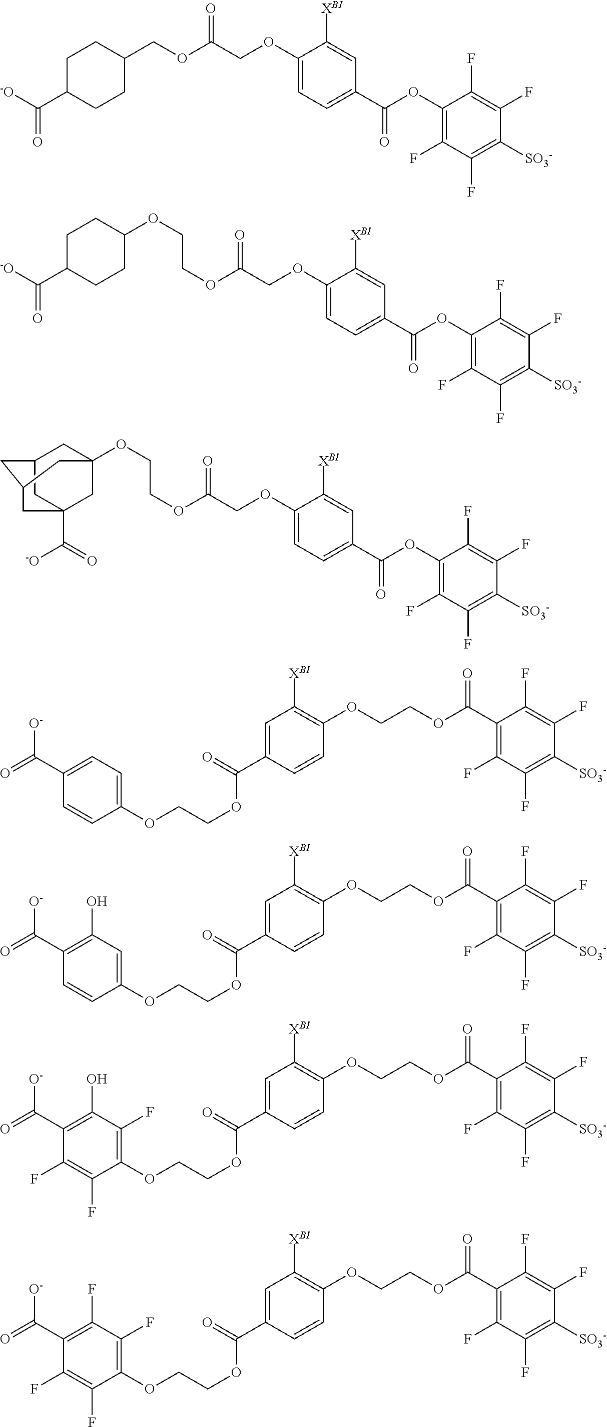

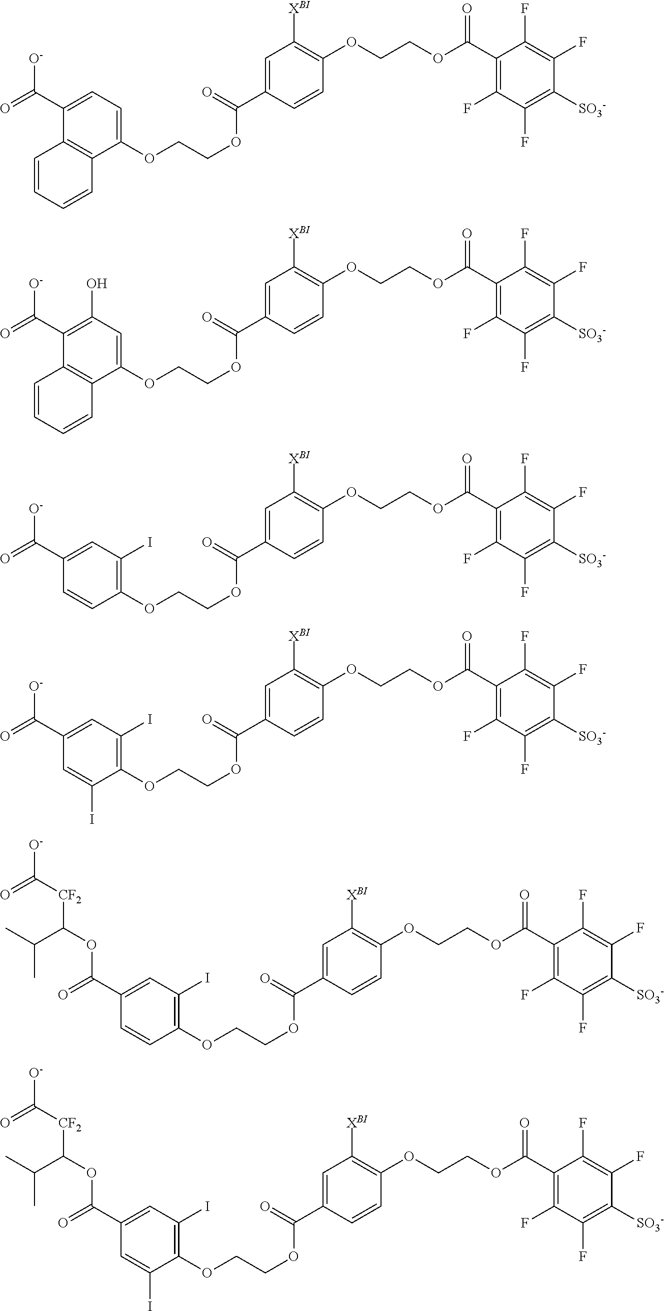

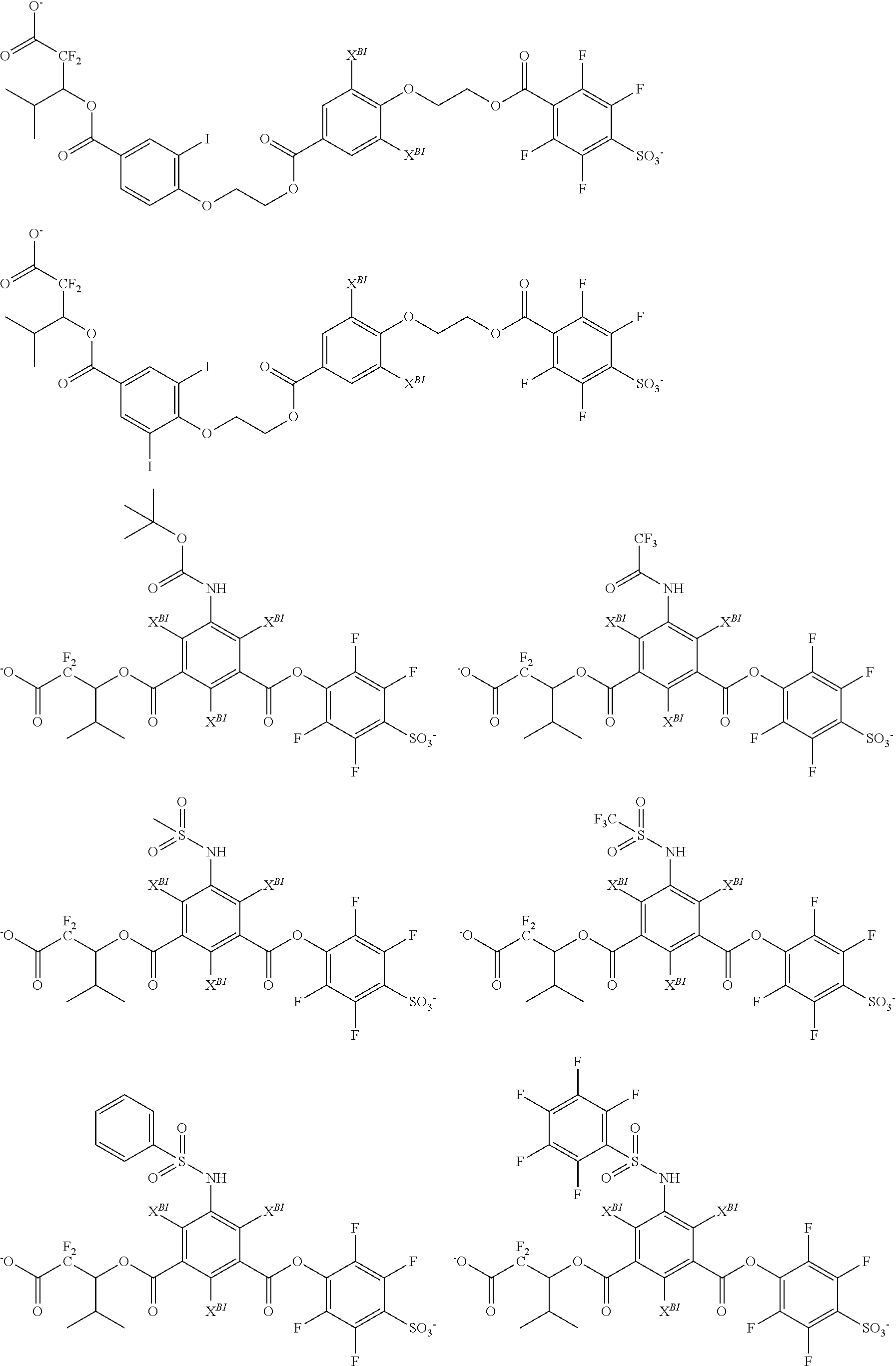

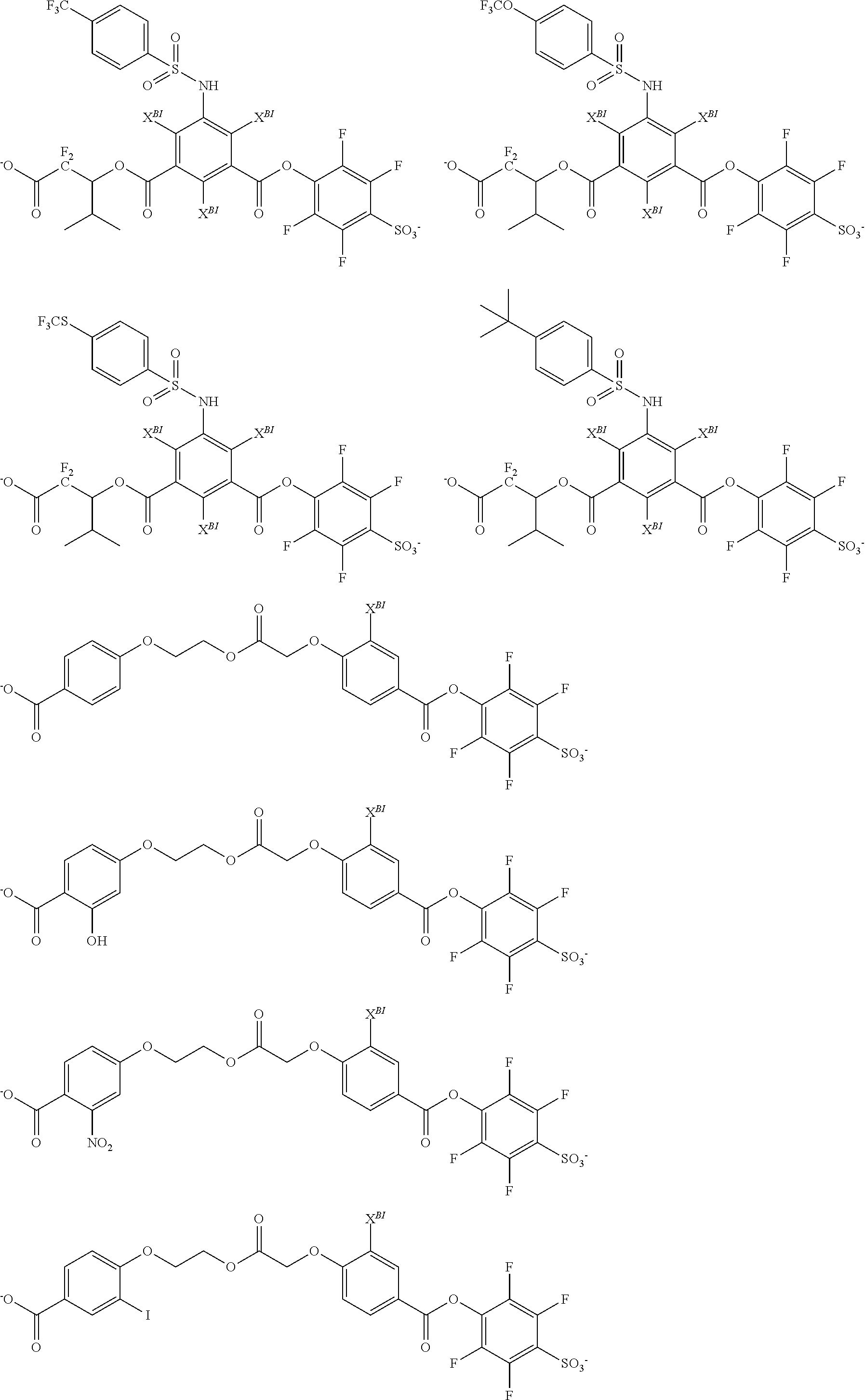

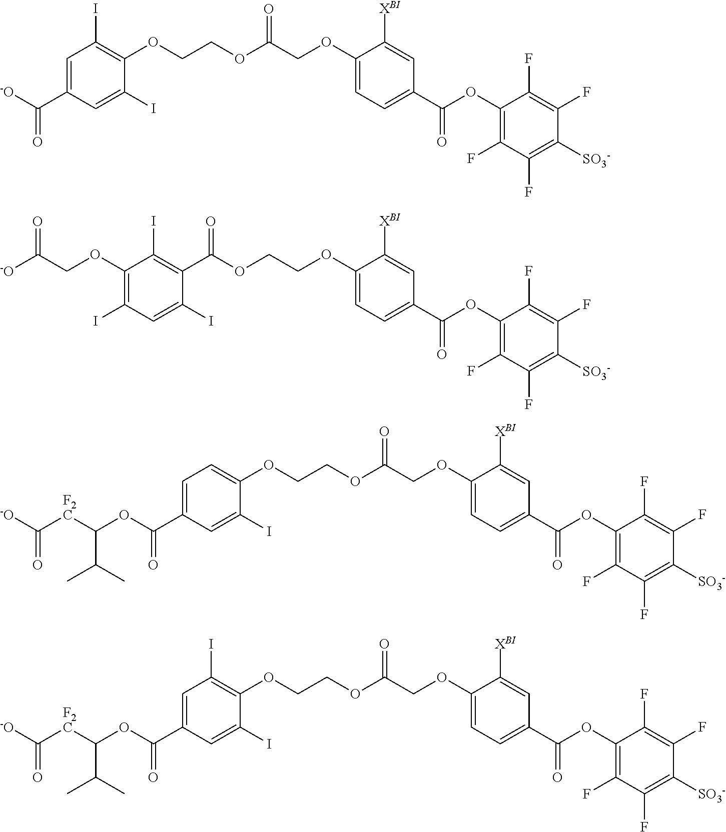

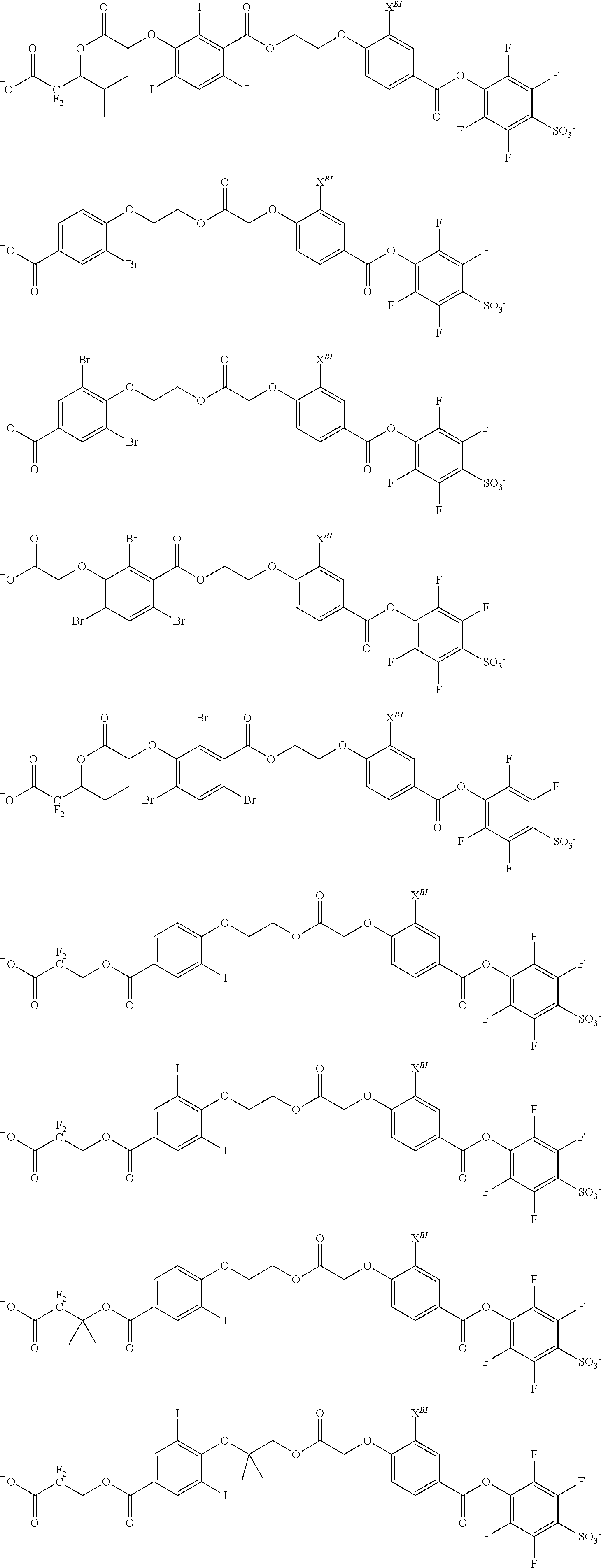

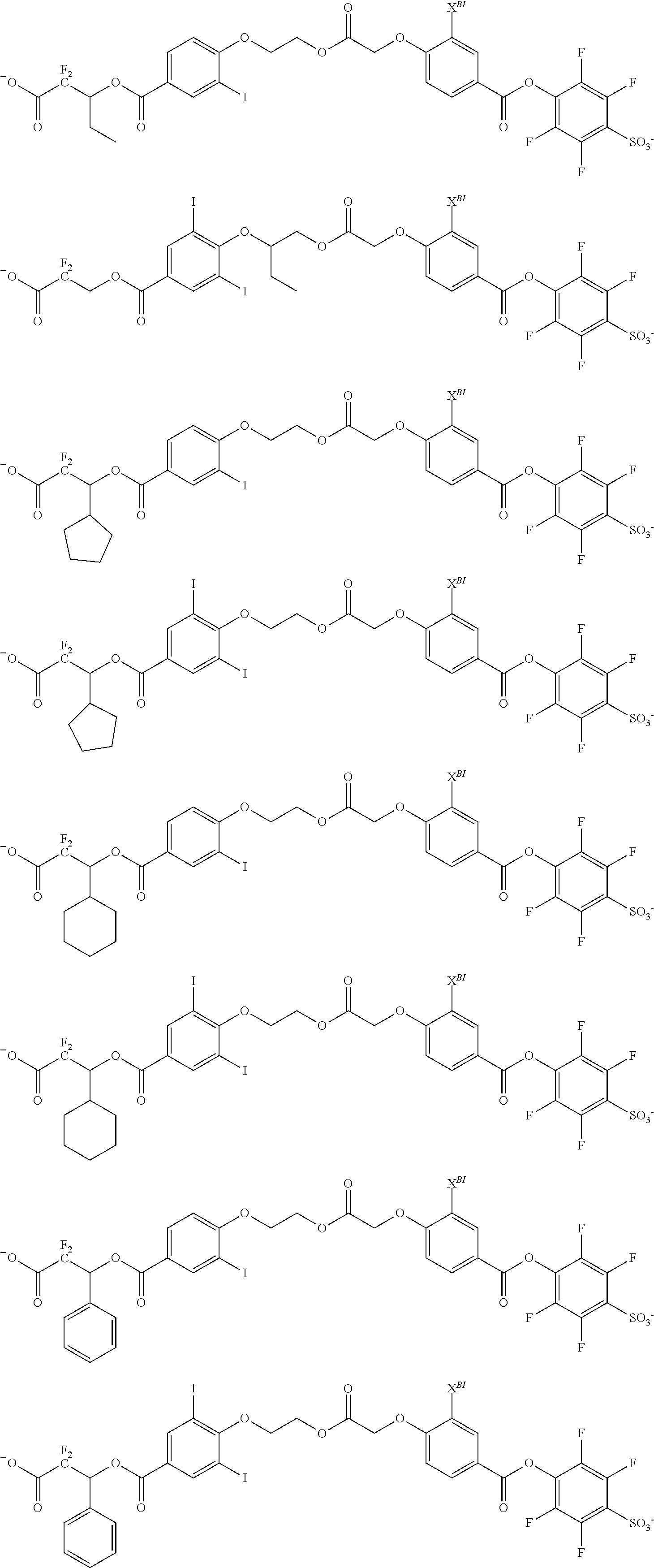

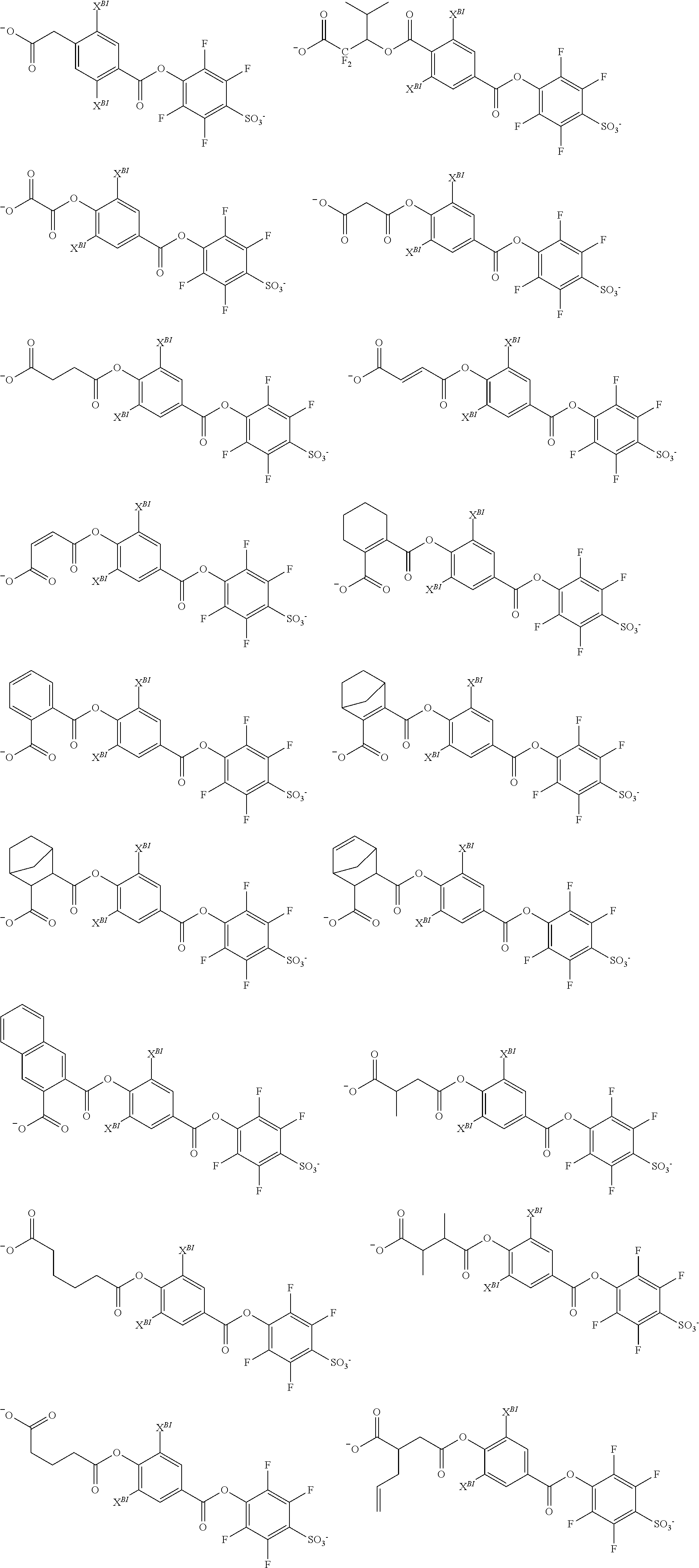

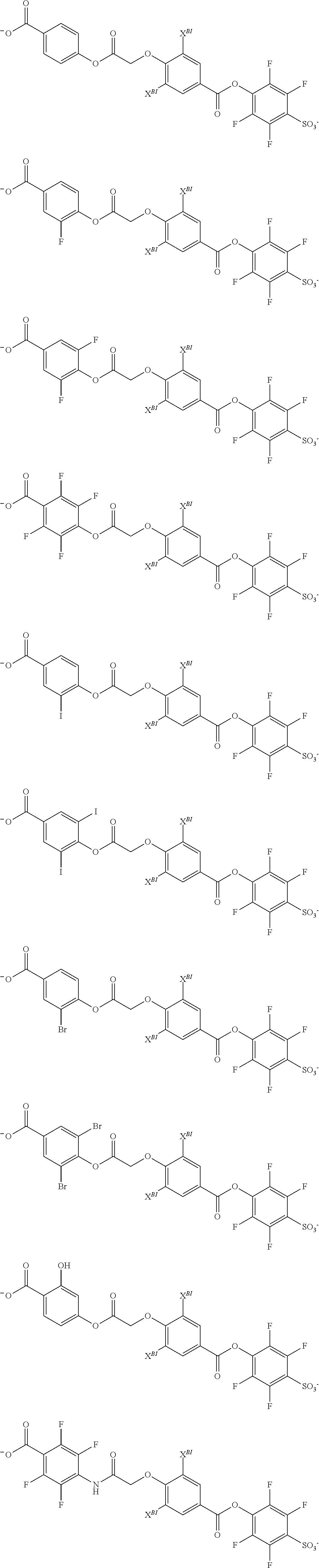

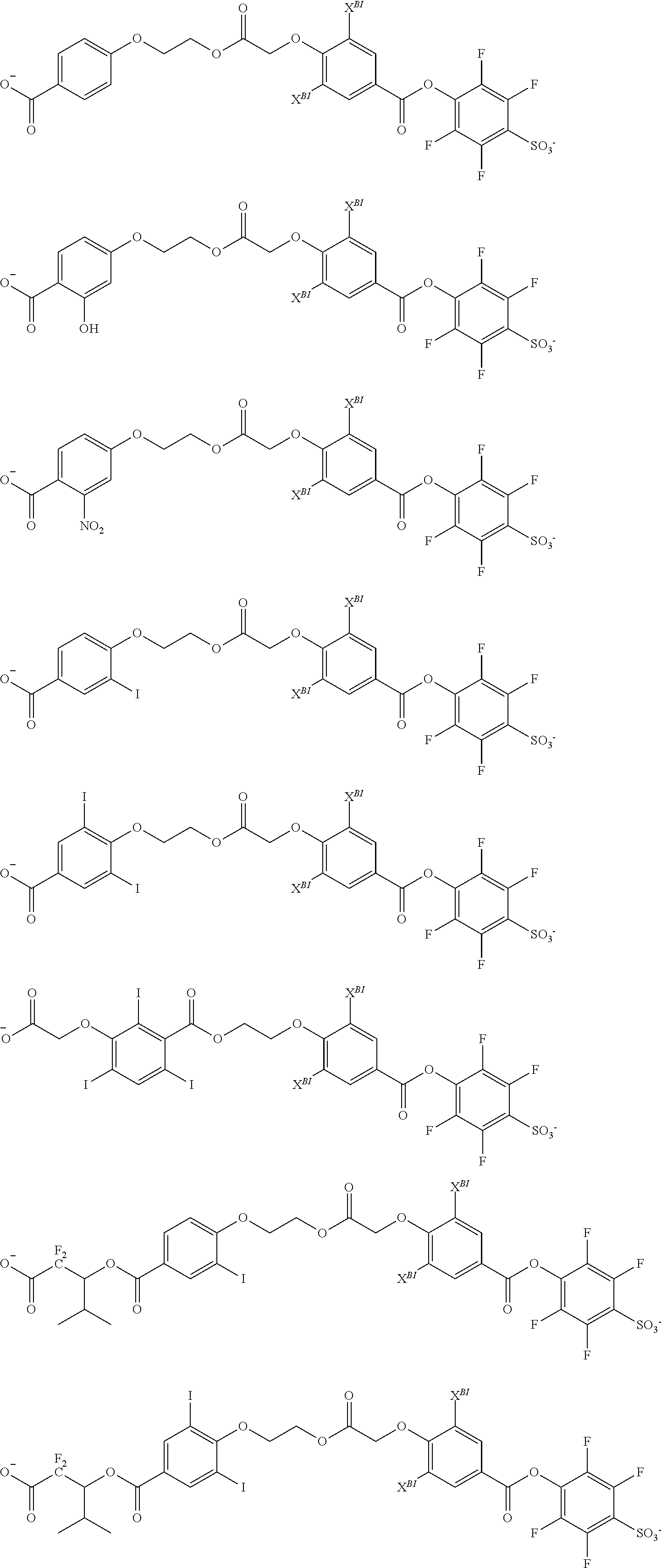

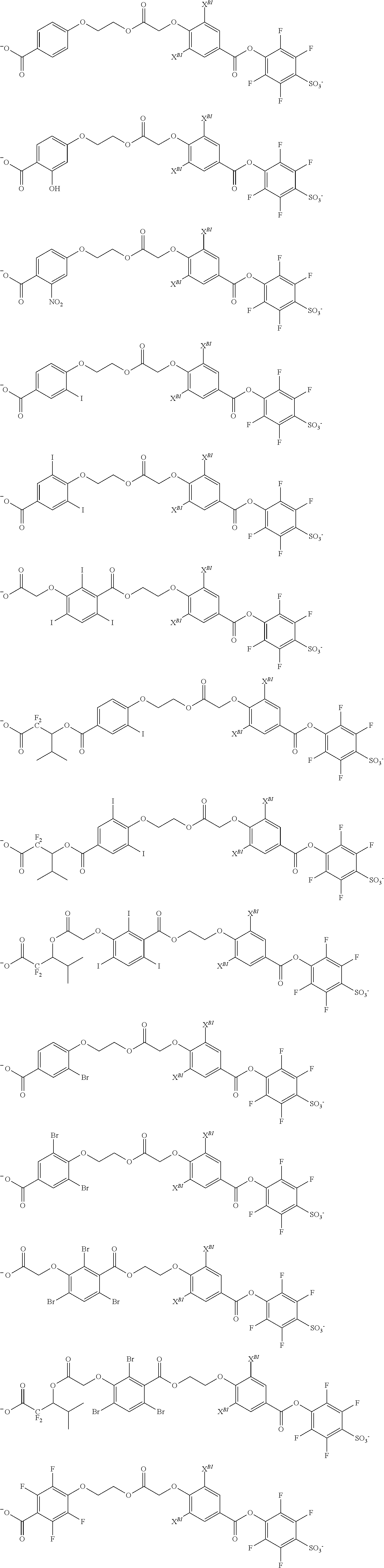

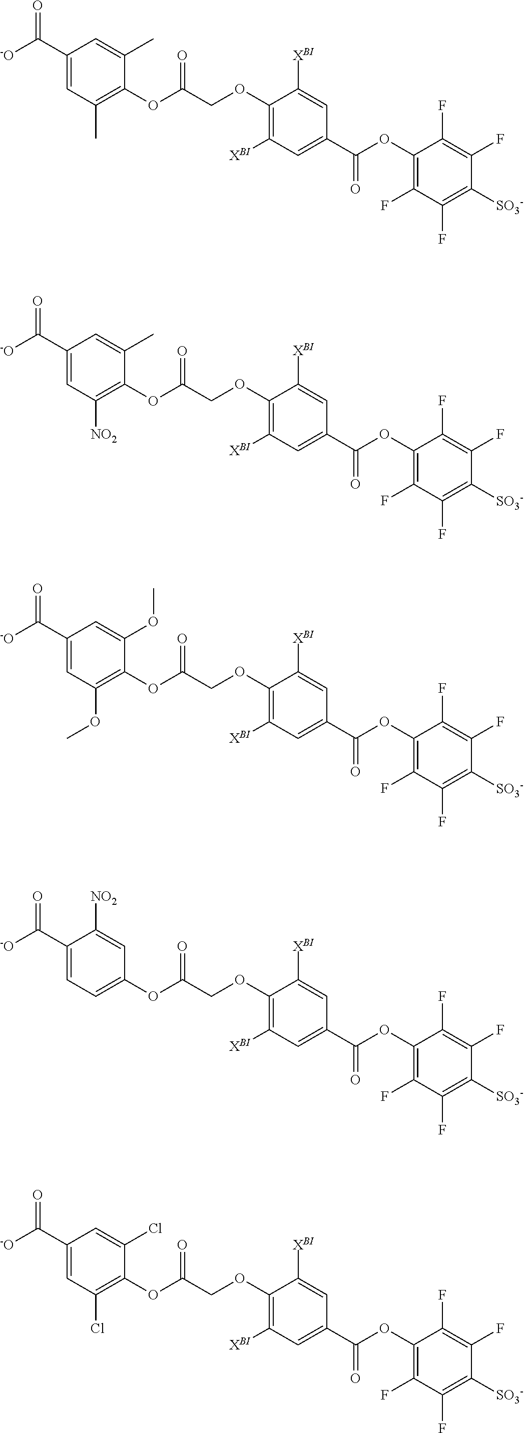

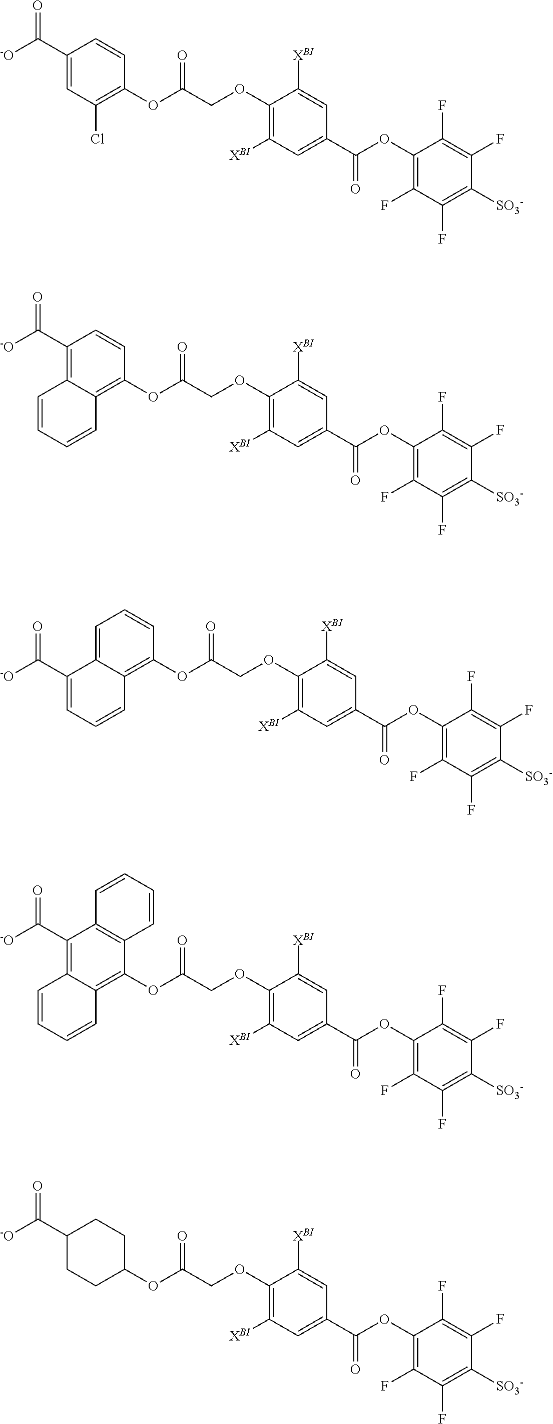

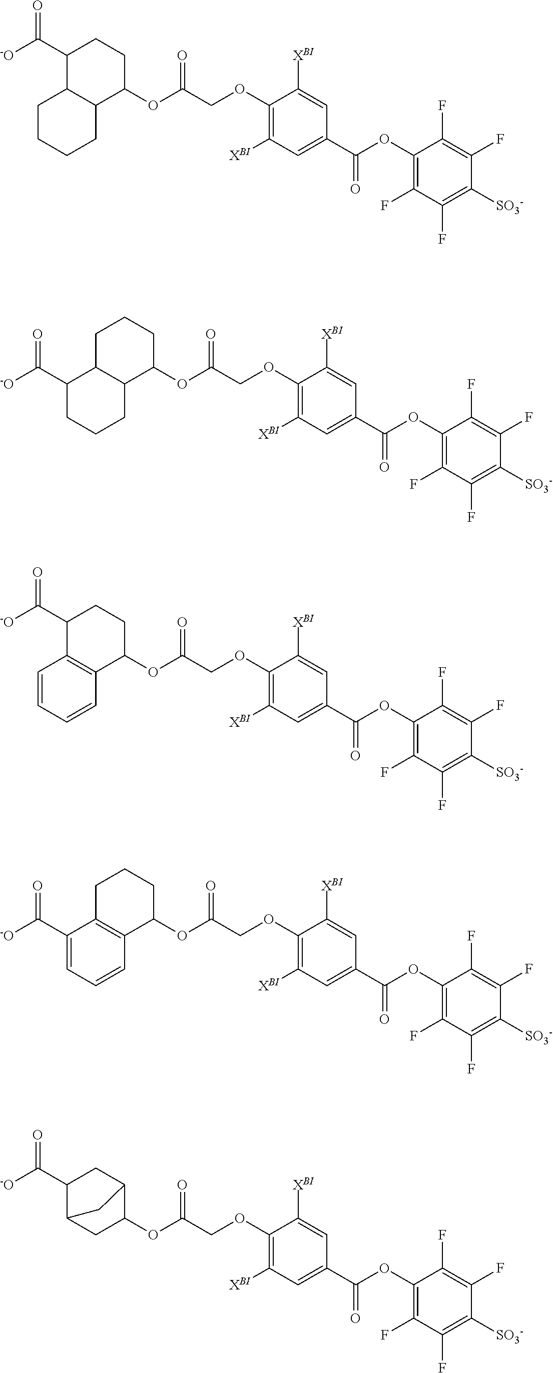

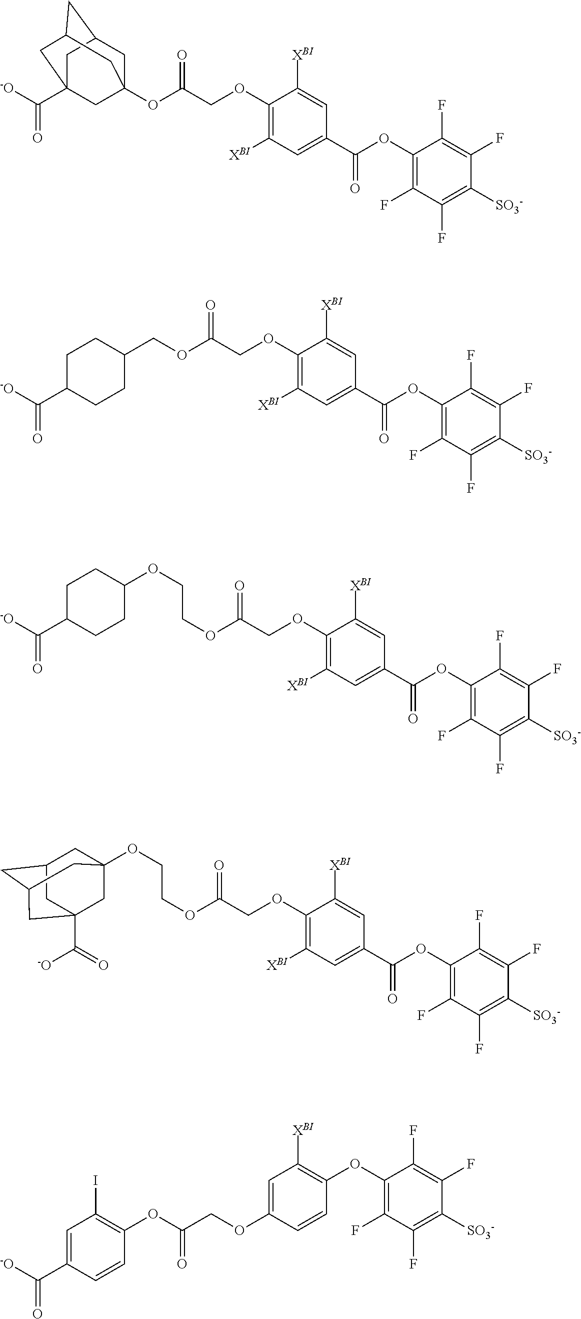

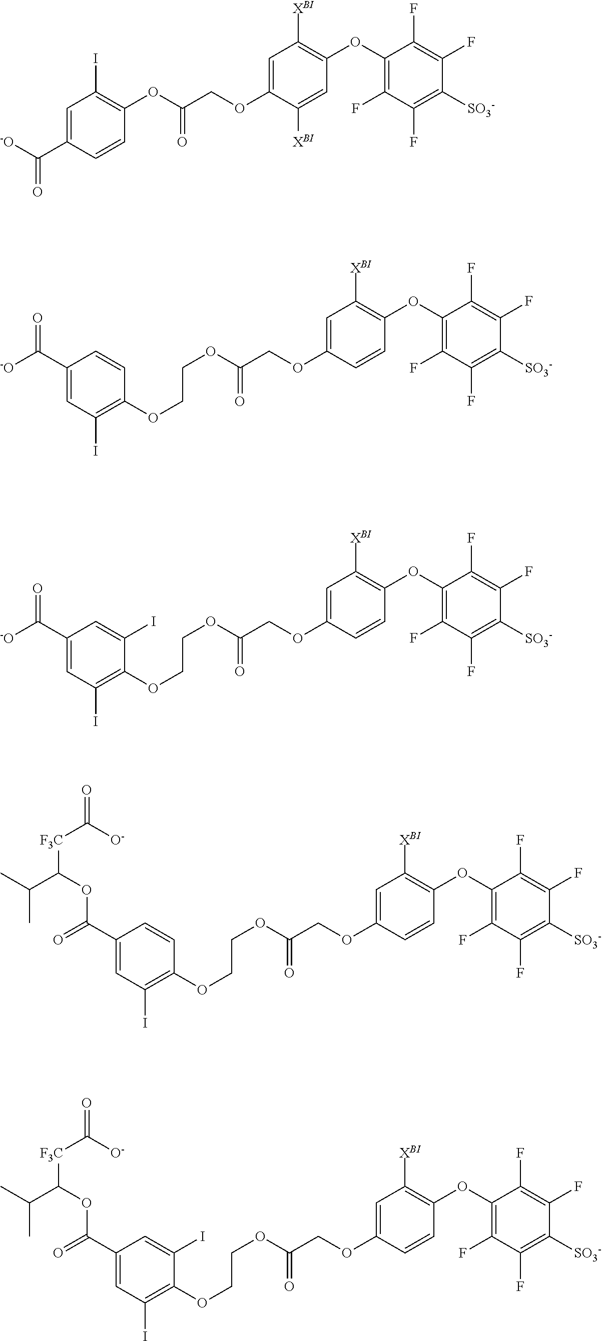

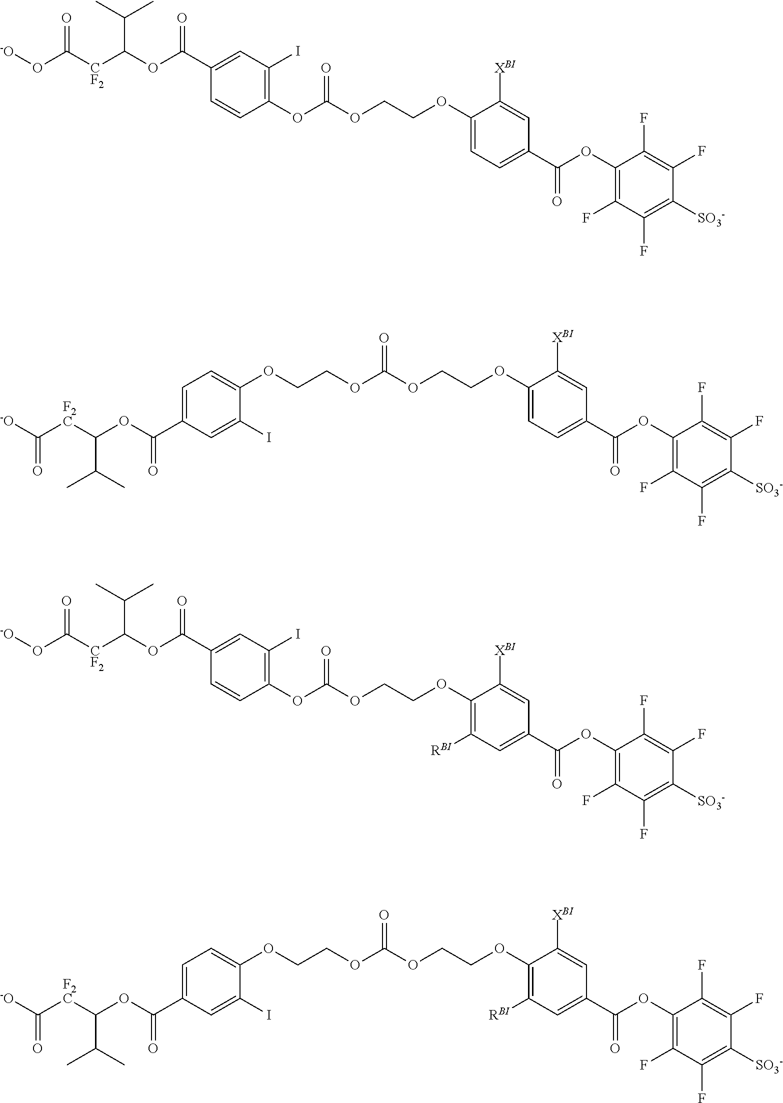

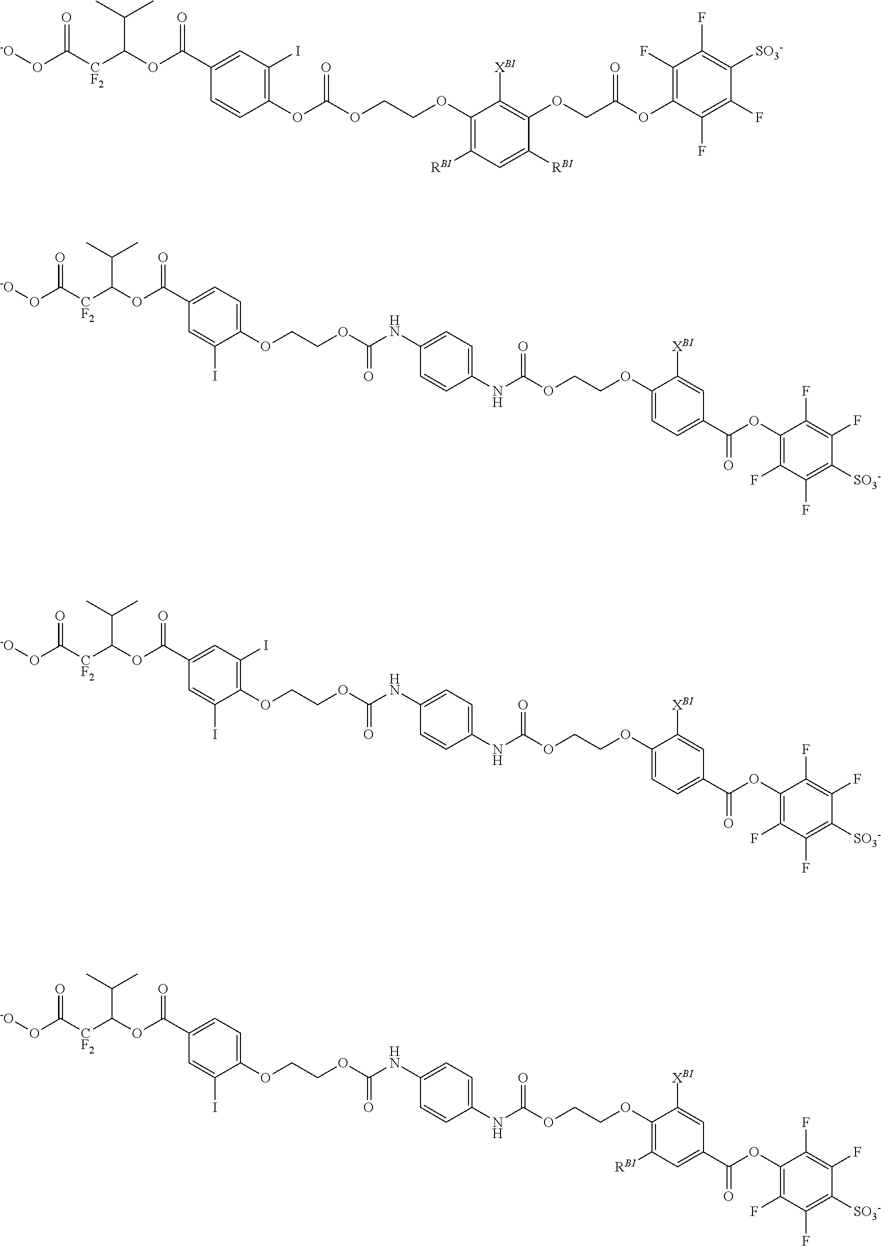

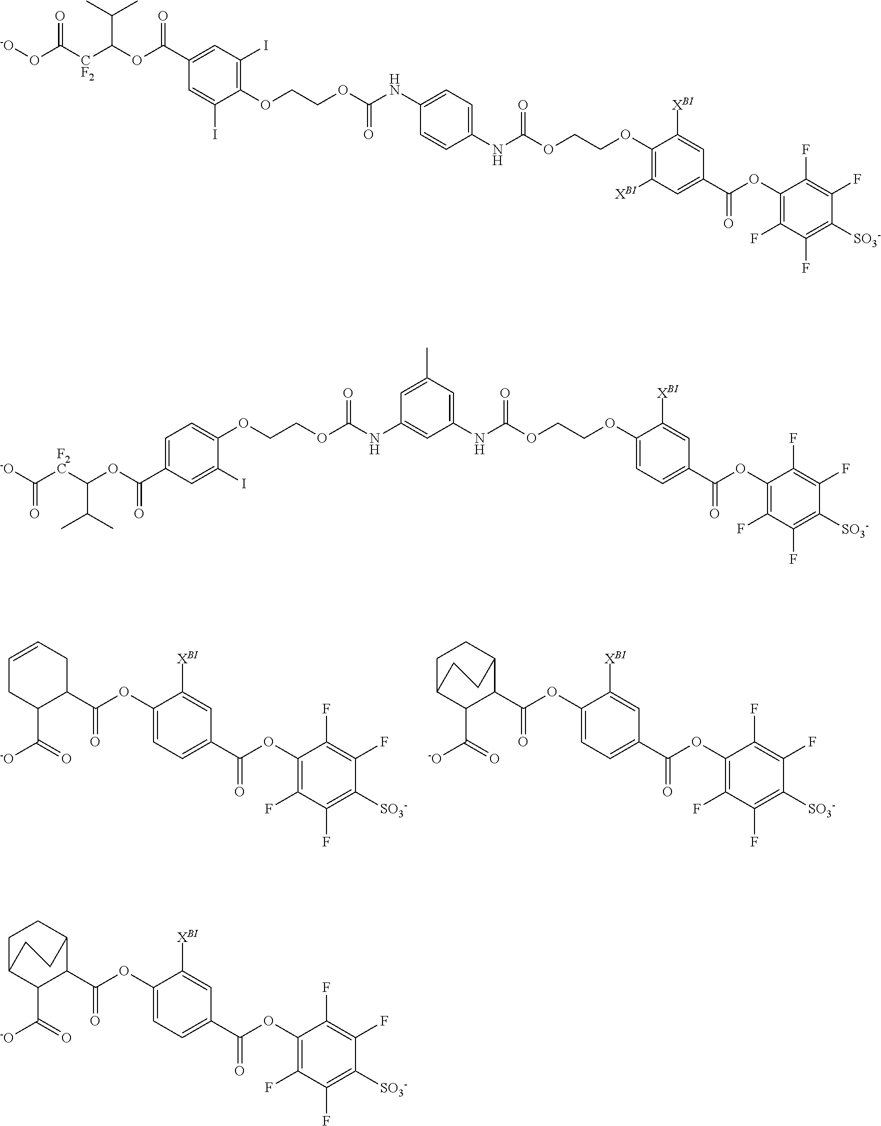

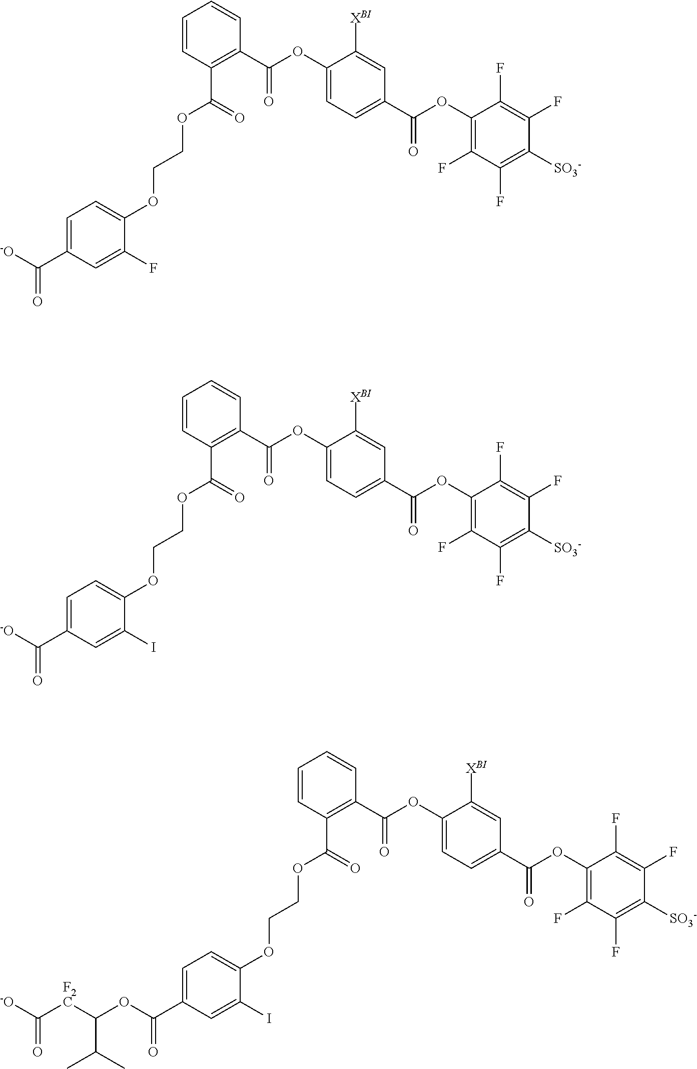

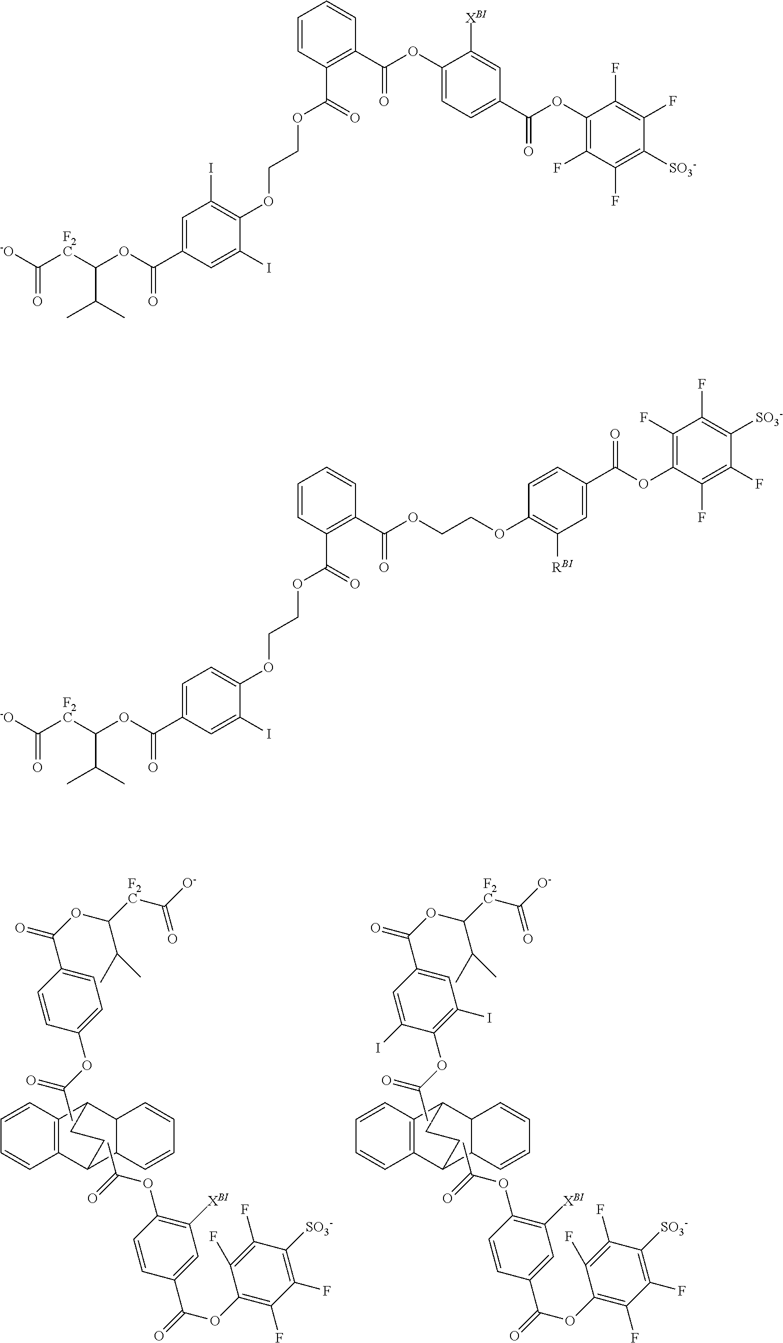

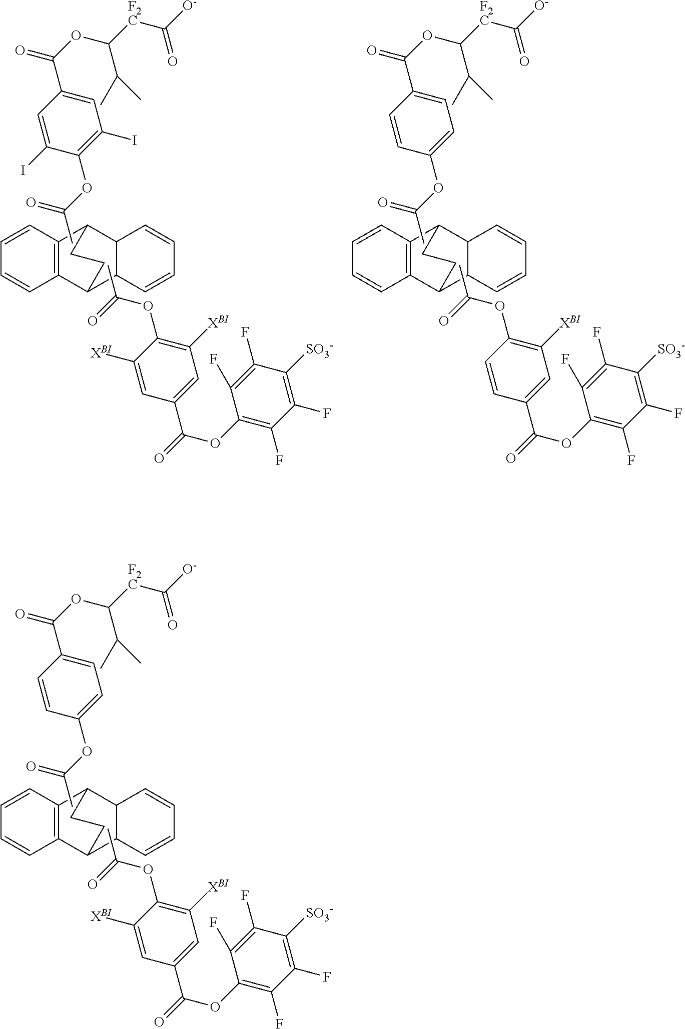

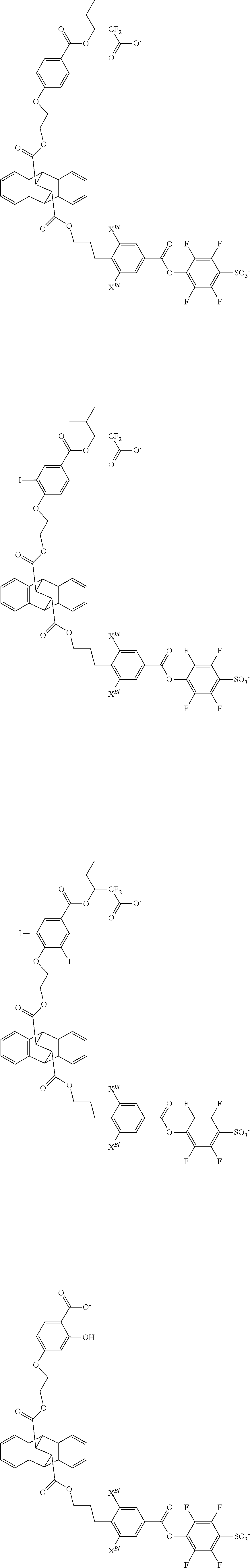

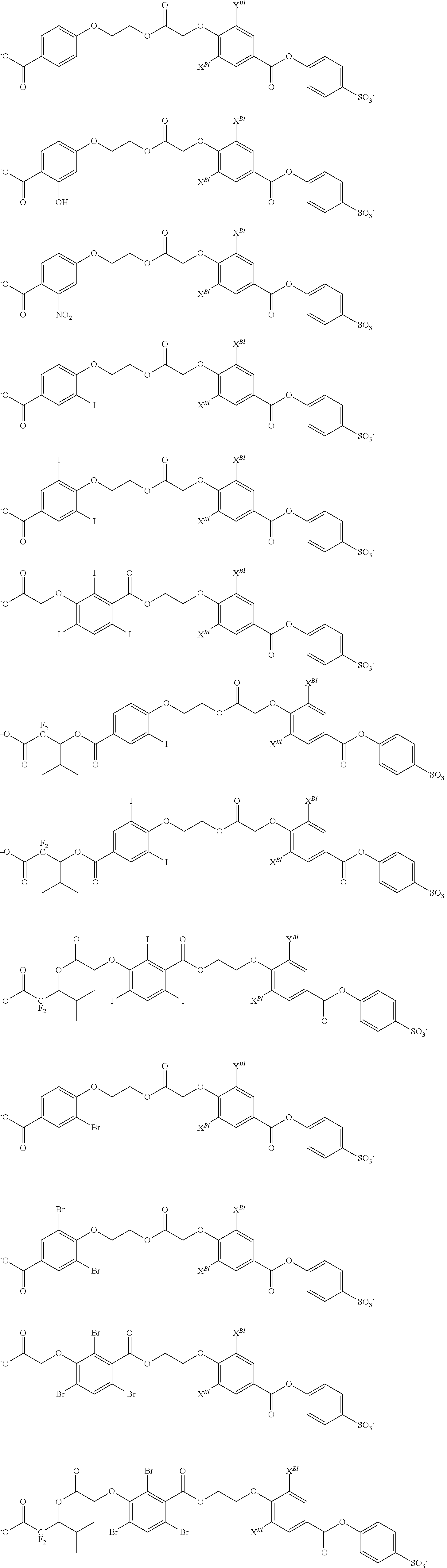

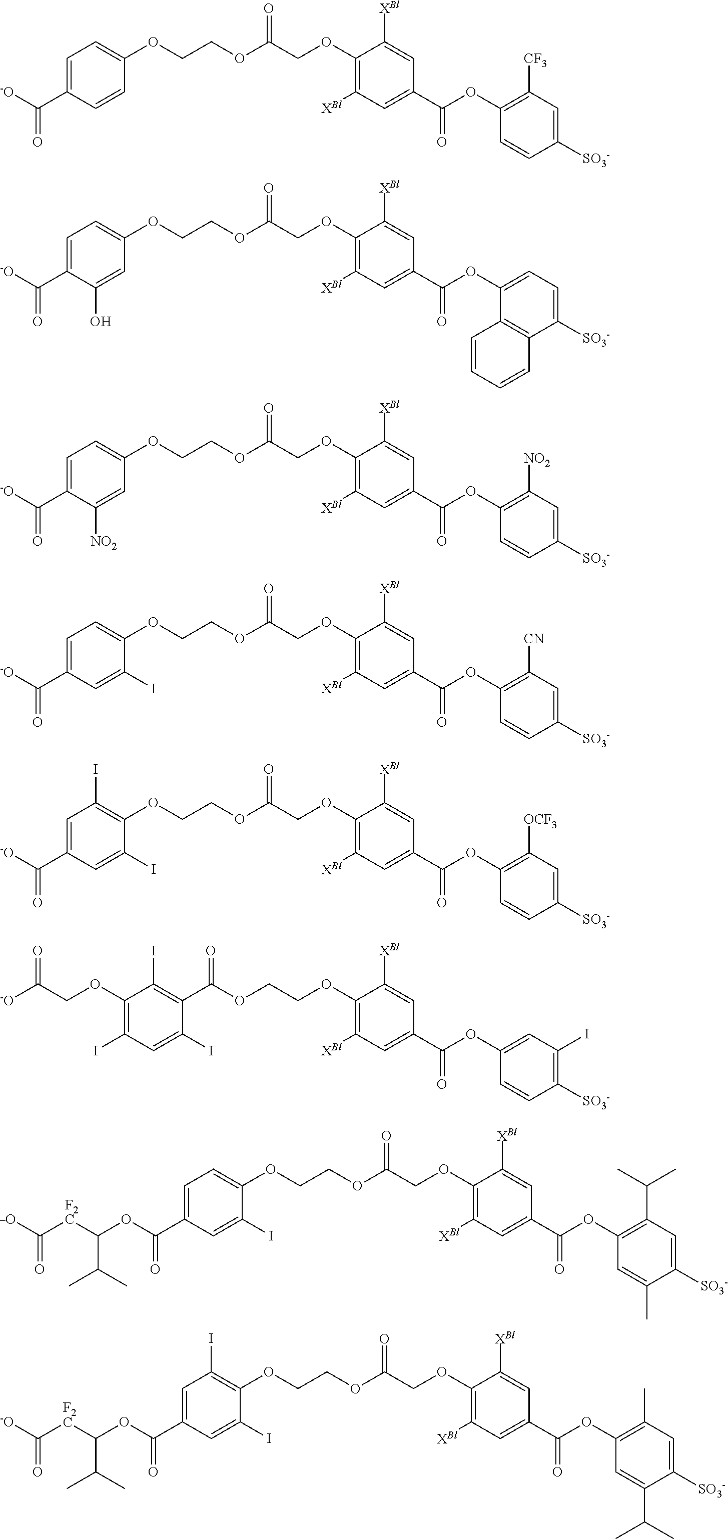

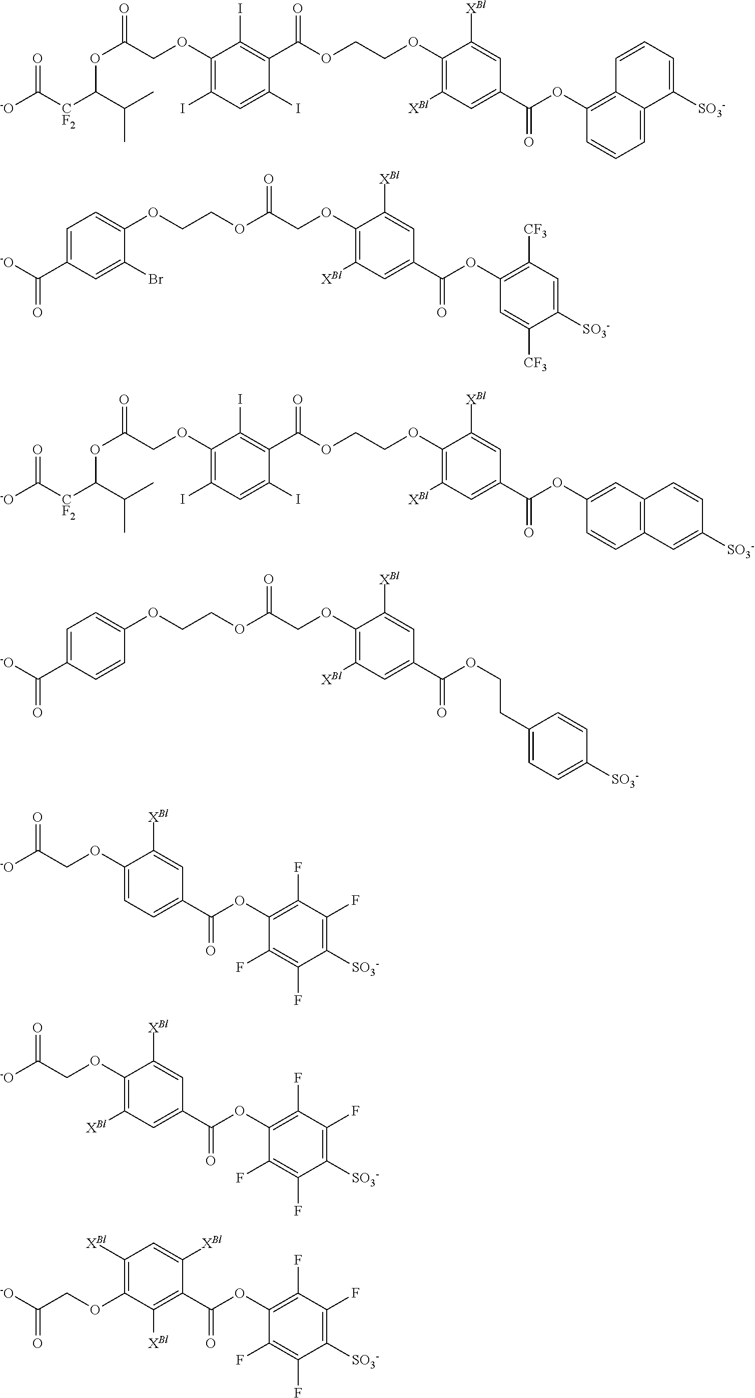

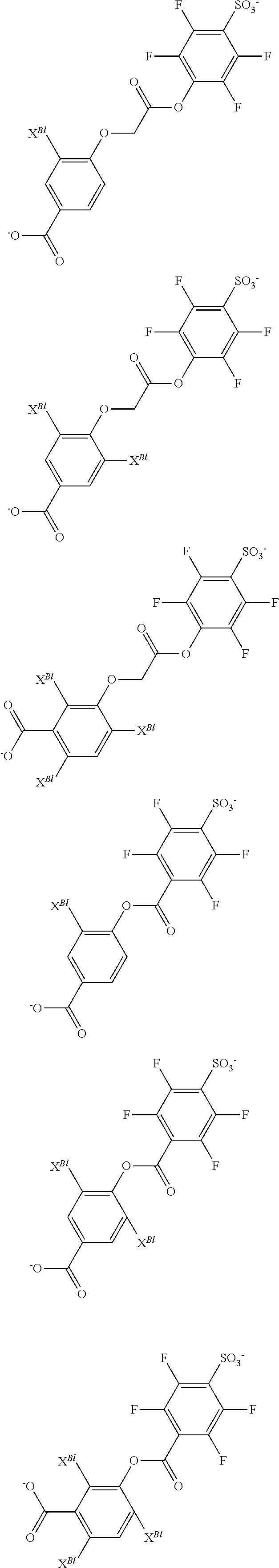

In formula (1), M⁺ is a sulfonium cation or an iodonium cation. Two cations M⁺ may be a sulfonium cation and an iodonium cation, respectively, may be sulfonium cations, respectively, or may be iodonium cations, respectively. When two cations M⁺ are sulfonium cations, respectively, they may be the same or different. When two cations M⁺ are iodonium cations, respectively, they may be the same or different.

The sulfonium cation preferably has the formula (2), and the iodonium cation preferably has the formula (3).

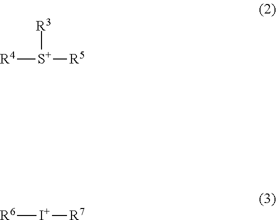

In formulae (2) and (3), R³ to R⁷ are each independently a halogen atom, or a C₁-C₂₀ hydrocarbyl group which may contain a heteroatom.

Examples of the halogen atom represented by R³ to R⁷ include a fluorine atom, a chlorine atom, a bromine atom, and an iodine atom.

The C₁-C₂₀ hydrocarbyl group represented by R³ to R⁷ may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl and icosyl groups; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl and adamantyl groups; C₂-C₂₀ alkenyl groups such as vinyl, propenyl, butenyl and hexenyl groups; C₂-C₂₀ alkynyl groups such as ethynyl, propynyl and butynyl groups; C₃-C₂₀ cyclic unsaturated aliphatic hydrocarbyl groups such as cyclohexenyl and norbornenyl groups; C₆-C₂₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl and tert-butylnaphthyl groups; C₇-C₂₀ aralkyl groups such as benzyl and phenethyl groups; and combinations thereof.

In the hydrocarbyl group, some or all hydrogen atoms may be substituted by a moiety containing a heteroatom such as oxygen, sulfur, nitrogen or halogen and some constituent-CH₂— may be replaced by a moiety containing a heteroatom such as oxygen, sulfur or nitrogen, so that the group may contain hydroxy, fluorine, chlorine, bromine, iodine, cyano, nitro, mercapto, pentafluorosulfanyl, carbonyl, ether bond, ester bond, sulfonic ester bond, carbonate bond, lactone ring, sultone ring, carboxylic anhydride (—C(═O)—O—C(═O)—), or haloalkyl moiety.

R³ and R⁴ may bond together to form a ring with the sulfur atom to which they are attached. Examples of the ring are shown below.

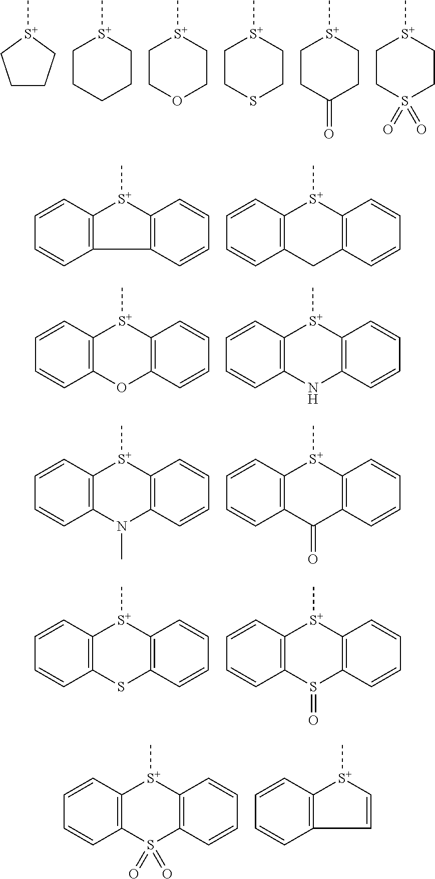

Herein the broken line designates a point of attachment.

Examples of the sulfonium cation represented by formula M⁺ are shown below, but not limited thereto.

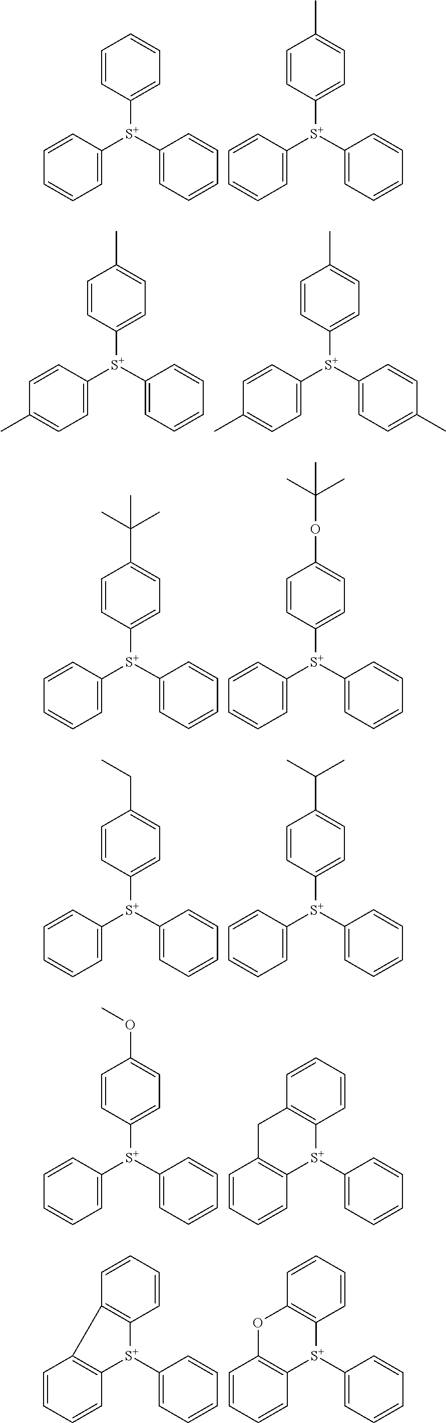

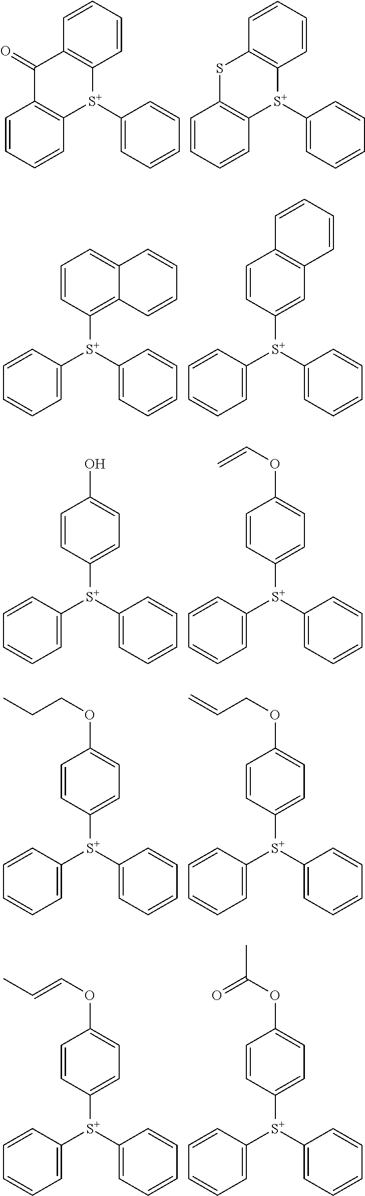

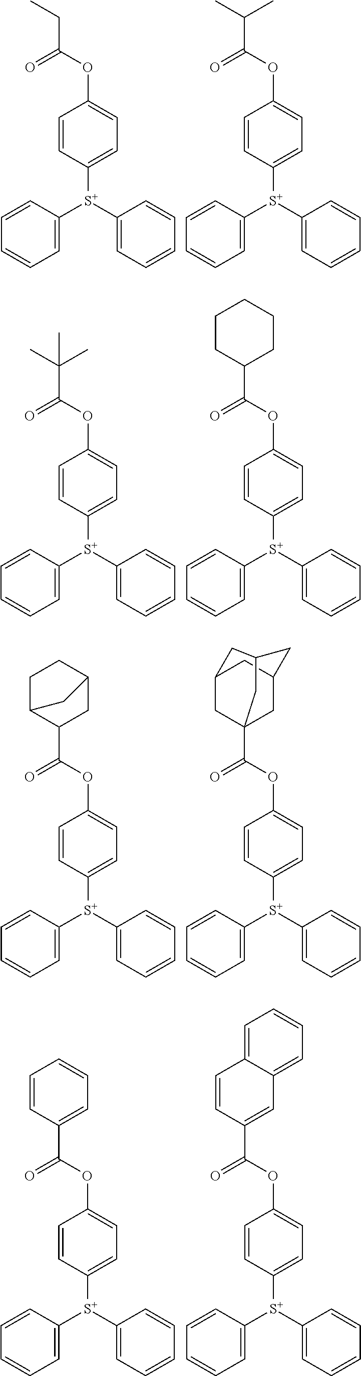

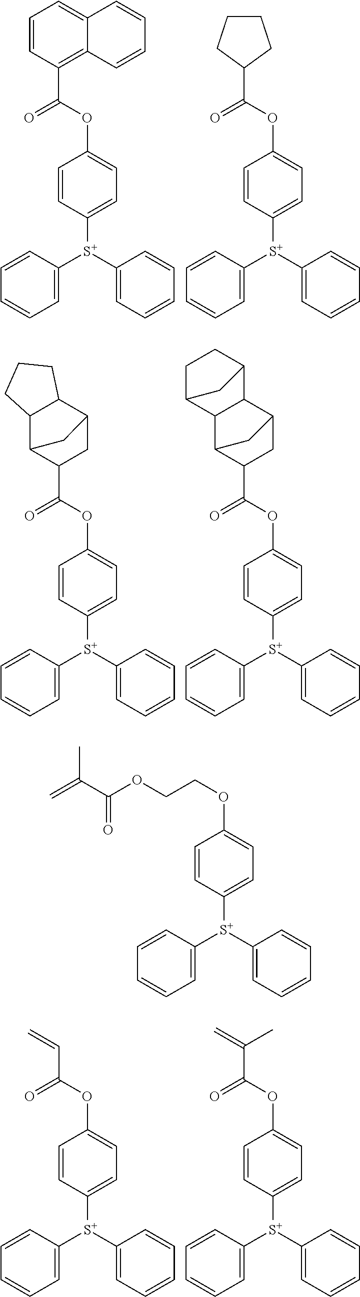

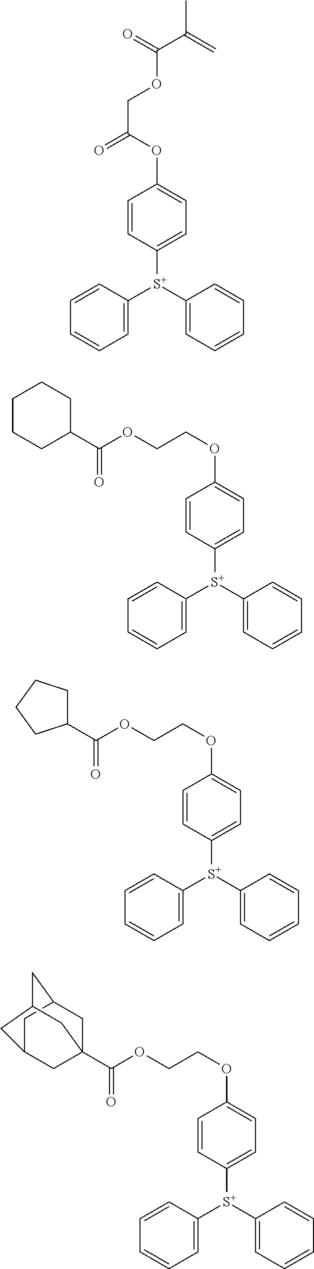 [SMILES: C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2]

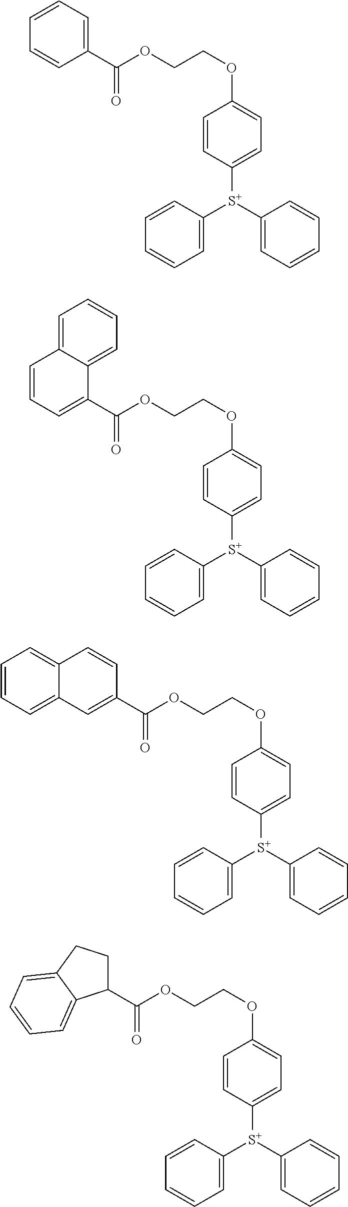 [SMILES: O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

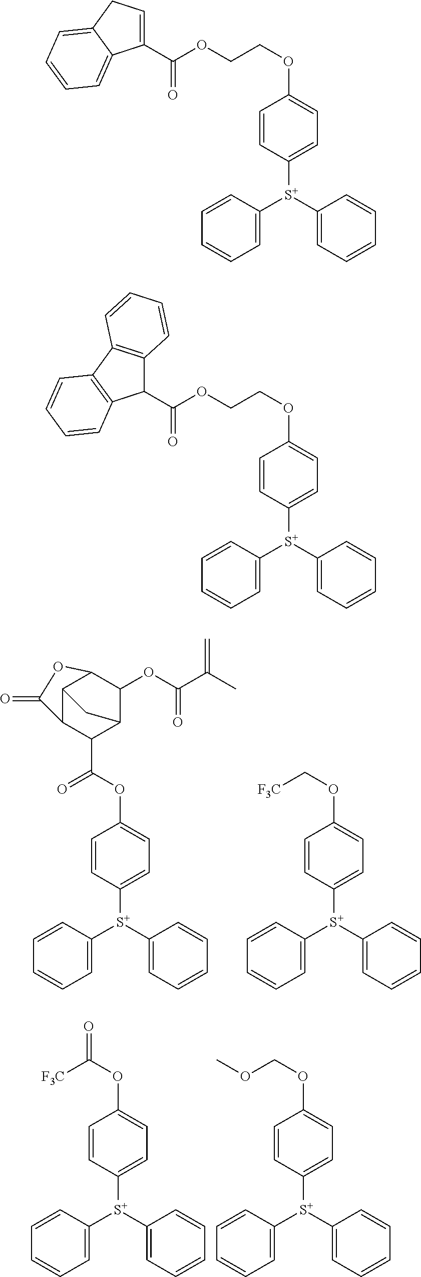 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F ; COCOc1ccc([S+](c2ccccc2)c2ccccc2)cc1]

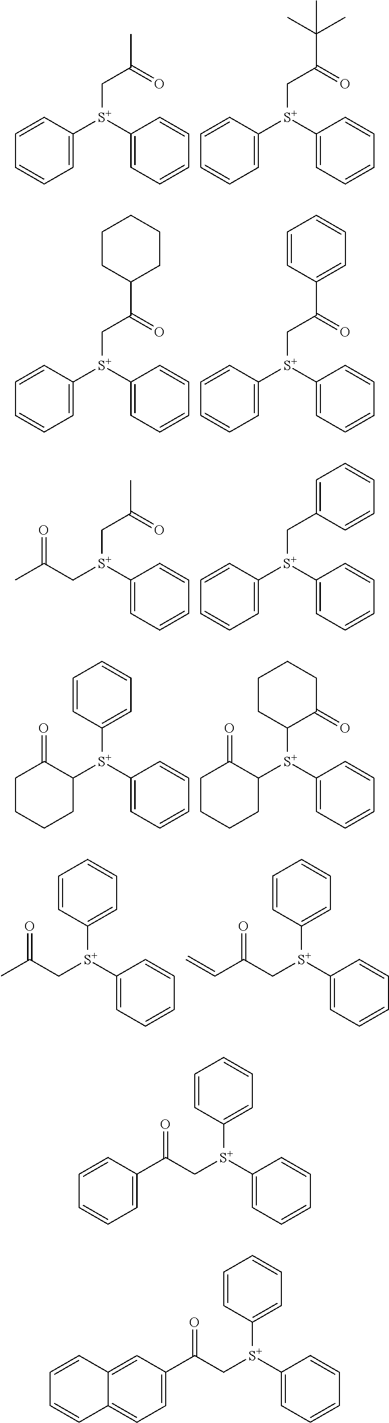

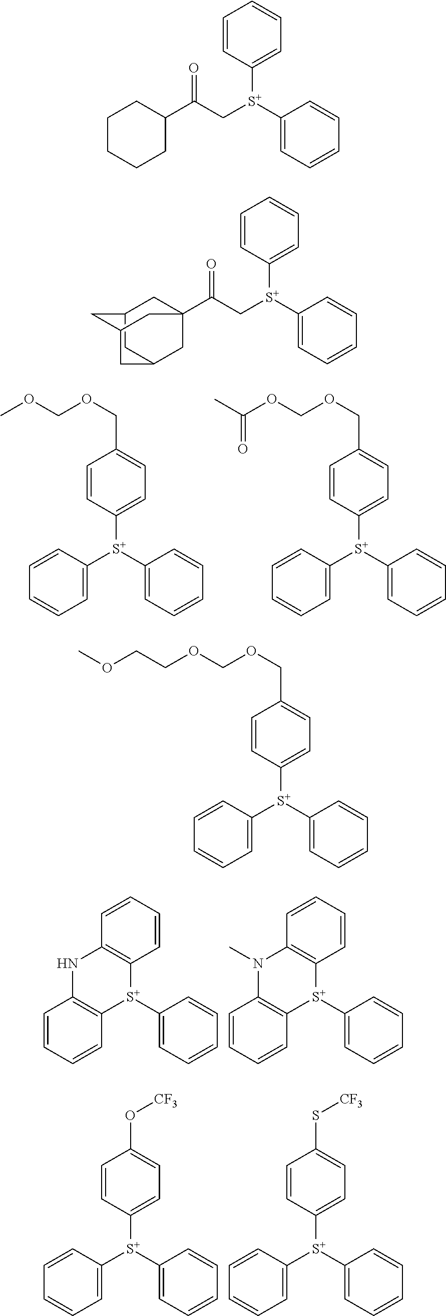

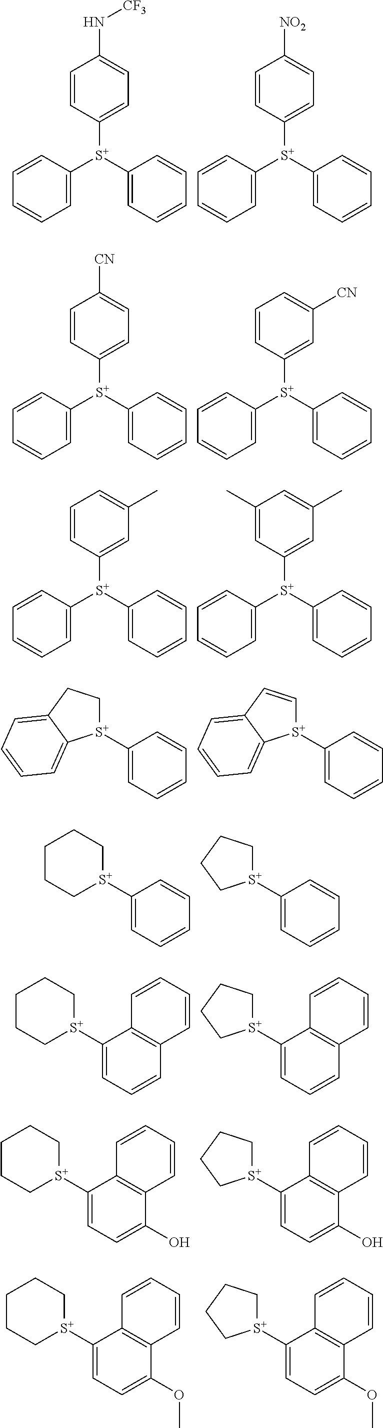

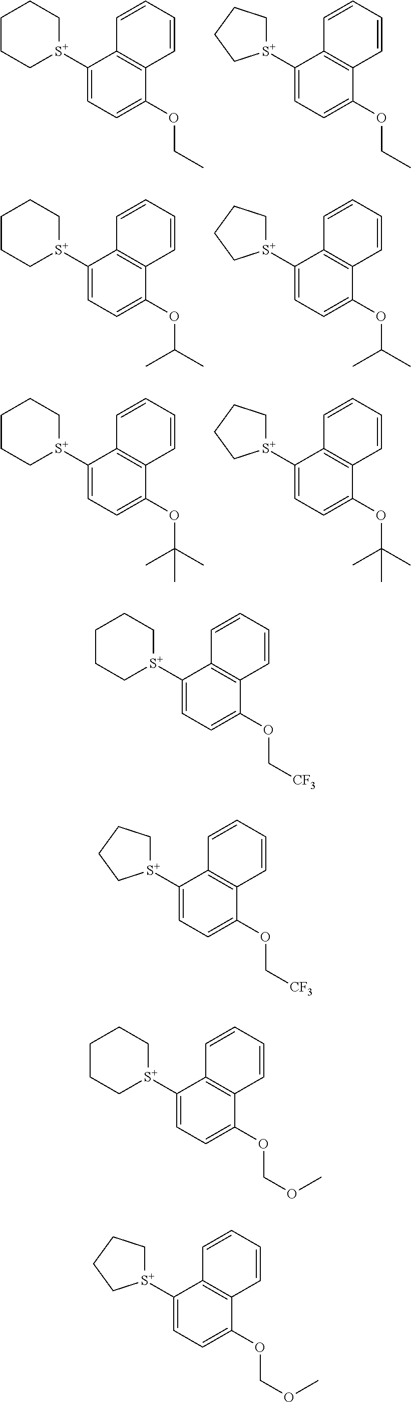

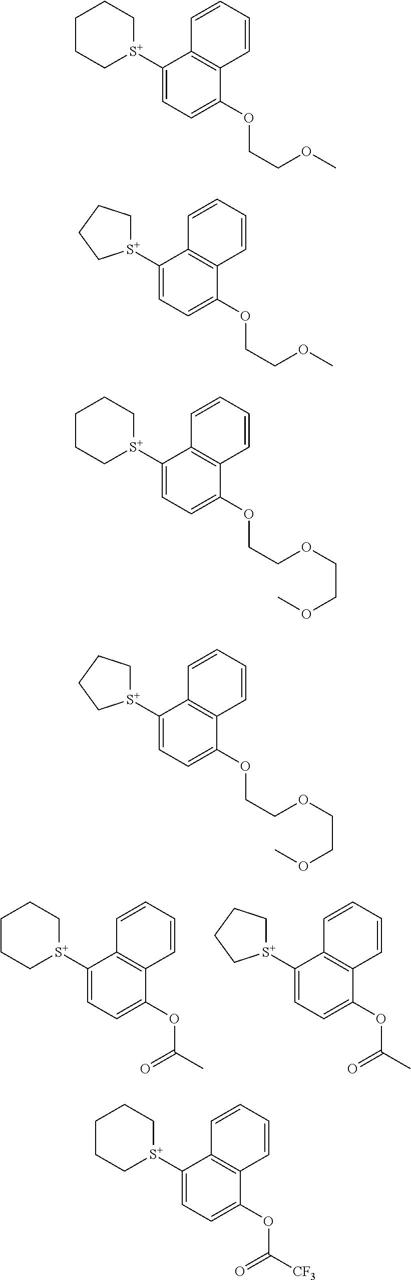

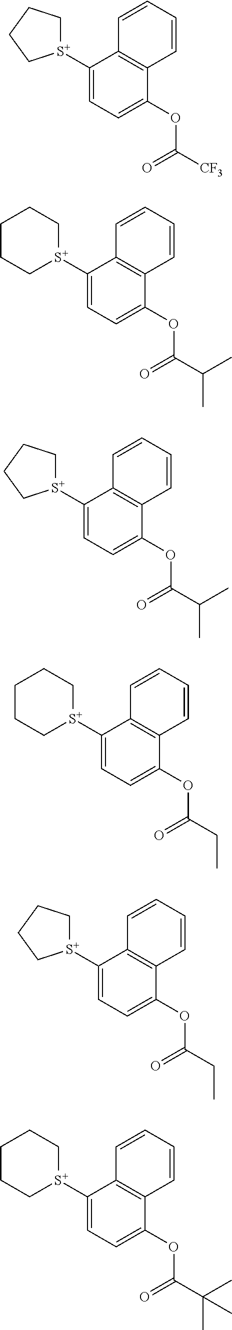 [SMILES: O=C(Oc1ccc([S+]2CCCC2)c2ccccc12)C(F)(F)F ; CC(C)C(=O)Oc1ccc([S+]2CCCCC2)c2ccccc12 ; CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12 ; CC(C)(C)C(=O)Oc1ccc([S+]2CCCCC2)c2ccccc12]

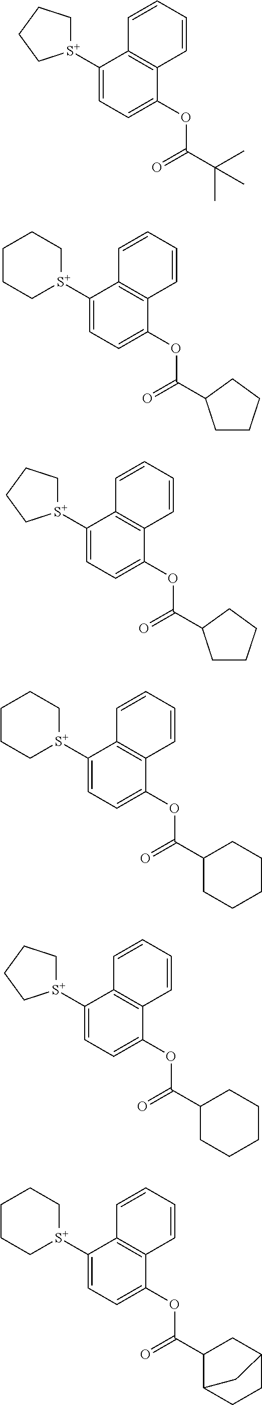 [SMILES: CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1 ; O=C(Oc1ccc([S+]2CCCCC2)c2ccccc12)C1CC2CCC1C2]

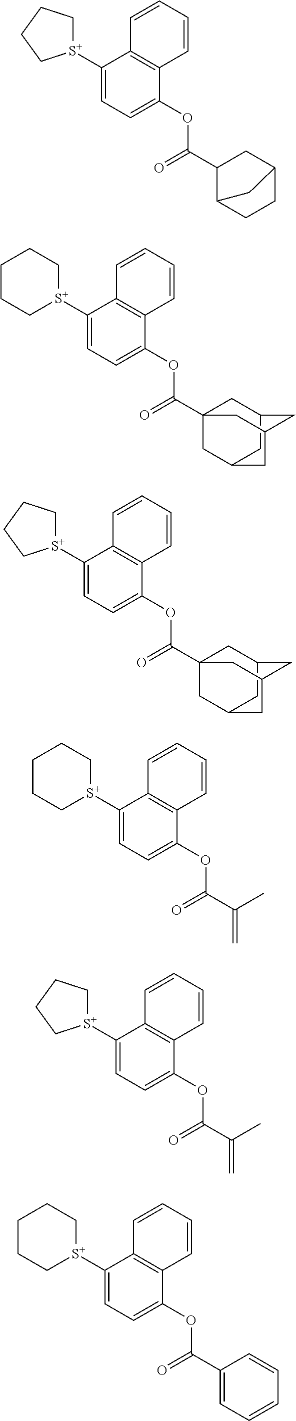 [SMILES: O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; C=C(C)C(=O)Oc1ccc([S+]2CCCCC2)c2ccccc12 ; C=C(C)C(=O)Oc1ccc([S+]2CCCC2)c2ccccc12 ; O=C(Oc1ccc([S+]2CCCCC2)c2ccccc12)c1ccccc1]

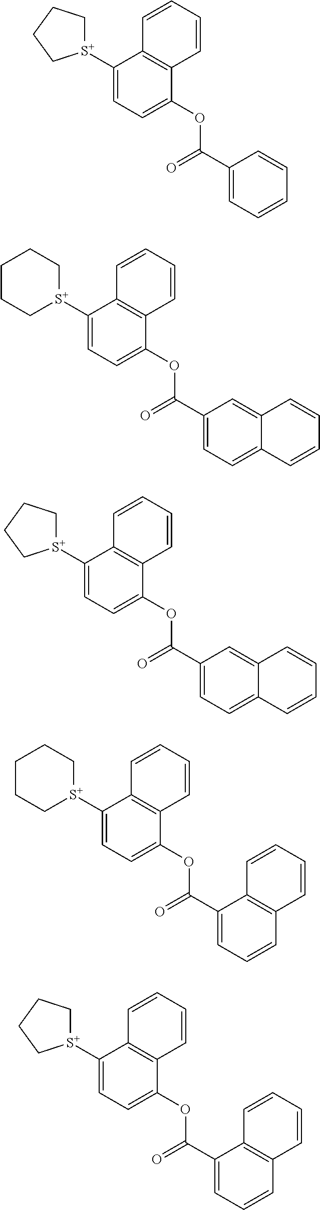 [SMILES: O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12]

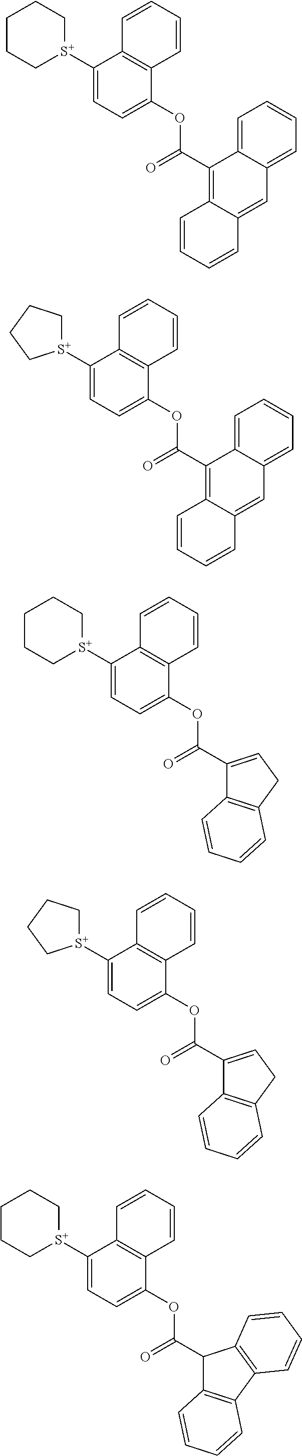 [SMILES: O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21 ; O=C(Oc1ccc([S+]2CCCCC2)c2ccccc12)C1c2ccccc2-c2ccccc21]

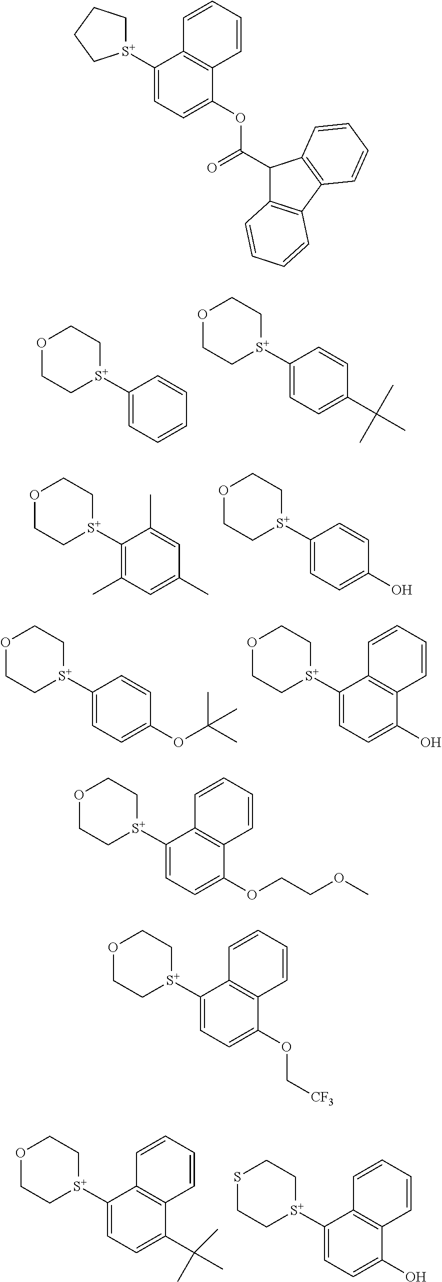

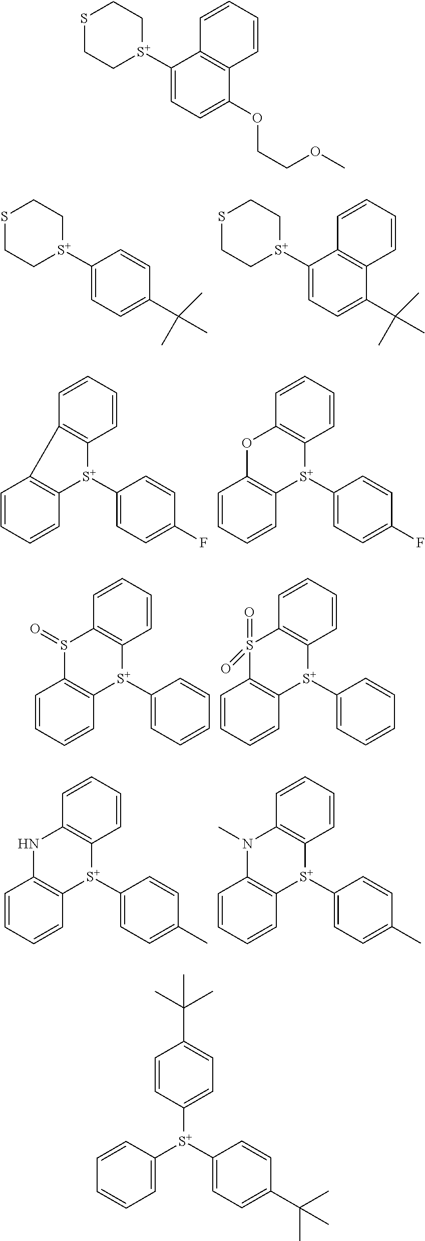

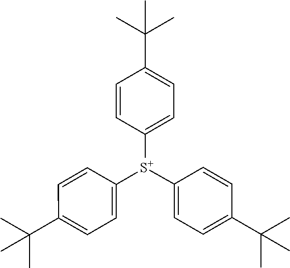 [SMILES: CC(C)(C)c1ccc([S+](c2ccc(C(C)(C)C)cc2)c2ccc(C(C)(C)C)cc2)cc1]

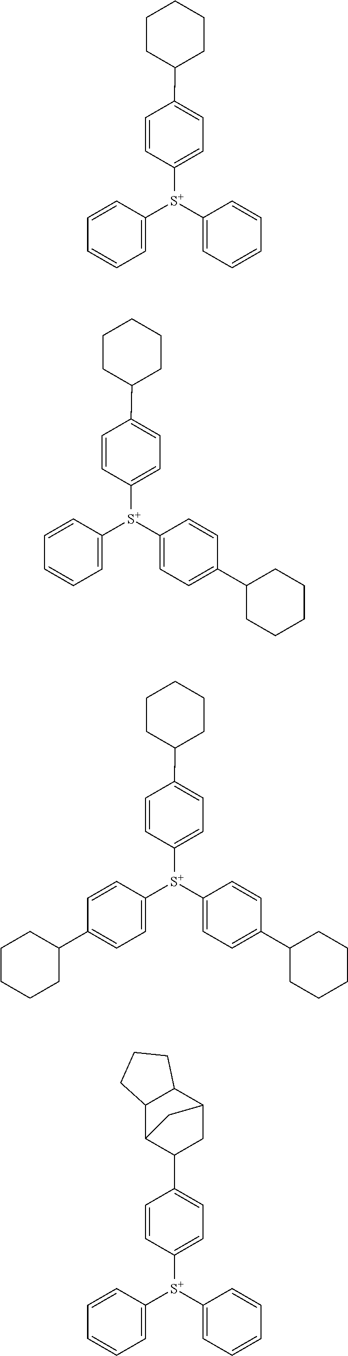 [SMILES: c1ccc([S+](c2ccccc2)c2ccc(C3CCCCC3)cc2)cc1 ; c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1]

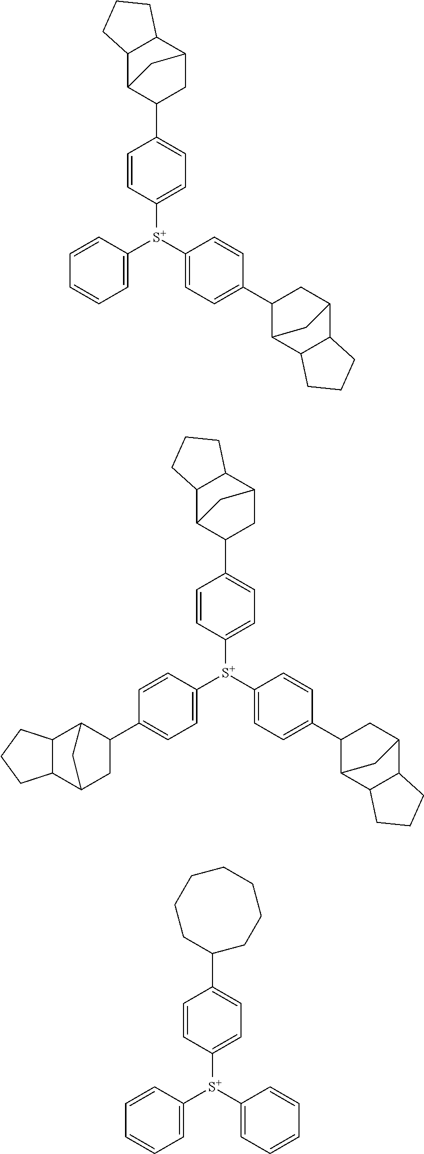 [SMILES: c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1]

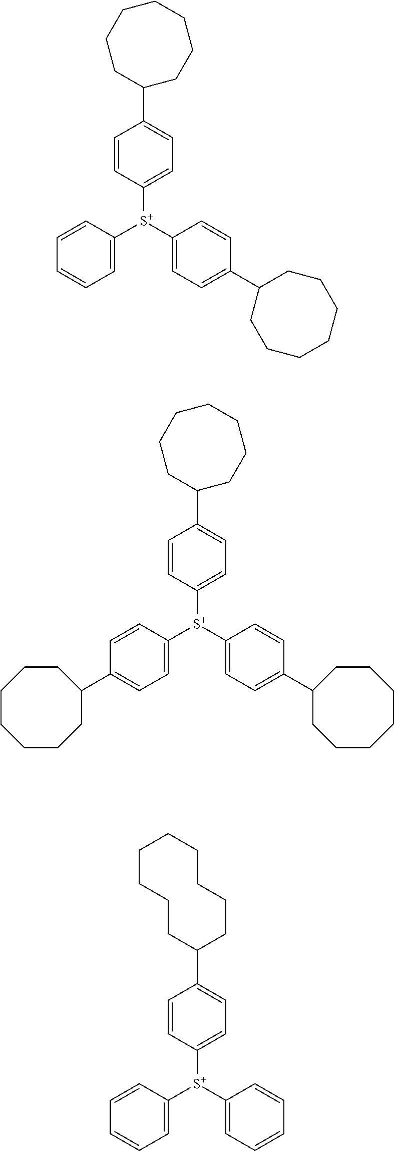 [SMILES: c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1 ; c1ccc([S+](c2ccccc2)c2ccc(C3CCCCCCCCC3)cc2)cc1]

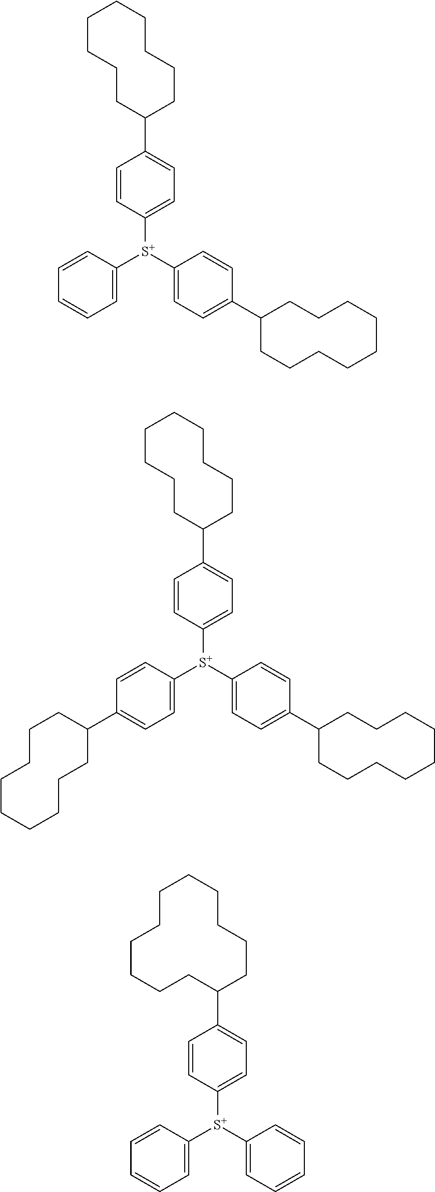 [SMILES: c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1 ; c1ccc([S+](c2ccccc2)c2ccc(C3CCCCCCCCCCC3)cc2)cc1]

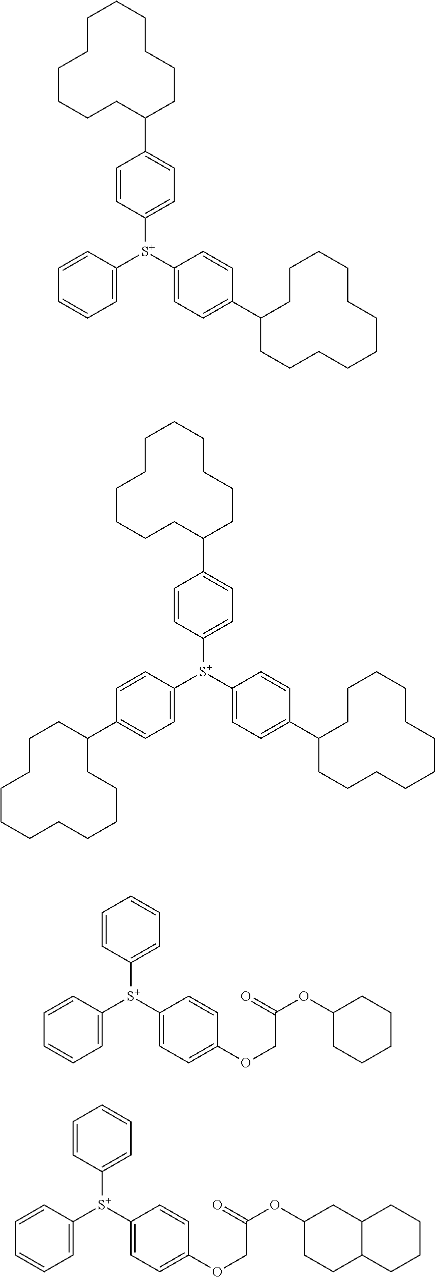 [SMILES: c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1]

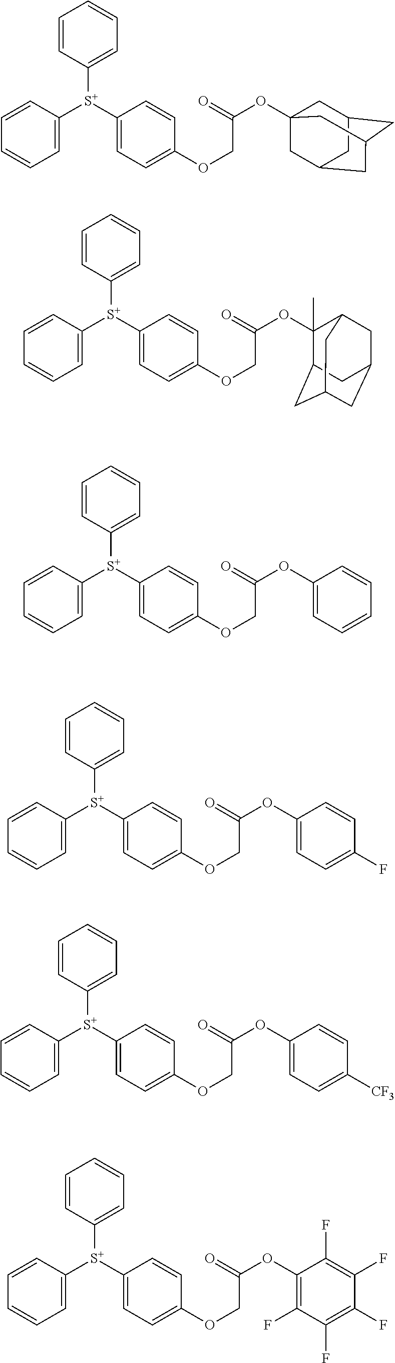 [SMILES: O=C(COc1ccc([S+](c2ccccc2)c2ccccc2)cc1)OC12CC3CC(CC(C3)C1)C2 ; CC1(OC(=O)COc2ccc([S+](c3ccccc3)c3ccccc3)cc2)C2CC3CC(C2)CC1C3 ; O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F]

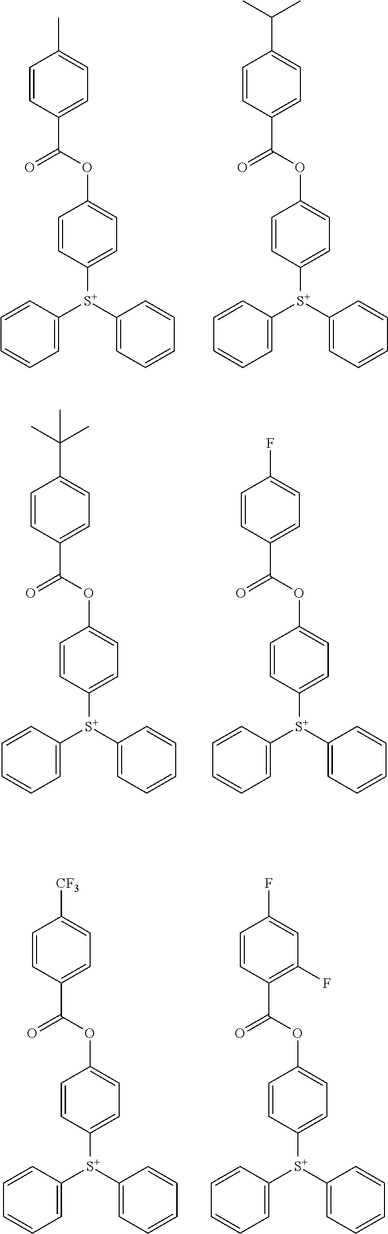 [SMILES: Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F]

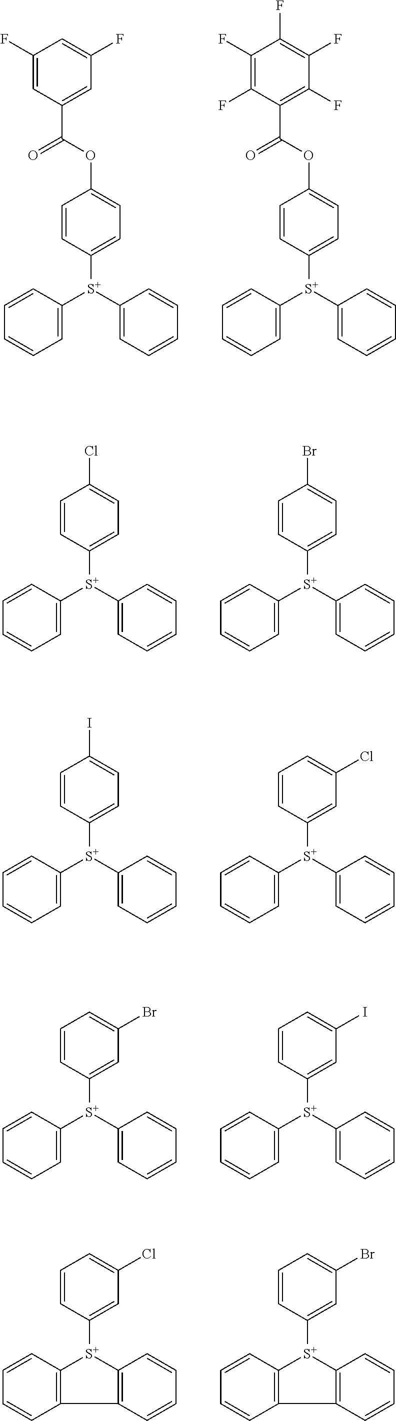

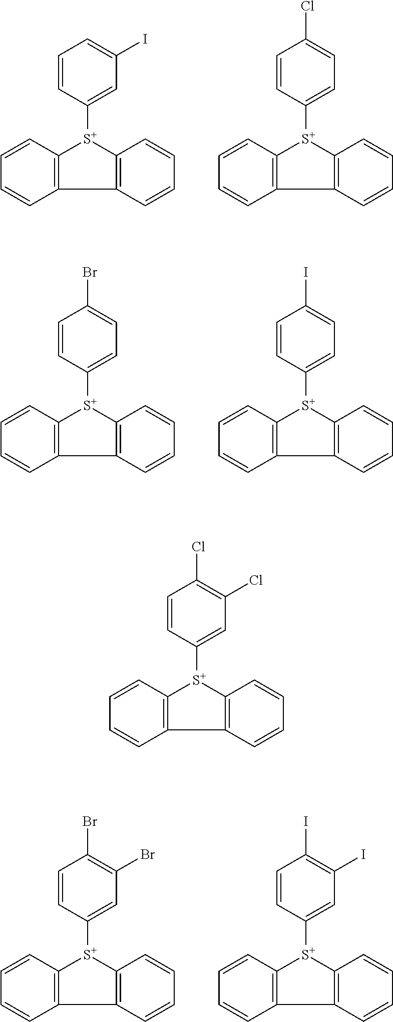

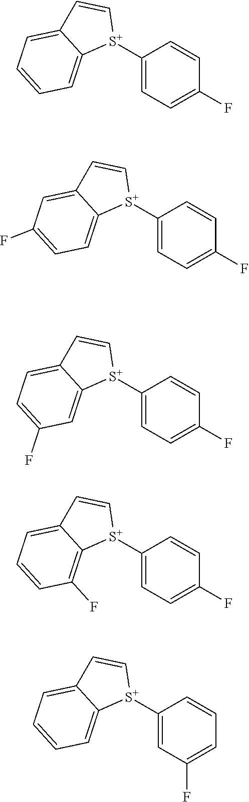 [SMILES: Fc1ccc(-[s+]2ccc3ccccc32)cc1 ; Fc1ccc(-[s+]2ccc3cc(F)ccc32)cc1 ; Fc1ccc(-[s+]2ccc3ccc(F)cc32)cc1 ; Fc1ccc(-[s+]2ccc3cccc(F)c32)cc1 ; Fc1cccc(-[s+]2ccc3ccccc32)c1]

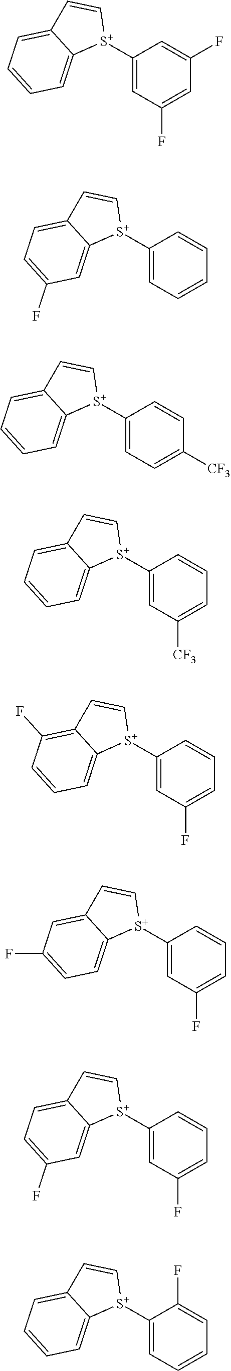

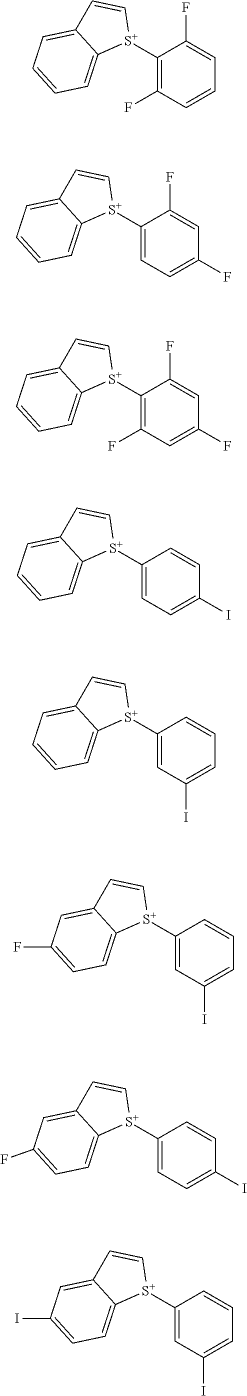

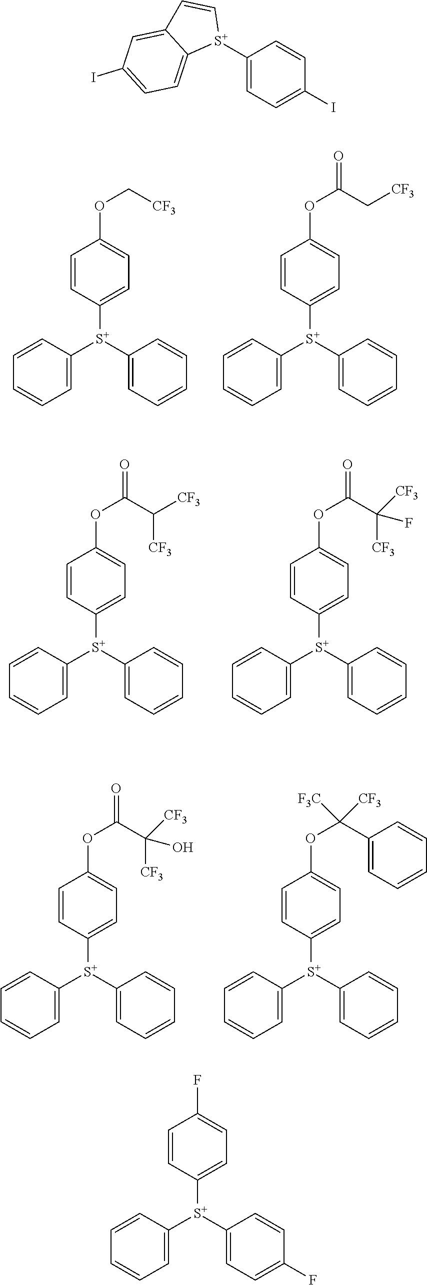

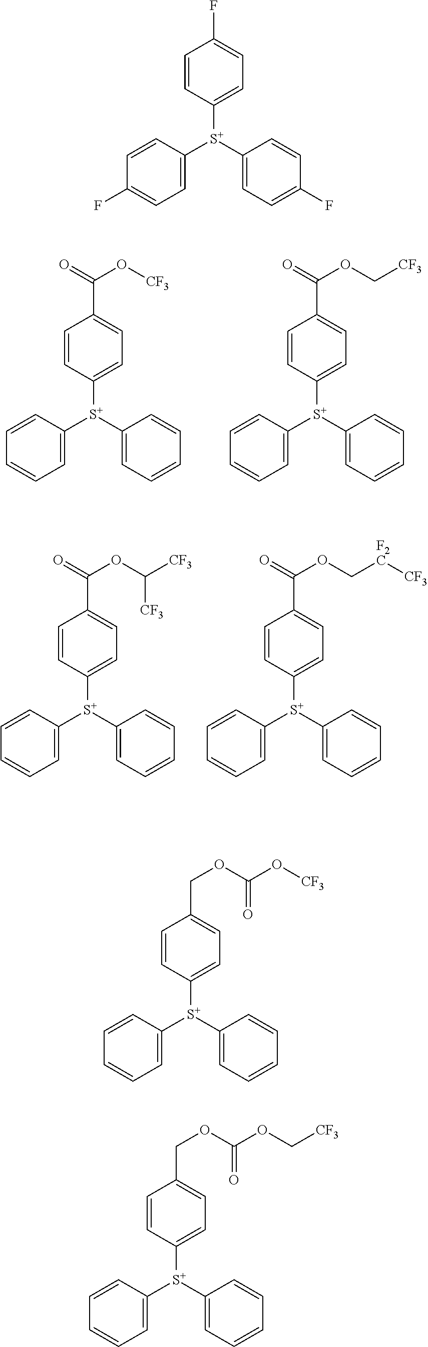

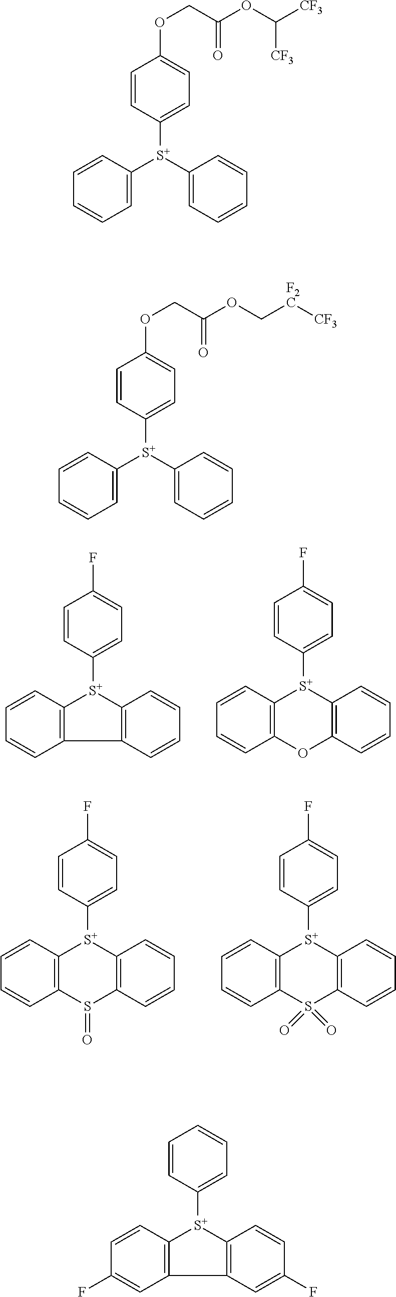

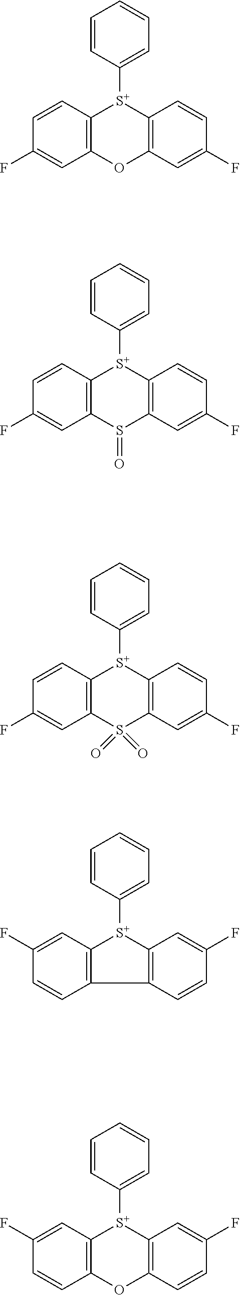 [SMILES: Fc1ccc2c(c1)Oc1cc(F)ccc1[S+]2c1ccccc1 ; O=S1c2cc(F)ccc2[S+](c2ccccc2)c2ccc(F)cc21 ; O=S1(=O)c2cc(F)ccc2[S+](c2ccccc2)c2ccc(F)cc21 ; Fc1ccc2c3ccc(F)cc3[s+](-c3ccccc3)c2c1 ; Fc1ccc2c(c1)[S+](c1ccccc1)c1cc(F)ccc1O2]

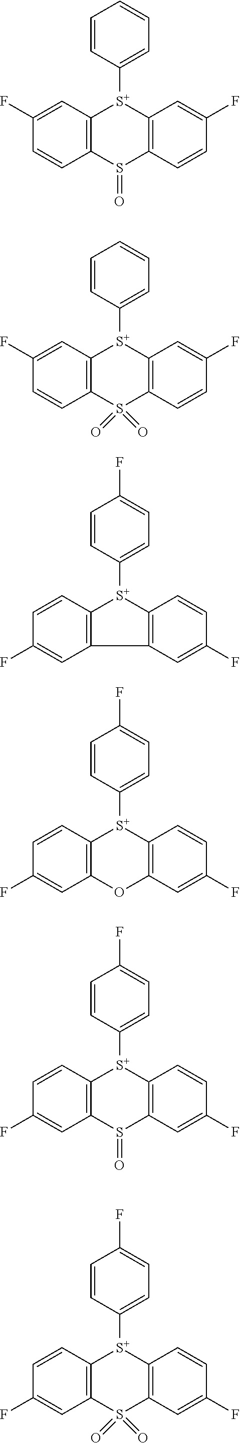 [SMILES: O=S1c2ccc(F)cc2[S+](c2ccccc2)c2cc(F)ccc21 ; O=S1(=O)c2ccc(F)cc2[S+](c2ccccc2)c2cc(F)ccc21 ; Fc1ccc(-[s+]2c3ccc(F)cc3c3cc(F)ccc32)cc1 ; Fc1ccc([S+]2c3ccc(F)cc3Oc3cc(F)ccc32)cc1 ; O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21]

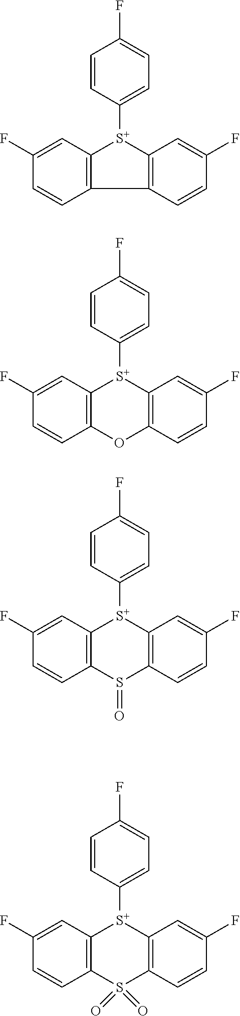 [SMILES: Fc1ccc(-[s+]2c3cc(F)ccc3c3ccc(F)cc32)cc1 ; Fc1ccc([S+]2c3cc(F)ccc3Oc3ccc(F)cc32)cc1 ; O=S1c2ccc(F)cc2[S+](c2ccc(F)cc2)c2cc(F)ccc21 ; O=S1(=O)c2ccc(F)cc2[S+](c2ccc(F)cc2)c2cc(F)ccc21]

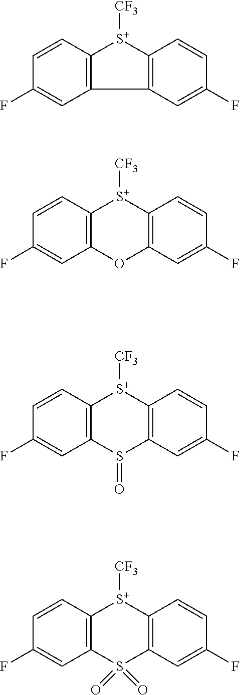 [SMILES: Fc1ccc2c(c1)c1cc(F)ccc1[s+]2C(F)(F)F ; Fc1ccc2c(c1)Oc1cc(F)ccc1[S+]2C(F)(F)F ; O=S1c2cc(F)ccc2[S+](C(F)(F)F)c2ccc(F)cc21 ; O=S1(=O)c2cc(F)ccc2[S+](C(F)(F)F)c2ccc(F)cc21]

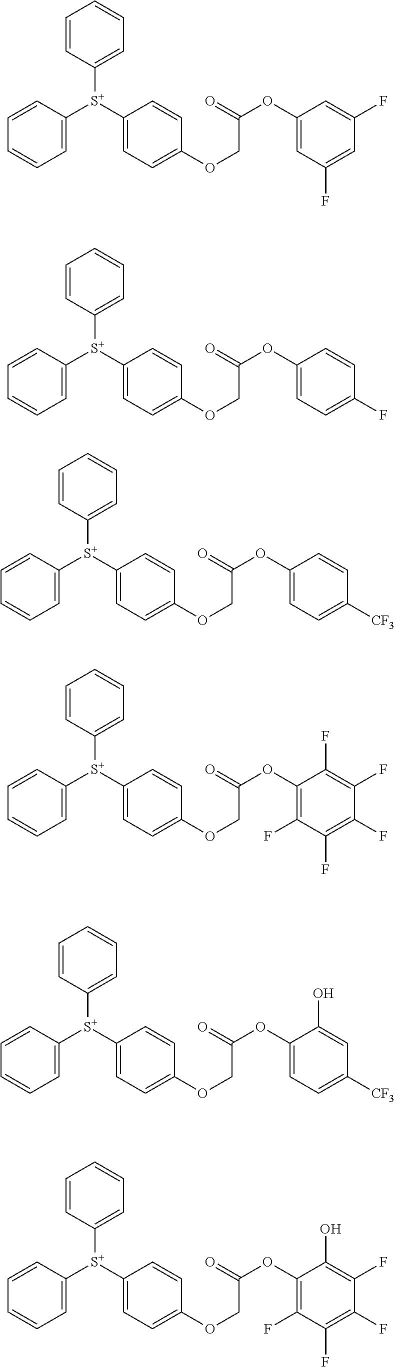 [SMILES: O=C(COc1ccc([S+](c2ccccc2)c2ccccc2)cc1)Oc1cc(F)cc(F)c1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; O=C(COc1ccc([S+](c2ccccc2)c2ccccc2)cc1)Oc1ccc(C(F)(F)F)cc1O ; O=C(COc1ccc([S+](c2ccccc2)c2ccccc2)cc1)Oc1c(O)c(F)c(F)c(F)c1F]

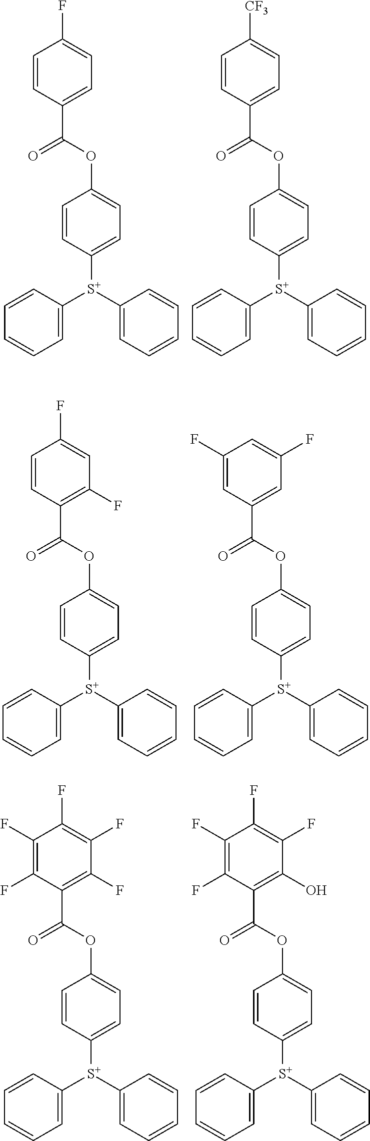 [SMILES: O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F ; O=C(Oc1ccc([S+](c2ccccc2)c2ccccc2)cc1)c1cc(F)cc(F)c1 ; O=C(Oc1ccc([S+](c2ccccc2)c2ccccc2)cc1)c1c(F)c(F)c(F)c(F)c1F ; O=C(Oc1ccc([S+](c2ccccc2)c2ccccc2)cc1)c1c(O)c(F)c(F)c(F)c1F]

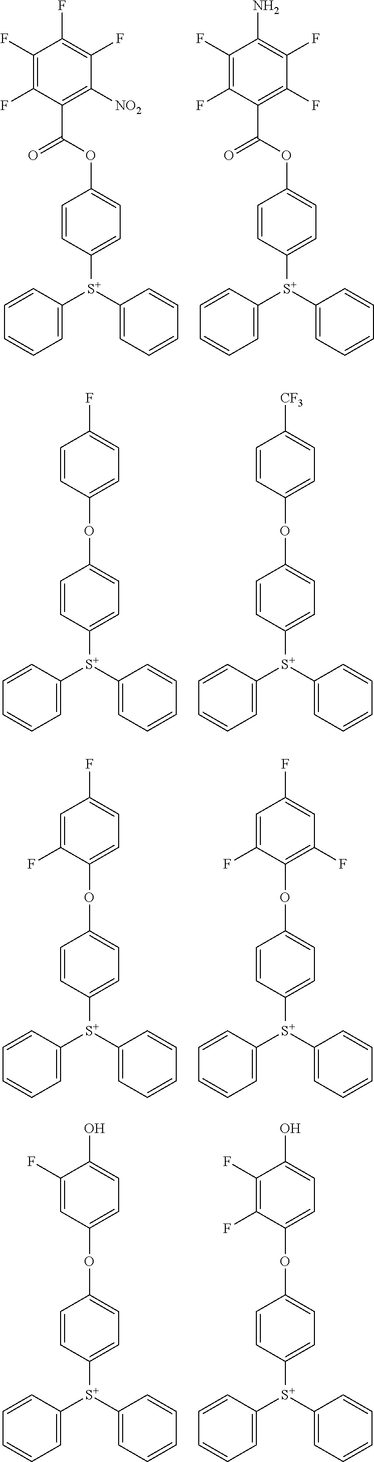

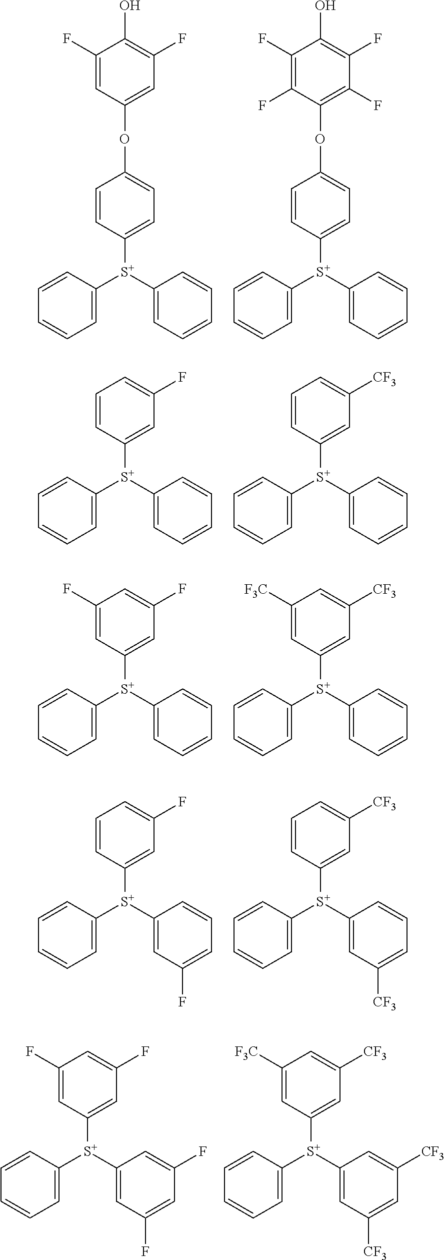

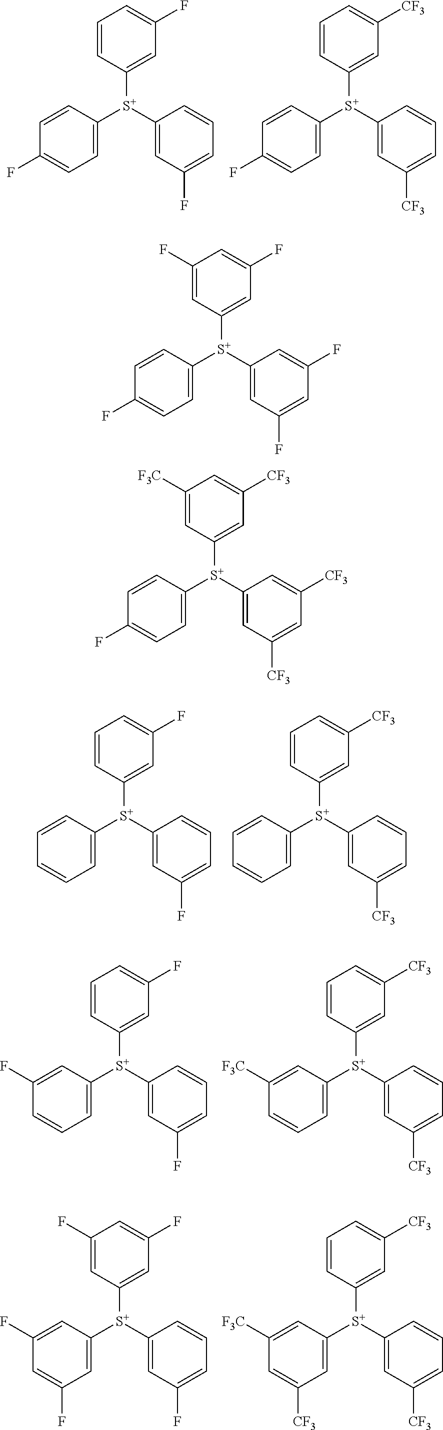

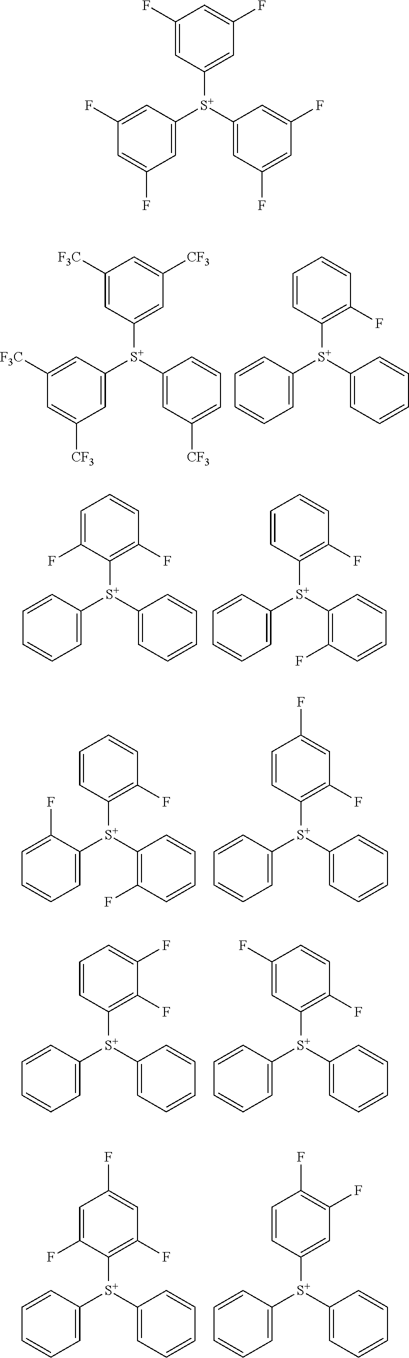

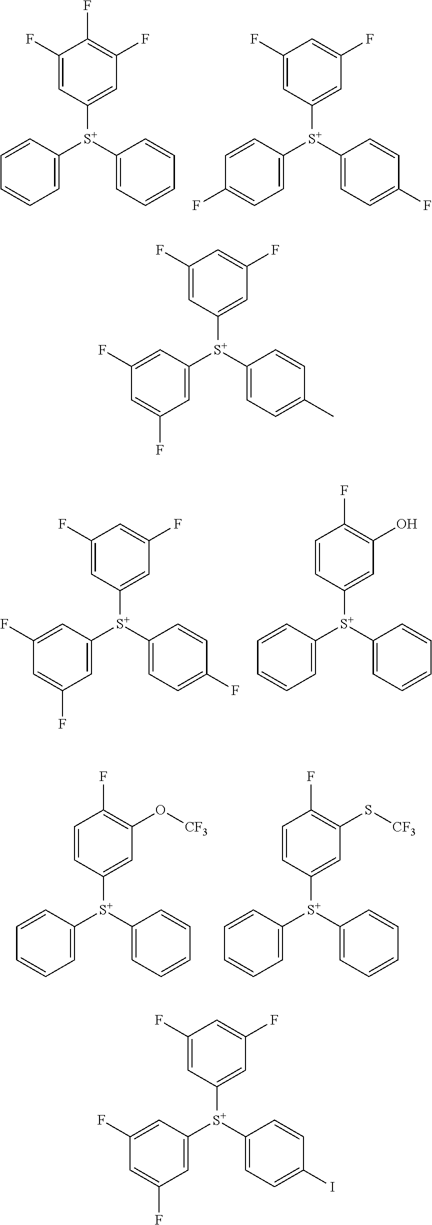

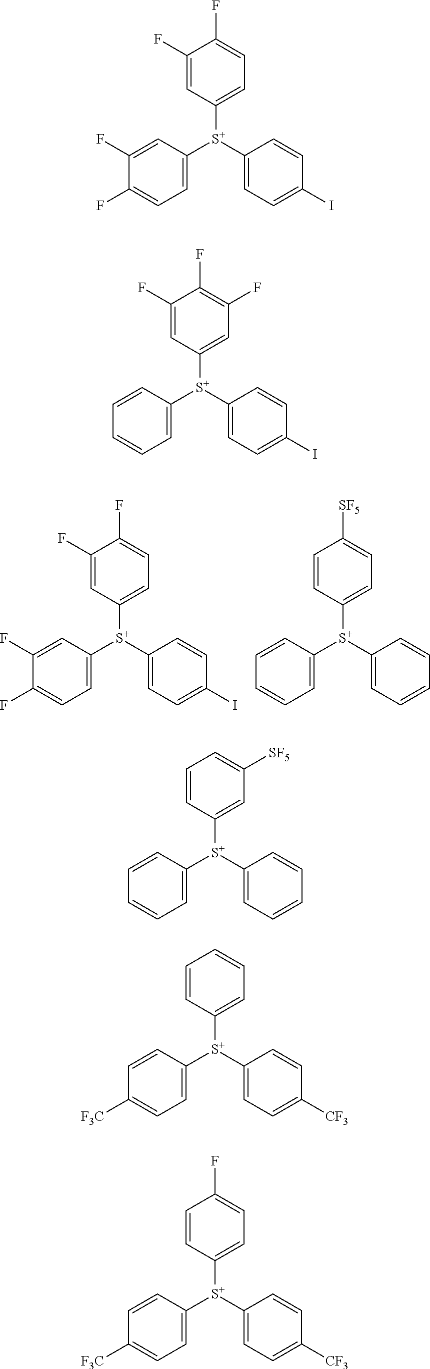

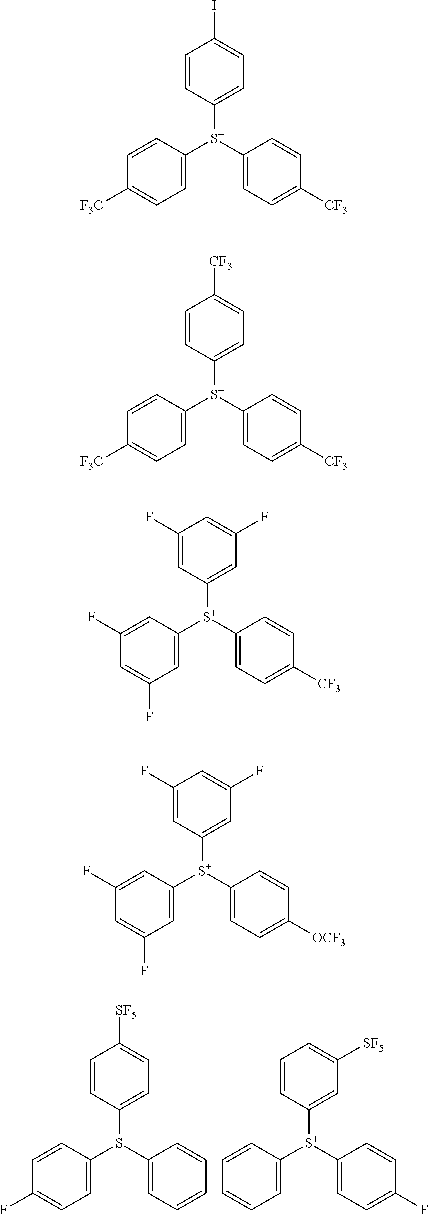

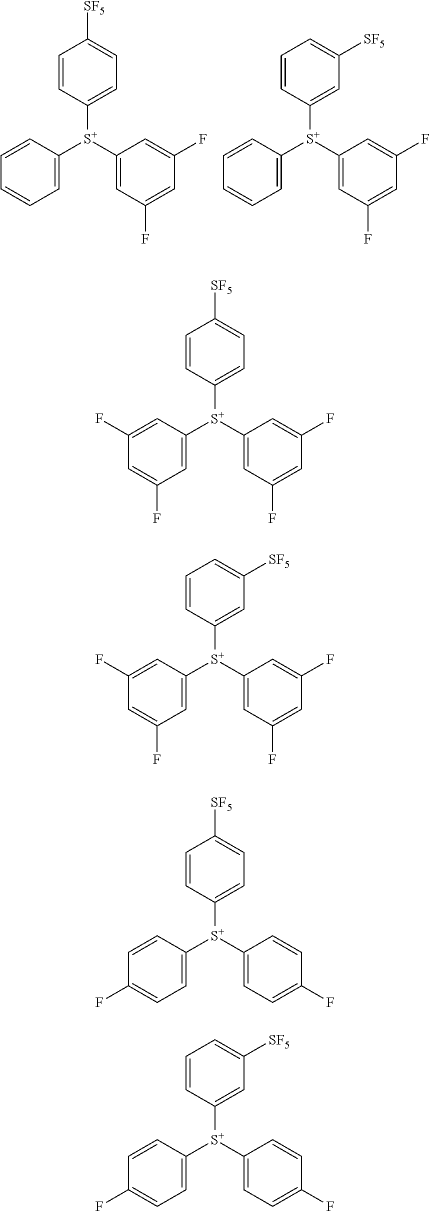

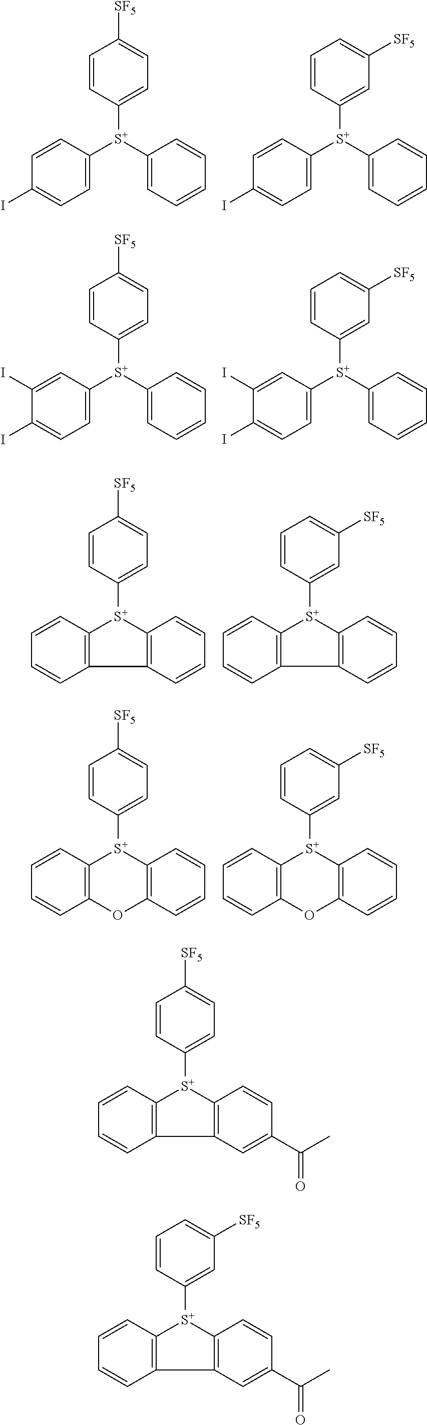

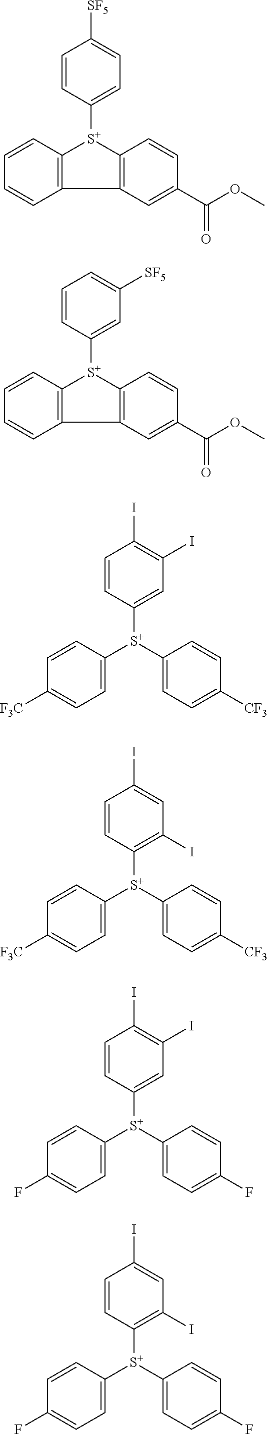

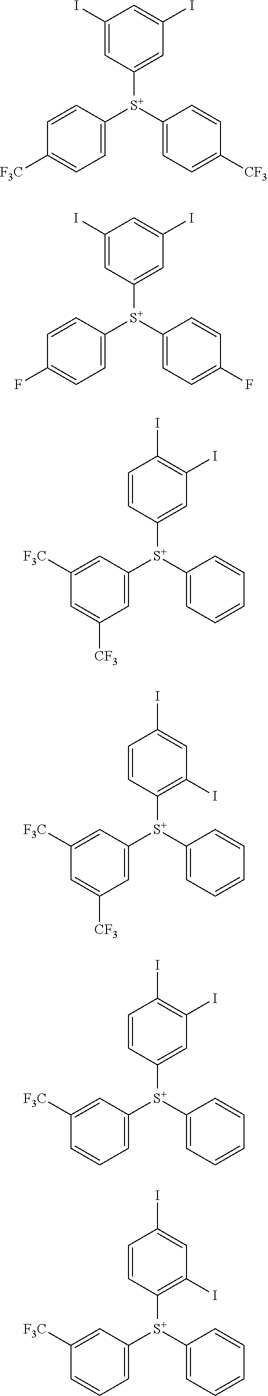 [SMILES: FC(F)(F)c1ccc([S+](c2ccc(C(F)(F)F)cc2)c2cc(I)cc(I)c2)cc1 ; Fc1ccc([S+](c2ccc(F)cc2)c2cc(I)cc(I)c2)cc1 ; FC(F)(F)c1cc([S+](c2ccccc2)c2ccc(I)c(I)c2)cc(C(F)(F)F)c1 ; FC(F)(F)c1cc([S+](c2ccccc2)c2ccc(I)cc2I)cc(C(F)(F)F)c1 ; FC(F)(F)c1cccc([S+](c2ccccc2)c2ccc(I)c(I)c2)c1 ; FC(F)(F)c1cccc([S+](c2ccccc2)c2ccc(I)cc2I)c1]

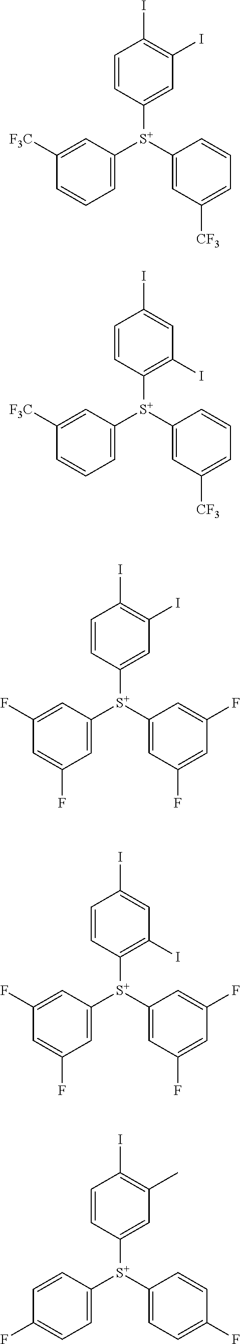 [SMILES: FC(F)(F)c1cccc([S+](c2cccc(C(F)(F)F)c2)c2ccc(I)c(I)c2)c1 ; FC(F)(F)c1cccc([S+](c2cccc(C(F)(F)F)c2)c2ccc(I)cc2I)c1 ; Fc1cc(F)cc([S+](c2cc(F)cc(F)c2)c2ccc(I)c(I)c2)c1 ; Fc1cc(F)cc([S+](c2cc(F)cc(F)c2)c2ccc(I)cc2I)c1 ; Cc1cc([S+](c2ccc(F)cc2)c2ccc(F)cc2)ccc1I]

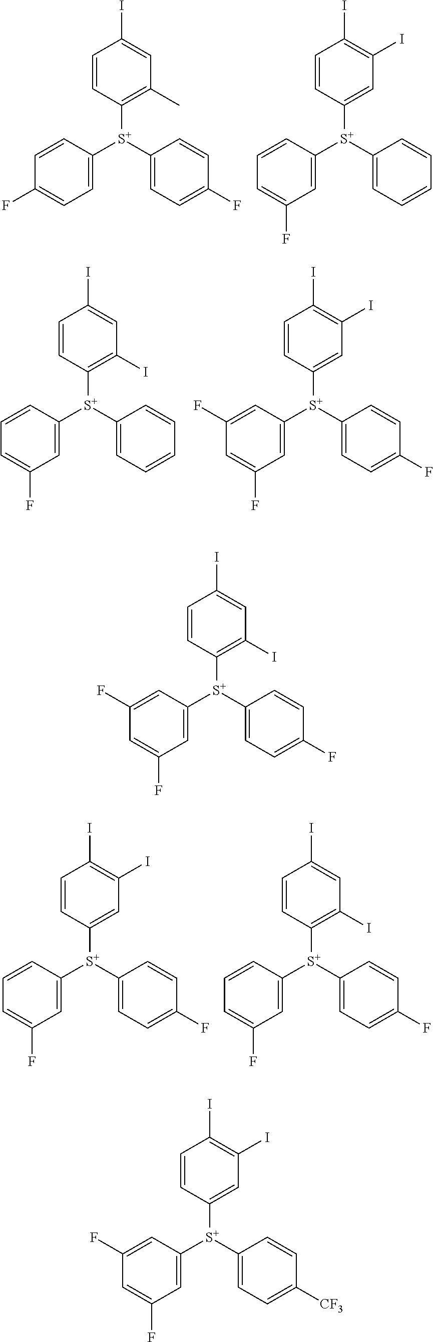

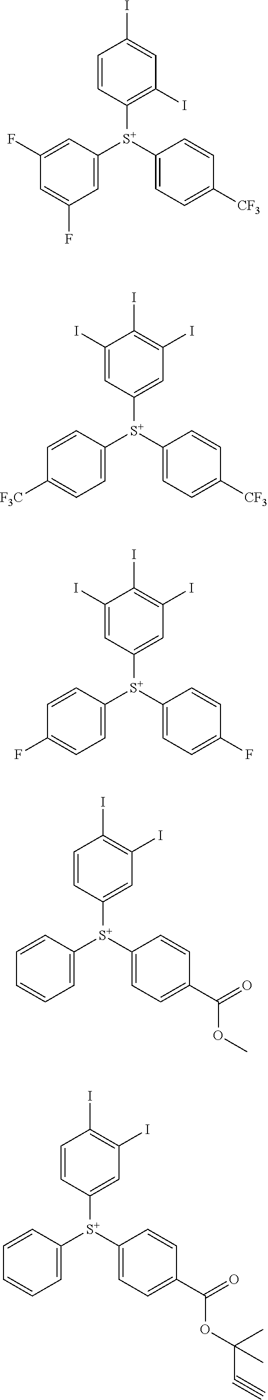 [SMILES: Fc1cc(F)cc([S+](c2ccc(C(F)(F)F)cc2)c2ccc(I)cc2I)c1 ; FC(F)(F)c1ccc([S+](c2ccc(C(F)(F)F)cc2)c2cc(I)c(I)c(I)c2)cc1 ; Fc1ccc([S+](c2ccc(F)cc2)c2cc(I)c(I)c(I)c2)cc1 ; COC(=O)c1ccc([S+](c2ccccc2)c2ccc(I)c(I)c2)cc1 ; C#CC(C)(C)OC(=O)c1ccc([S+](c2ccccc2)c2ccc(I)c(I)c2)cc1]

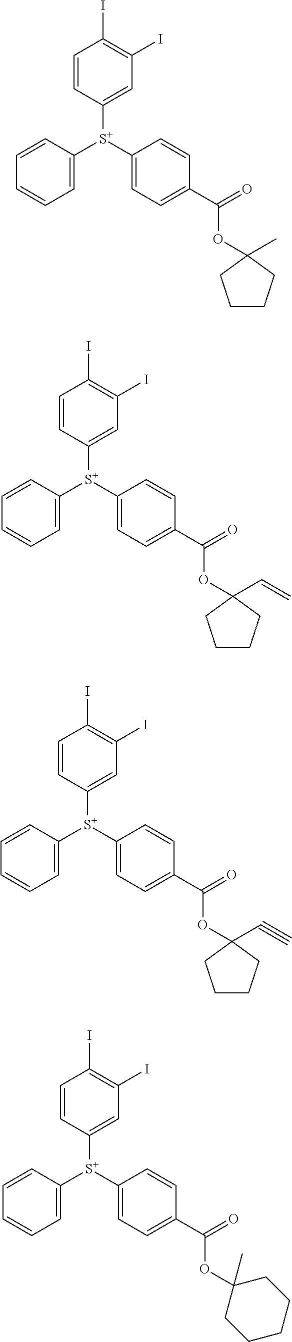 [SMILES: CC1(OC(=O)c2ccc([S+](c3ccccc3)c3ccc(I)c(I)c3)cc2)CCCC1 ; C=CC1(OC(=O)c2ccc([S+](c3ccccc3)c3ccc(I)c(I)c3)cc2)CCCC1 ; C#CC1(OC(=O)c2ccc([S+](c3ccccc3)c3ccc(I)c(I)c3)cc2)CCCC1 ; CC1(OC(=O)c2ccc([S+](c3ccccc3)c3ccc(I)c(I)c3)cc2)CCCCC1]

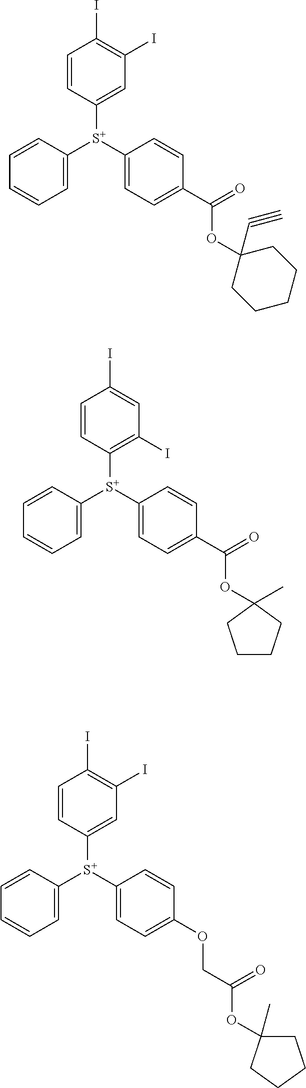 [SMILES: C#CC1(OC(=O)c2ccc([S+](c3ccccc3)c3ccc(I)c(I)c3)cc2)CCCCC1 ; CC1(OC(=O)c2ccc([S+](c3ccccc3)c3ccc(I)cc3I)cc2)CCCC1 ; CC1(OC(=O)COc2ccc([S+](c3ccccc3)c3ccc(I)c(I)c3)cc2)CCCC1]

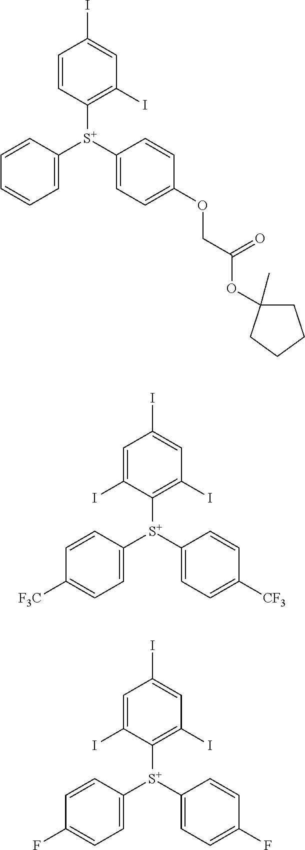 [SMILES: CC1(OC(=O)COc2ccc([S+](c3ccccc3)c3ccc(I)cc3I)cc2)CCCC1 ; FC(F)(F)c1ccc([S+](c2ccc(C(F)(F)F)cc2)c2c(I)cc(I)cc2I)cc1 ; Fc1ccc([S+](c2ccc(F)cc2)c2c(I)cc(I)cc2I)cc1]

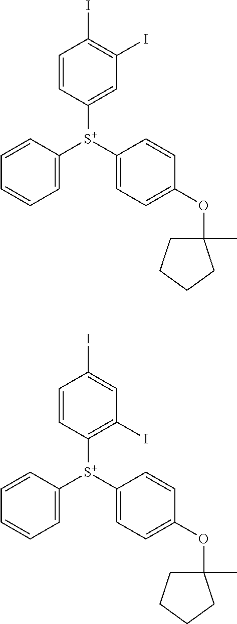 [SMILES: CC1(Oc2ccc([S+](c3ccccc3)c3ccc(I)c(I)c3)cc2)CCCC1 ; CC1(Oc2ccc([S+](c3ccccc3)c3ccc(I)cc3I)cc2)CCCC1]

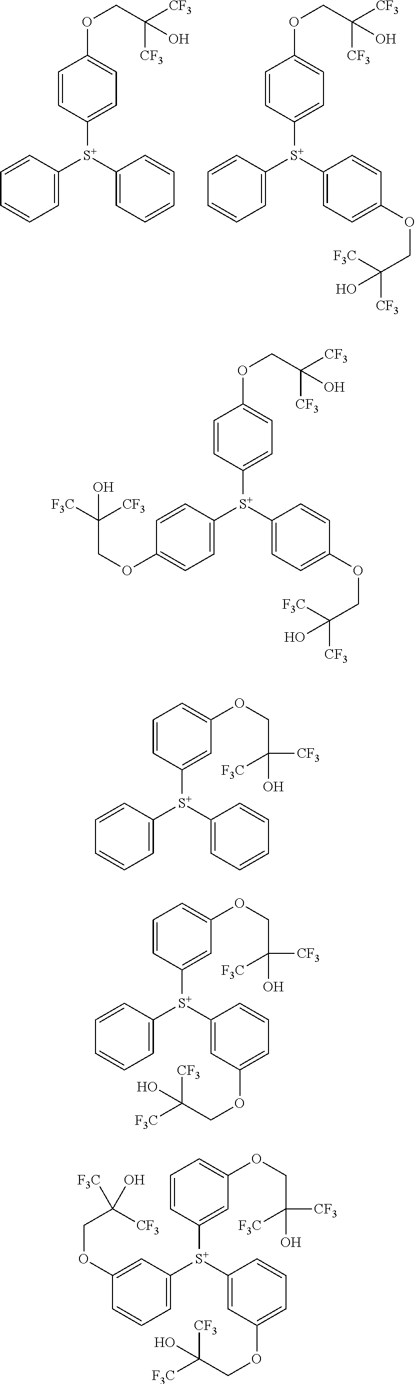

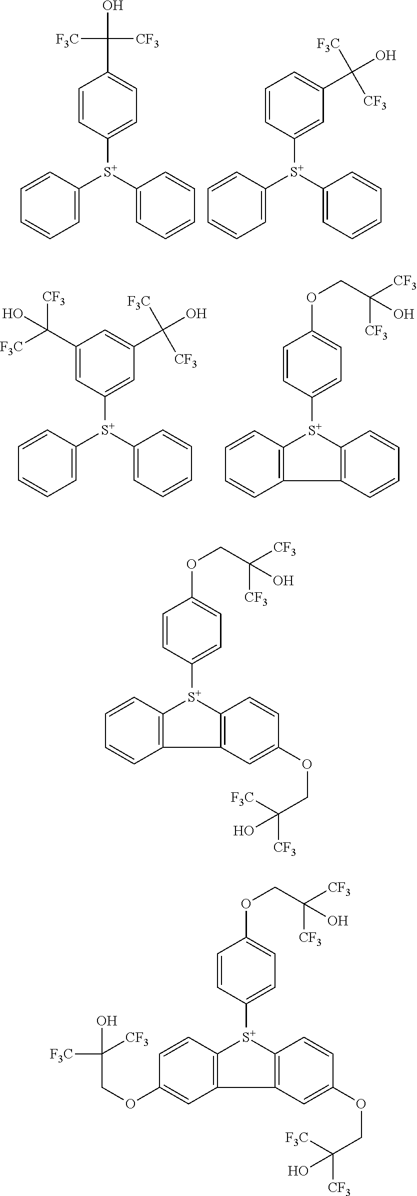 [SMILES: OC(c1ccc([S+](c2ccccc2)c2ccccc2)cc1)(C(F)(F)F)C(F)(F)F ; OC(c1cccc([S+](c2ccccc2)c2ccccc2)c1)(C(F)(F)F)C(F)(F)F ; OC(c1cc([S+](c2ccccc2)c2ccccc2)cc(C(O)(C(F)(F)F)C(F)(F)F)c1)(C(F)(F)F)C(F)(F)F ; OC(COc1ccc(-[s+]2c3ccccc3c3ccccc32)cc1)(C(F)(F)F)C(F)(F)F ; OC(COc1ccc(-[s+]2c3ccccc3c3cc(OCC(O)(C(F)(F)F)C(F)(F)F)ccc32)cc1)(C(F)(F)F)C(F)(F)F ; OC(COc1ccc(-[s+]2c3ccc(OCC(O)(C(F)(F)F)C(F)(F)F)cc3c3cc(OCC(O)(C(F)(F)F)C(F)(F)F)ccc32)cc1)(C(F)(F)F)C(F)(F)F]

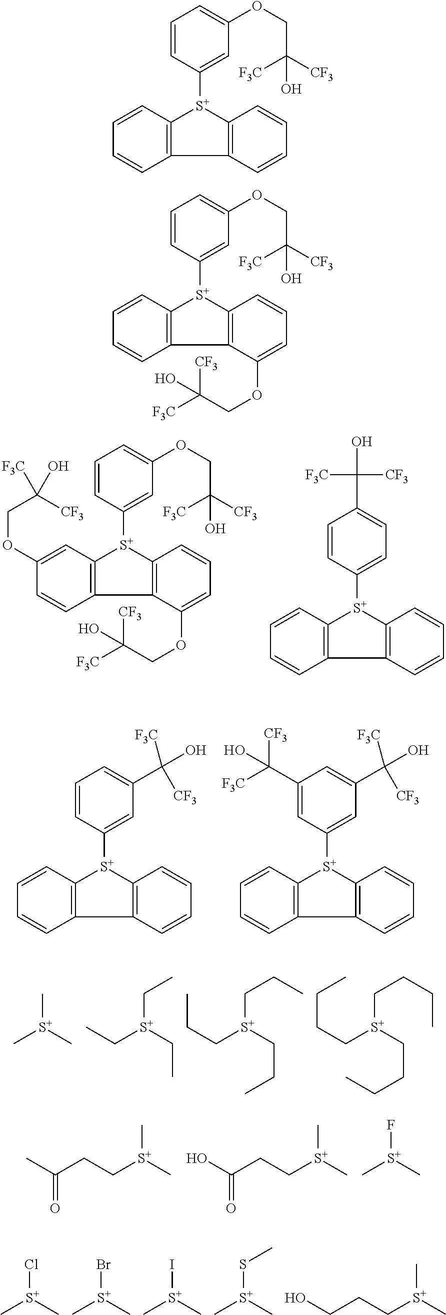

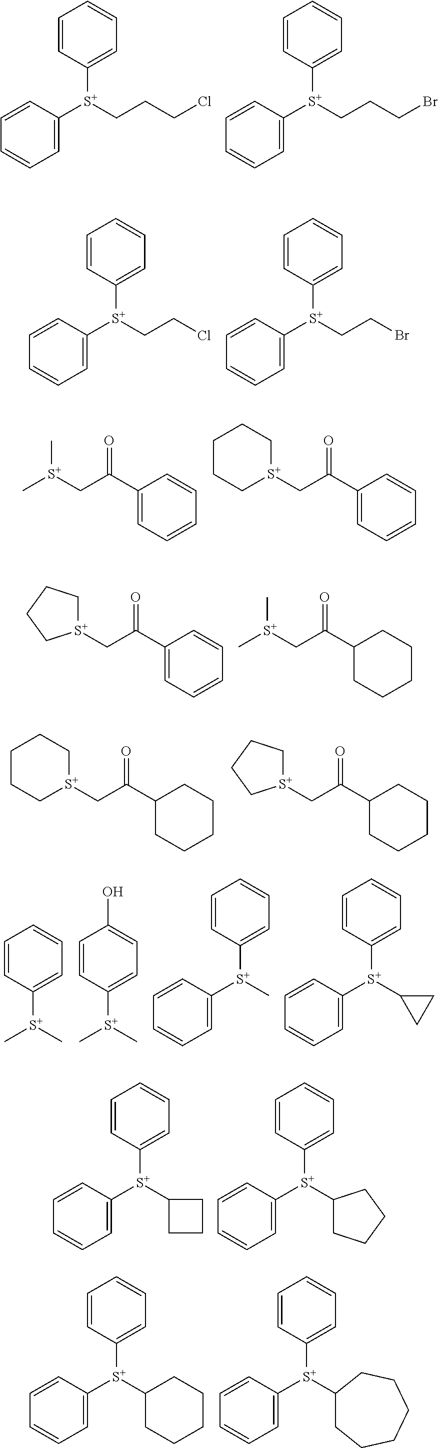

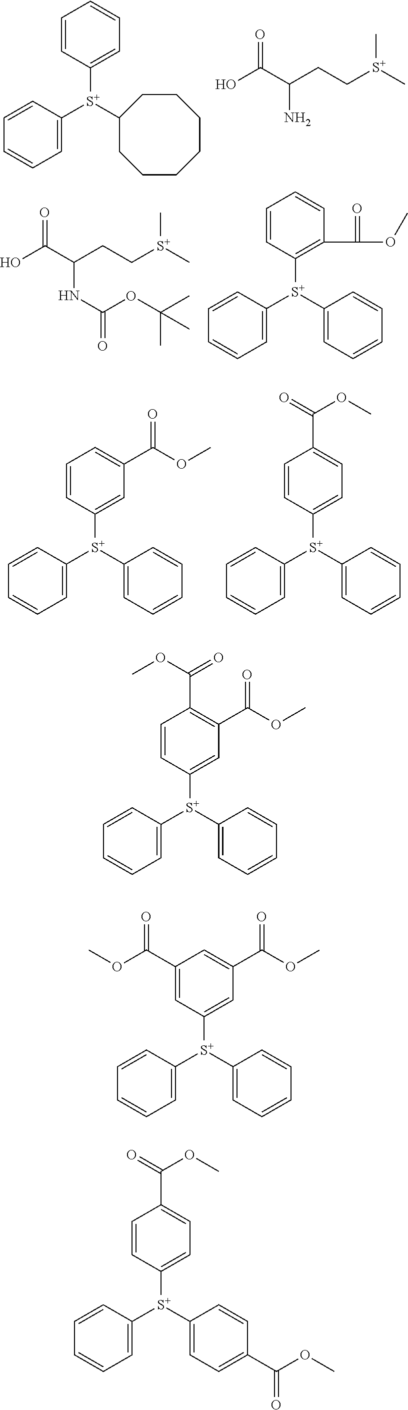

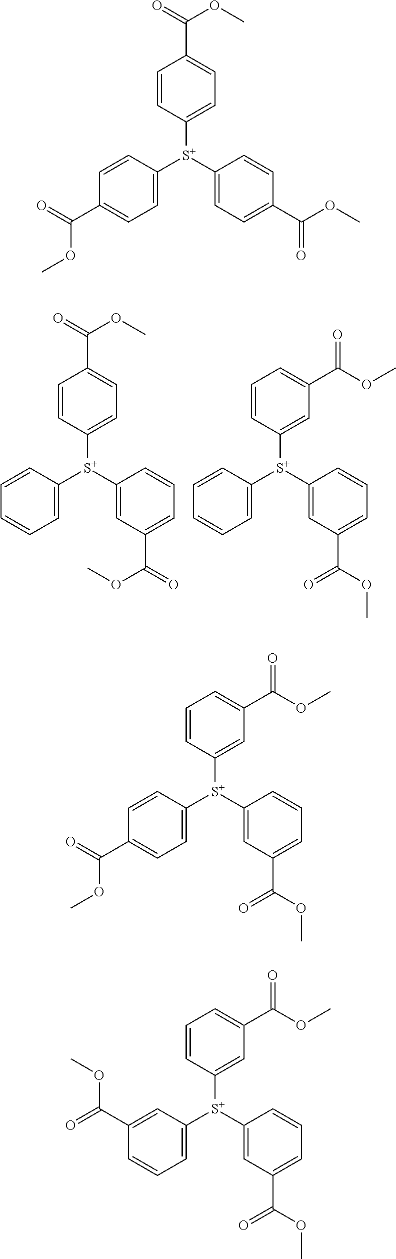 [SMILES: COC(=O)c1ccc([S+](c2ccc(C(=O)OC)cc2)c2ccc(C(=O)OC)cc2)cc1 ; COC(=O)c1ccc([S+](c2ccccc2)c2cccc(C(=O)OC)c2)cc1 ; COC(=O)c1cccc([S+](c2ccccc2)c2cccc(C(=O)OC)c2)c1 ; COC(=O)c1ccc([S+](c2cccc(C(=O)OC)c2)c2cccc(C(=O)OC)c2)cc1 ; COC(=O)c1cccc([S+](c2cccc(C(=O)OC)c2)c2cccc(C(=O)OC)c2)c1]

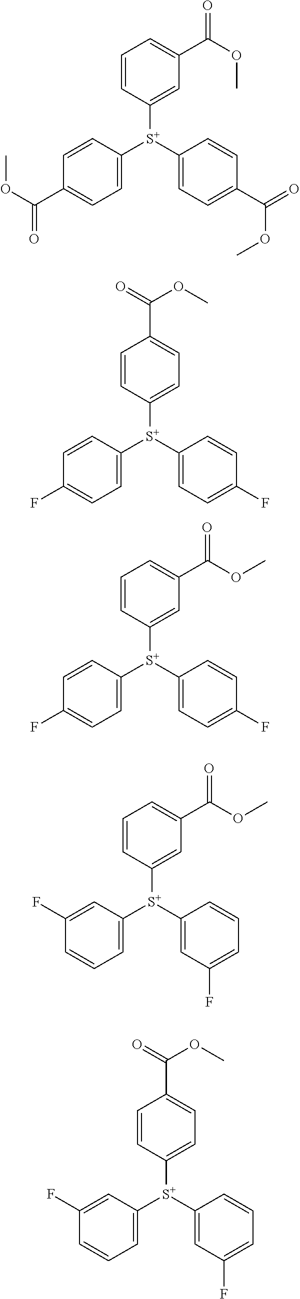 [SMILES: COC(=O)c1ccc([S+](c2ccc(C(=O)OC)cc2)c2cccc(C(=O)OC)c2)cc1 ; COC(=O)c1ccc([S+](c2ccc(F)cc2)c2ccc(F)cc2)cc1 ; COC(=O)c1cccc([S+](c2ccc(F)cc2)c2ccc(F)cc2)c1 ; COC(=O)c1cccc([S+](c2cccc(F)c2)c2cccc(F)c2)c1 ; COC(=O)c1ccc([S+](c2cccc(F)c2)c2cccc(F)c2)cc1]

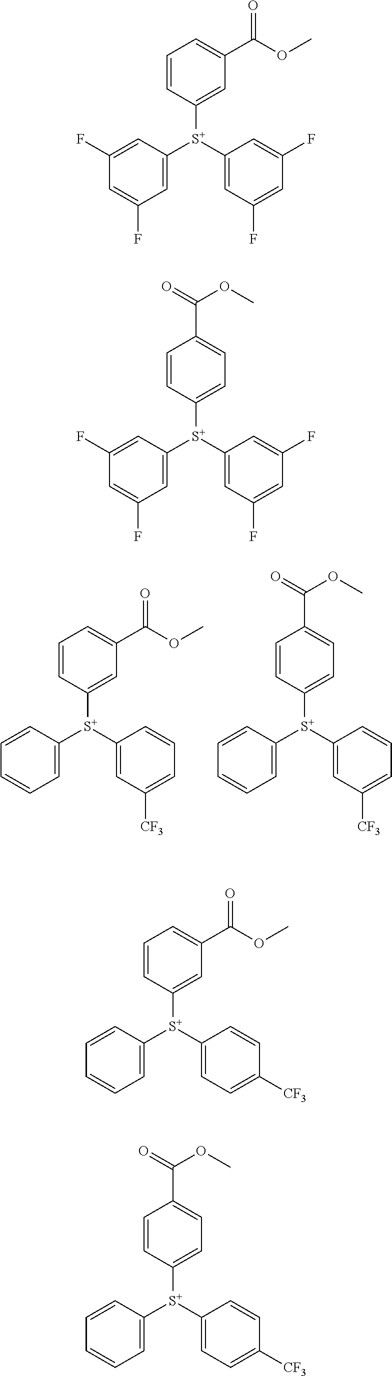 [SMILES: COC(=O)c1cccc([S+](c2cc(F)cc(F)c2)c2cc(F)cc(F)c2)c1 ; COC(=O)c1ccc([S+](c2cc(F)cc(F)c2)c2cc(F)cc(F)c2)cc1 ; COC(=O)c1cccc([S+](c2ccccc2)c2cccc(C(F)(F)F)c2)c1 ; COC(=O)c1ccc([S+](c2ccccc2)c2cccc(C(F)(F)F)c2)cc1 ; COC(=O)c1cccc([S+](c2ccccc2)c2ccc(C(F)(F)F)cc2)c1 ; COC(=O)c1ccc([S+](c2ccccc2)c2ccc(C(F)(F)F)cc2)cc1]

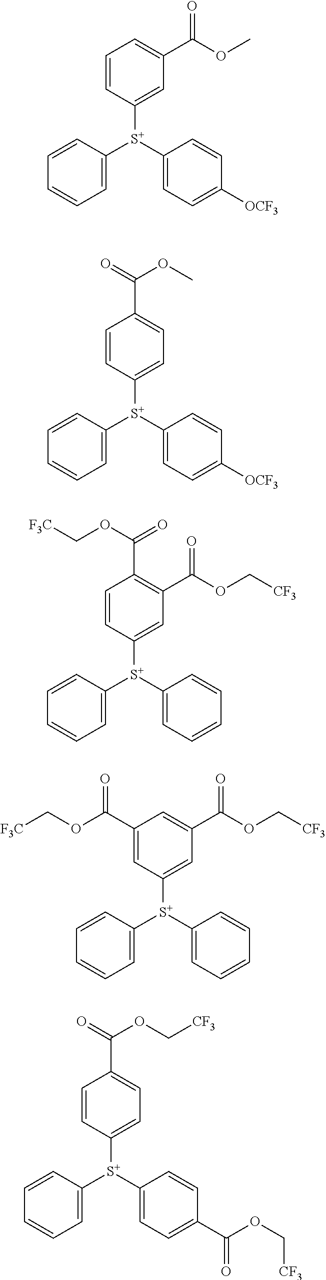 [SMILES: COC(=O)c1cccc([S+](c2ccccc2)c2ccc(OC(F)(F)F)cc2)c1 ; COC(=O)c1ccc([S+](c2ccccc2)c2ccc(OC(F)(F)F)cc2)cc1 ; O=C(OCC(F)(F)F)c1ccc([S+](c2ccccc2)c2ccccc2)cc1C(=O)OCC(F)(F)F ; O=C(OCC(F)(F)F)c1cc(C(=O)OCC(F)(F)F)cc([S+](c2ccccc2)c2ccccc2)c1 ; O=C(OCC(F)(F)F)c1ccc([S+](c2ccccc2)c2ccc(C(=O)OCC(F)(F)F)cc2)cc1]

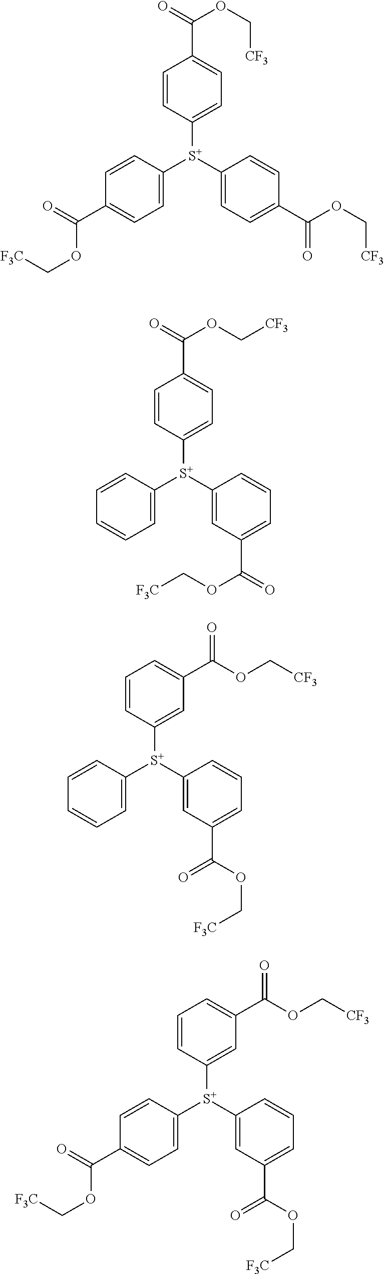 [SMILES: O=C(OCC(F)(F)F)c1ccc([S+](c2ccc(C(=O)OCC(F)(F)F)cc2)c2ccc(C(=O)OCC(F)(F)F)cc2)cc1 ; O=C(OCC(F)(F)F)c1ccc([S+](c2ccccc2)c2cccc(C(=O)OCC(F)(F)F)c2)cc1 ; O=C(OCC(F)(F)F)c1cccc([S+](c2ccccc2)c2cccc(C(=O)OCC(F)(F)F)c2)c1 ; O=C(OCC(F)(F)F)c1ccc([S+](c2cccc(C(=O)OCC(F)(F)F)c2)c2cccc(C(=O)OCC(F)(F)F)c2)cc1]

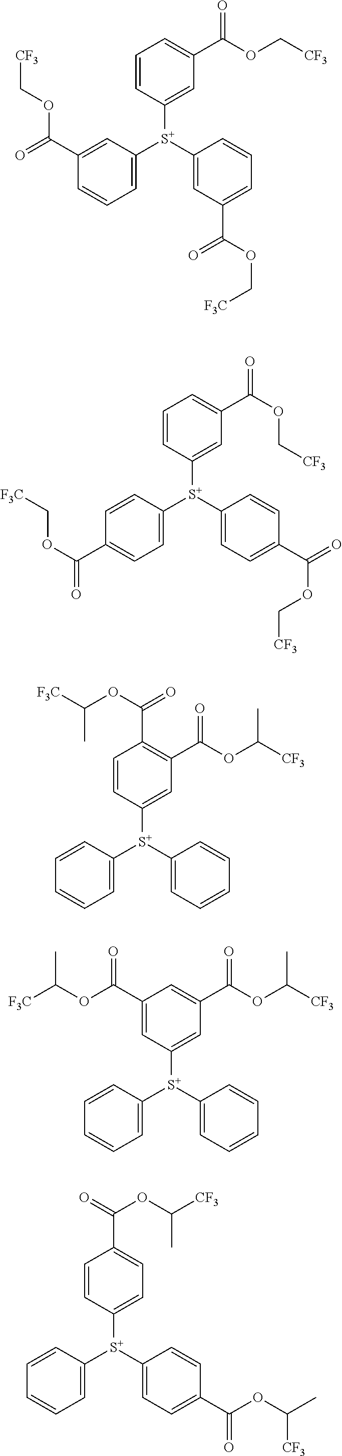 [SMILES: O=C(OCC(F)(F)F)c1cccc([S+](c2cccc(C(=O)OCC(F)(F)F)c2)c2cccc(C(=O)OCC(F)(F)F)c2)c1 ; O=C(OCC(F)(F)F)c1ccc([S+](c2ccc(C(=O)OCC(F)(F)F)cc2)c2cccc(C(=O)OCC(F)(F)F)c2)cc1 ; CC(OC(=O)c1ccc([S+](c2ccccc2)c2ccccc2)cc1C(=O)OC(C)C(F)(F)F)C(F)(F)F ; CC(OC(=O)c1cc(C(=O)OC(C)C(F)(F)F)cc([S+](c2ccccc2)c2ccccc2)c1)C(F)(F)F ; CC(OC(=O)c1ccc([S+](c2ccccc2)c2ccc(C(=O)OC(C)C(F)(F)F)cc2)cc1)C(F)(F)F]

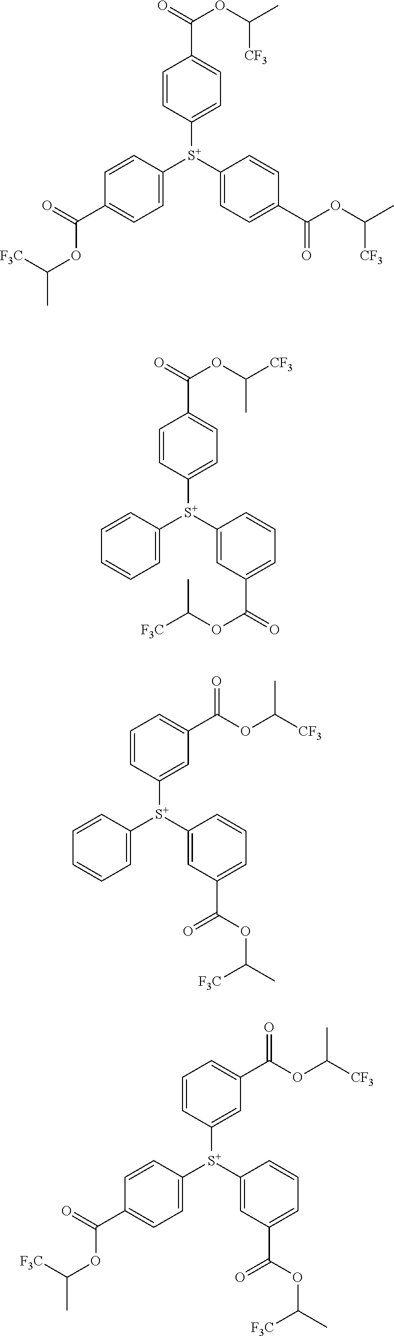 [SMILES: CC(OC(=O)c1ccc([S+](c2ccc(C(=O)OC(C)C(F)(F)F)cc2)c2ccc(C(=O)OC(C)C(F)(F)F)cc2)cc1)C(F)(F)F ; CC(OC(=O)c1ccc([S+](c2ccccc2)c2cccc(C(=O)OC(C)C(F)(F)F)c2)cc1)C(F)(F)F ; CC(OC(=O)c1cccc([S+](c2ccccc2)c2cccc(C(=O)OC(C)C(F)(F)F)c2)c1)C(F)(F)F ; CC(OC(=O)c1ccc([S+](c2cccc(C(=O)OC(C)C(F)(F)F)c2)c2cccc(C(=O)OC(C)C(F)(F)F)c2)cc1)C(F)(F)F]

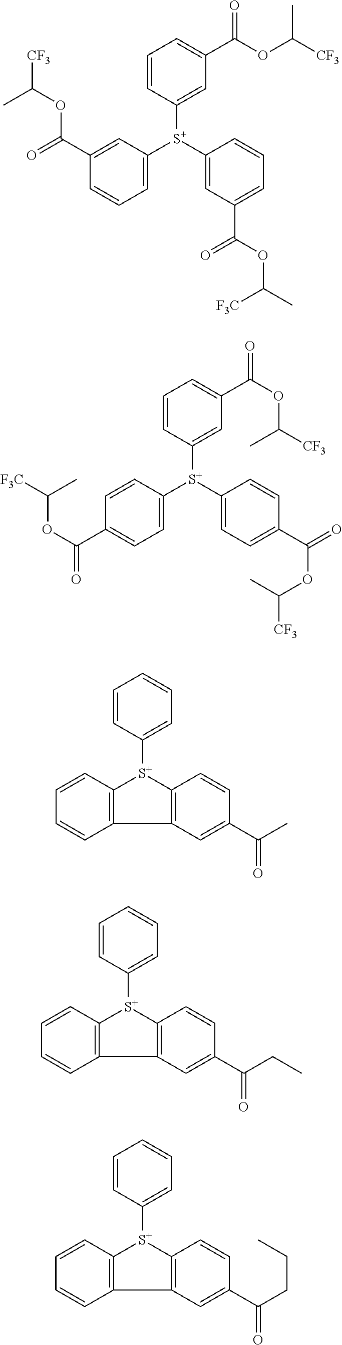 [SMILES: CC(OC(=O)c1cccc([S+](c2cccc(C(=O)OC(C)C(F)(F)F)c2)c2cccc(C(=O)OC(C)C(F)(F)F)c2)c1)C(F)(F)F ; CC(OC(=O)c1ccc([S+](c2ccc(C(=O)OC(C)C(F)(F)F)cc2)c2cccc(C(=O)OC(C)C(F)(F)F)c2)cc1)C(F)(F)F ; CC(=O)c1ccc2c(c1)c1ccccc1[s+]2-c1ccccc1 ; CCC(=O)c1ccc2c(c1)c1ccccc1[s+]2-c1ccccc1 ; CCCC(=O)c1ccc2c(c1)c1ccccc1[s+]2-c1ccccc1]

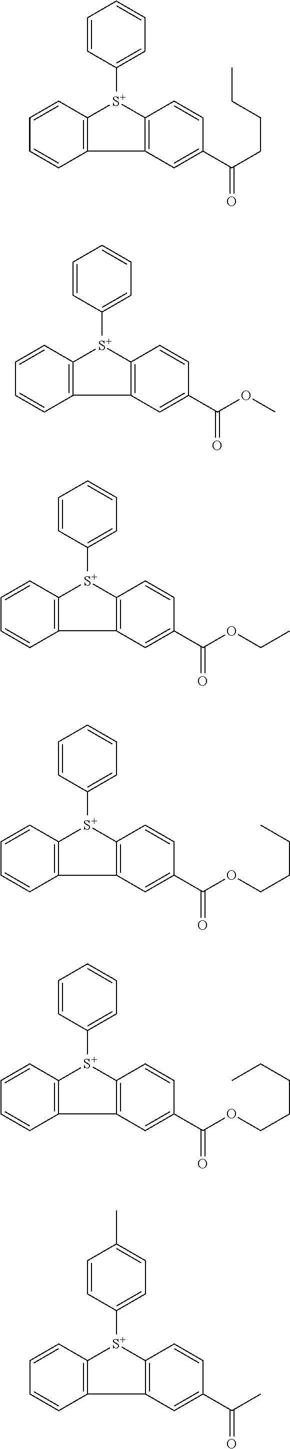 [SMILES: CCCCC(=O)c1ccc2c(c1)c1ccccc1[s+]2-c1ccccc1 ; COC(=O)c1ccc2c(c1)c1ccccc1[s+]2-c1ccccc1 ; CCOC(=O)c1ccc2c(c1)c1ccccc1[s+]2-c1ccccc1 ; CCCCOC(=O)c1ccc2c(c1)c1ccccc1[s+]2-c1ccccc1 ; CCCCCOC(=O)c1ccc2c(c1)c1ccccc1[s+]2-c1ccccc1 ; CC(=O)c1ccc2c(c1)c1ccccc1[s+]2-c1ccc(C)cc1]

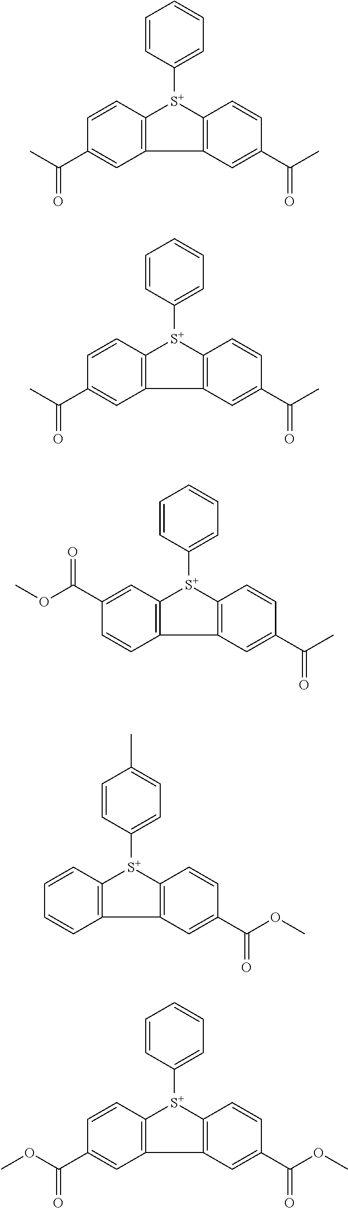

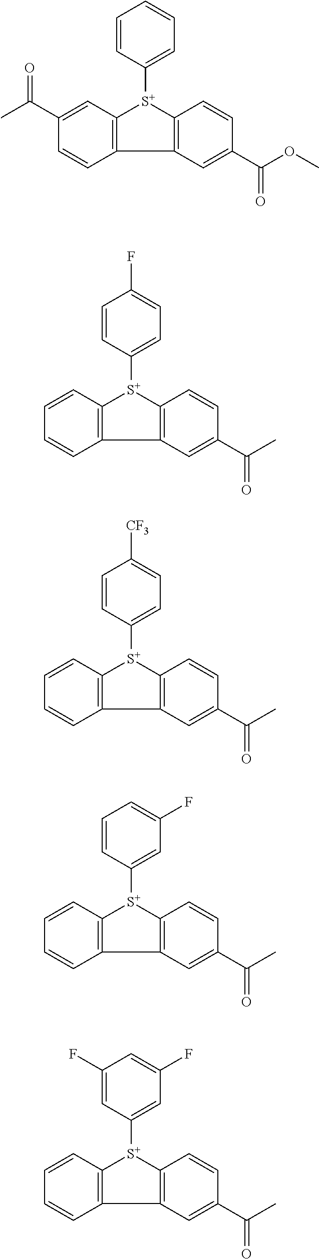 [SMILES: COC(=O)c1ccc2c(c1)c1ccc(C(C)=O)cc1[s+]2-c1ccccc1 ; CC(=O)c1ccc2c(c1)c1ccccc1[s+]2-c1ccc(F)cc1 ; CC(=O)c1ccc2c(c1)c1ccccc1[s+]2-c1ccc(C(F)(F)F)cc1 ; CC(=O)c1ccc2c(c1)c1ccccc1[s+]2-c1cccc(F)c1 ; CC(=O)c1ccc2c(c1)c1ccccc1[s+]2-c1cc(F)cc(F)c1]

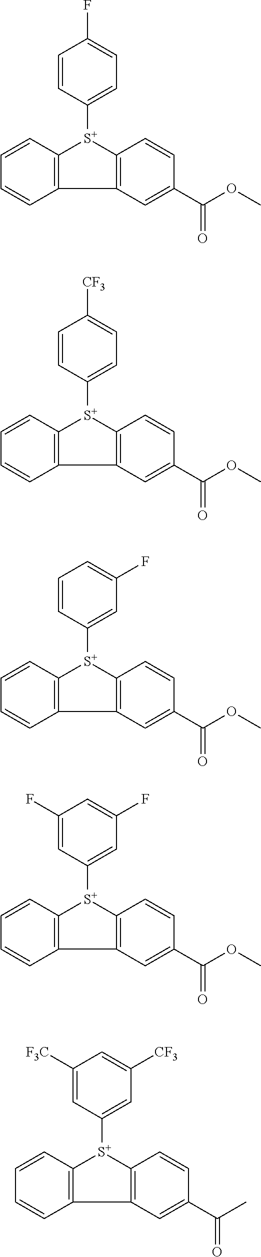 [SMILES: COC(=O)c1ccc2c(c1)c1ccccc1[s+]2-c1ccc(F)cc1 ; COC(=O)c1ccc2c(c1)c1ccccc1[s+]2-c1ccc(C(F)(F)F)cc1 ; COC(=O)c1ccc2c(c1)c1ccccc1[s+]2-c1cccc(F)c1 ; COC(=O)c1ccc2c(c1)c1ccccc1[s+]2-c1cc(F)cc(F)c1 ; CC(=O)c1ccc2c(c1)c1ccccc1[s+]2-c1cc(C(F)(F)F)cc(C(F)(F)F)c1]

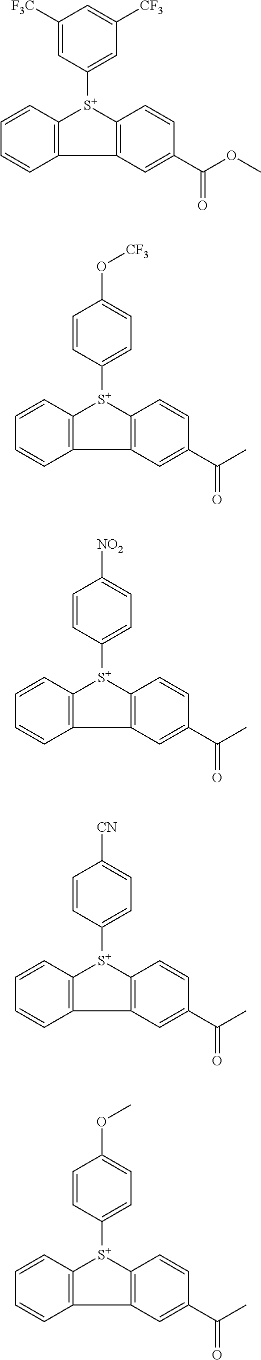 [SMILES: COC(=O)c1ccc2c(c1)c1ccccc1[s+]2-c1cc(C(F)(F)F)cc(C(F)(F)F)c1 ; CC(=O)c1ccc2c(c1)c1ccccc1[s+]2-c1ccc(OC(F)(F)F)cc1 ; CC(=O)c1ccc2c(c1)c1ccccc1[s+]2-c1ccc([N+](=O)[O-])cc1 ; CC(=O)c1ccc2c(c1)c1ccccc1[s+]2-c1ccc(C#N)cc1 ; COc1ccc(-[s+]2c3ccccc3c3cc(C(C)=O)ccc32)cc1]

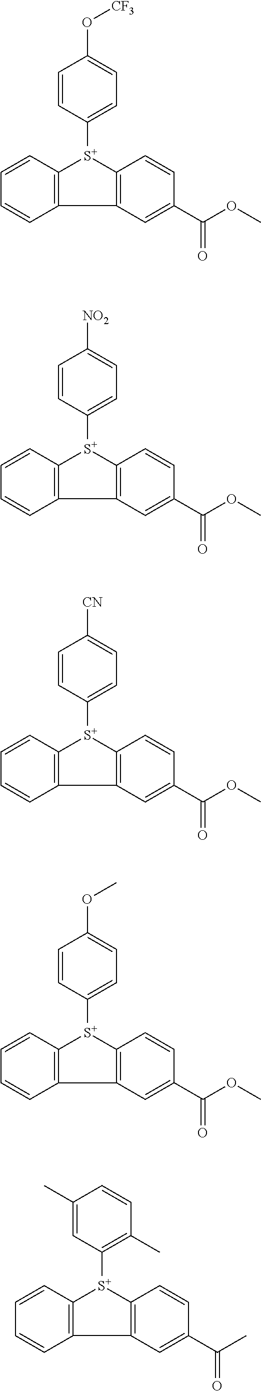 [SMILES: COC(=O)c1ccc2c(c1)c1ccccc1[s+]2-c1ccc(OC(F)(F)F)cc1 ; COC(=O)c1ccc2c(c1)c1ccccc1[s+]2-c1ccc([N+](=O)[O-])cc1 ; COC(=O)c1ccc2c(c1)c1ccccc1[s+]2-c1ccc(C#N)cc1 ; COC(=O)c1ccc2c(c1)c1ccccc1[s+]2-c1ccc(OC)cc1 ; CC(=O)c1ccc2c(c1)c1ccccc1[s+]2-c1cc(C)ccc1C]

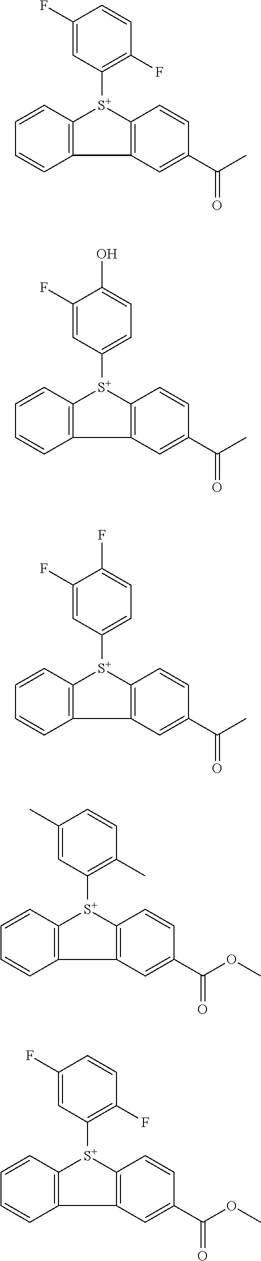 [SMILES: CC(=O)c1ccc2c(c1)c1ccccc1[s+]2-c1cc(F)ccc1F ; CC(=O)c1ccc2c(c1)c1ccccc1[s+]2-c1ccc(O)c(F)c1 ; CC(=O)c1ccc2c(c1)c1ccccc1[s+]2-c1ccc(F)c(F)c1 ; COC(=O)c1ccc2c(c1)c1ccccc1[s+]2-c1cc(C)ccc1C ; COC(=O)c1ccc2c(c1)c1ccccc1[s+]2-c1cc(F)ccc1F]

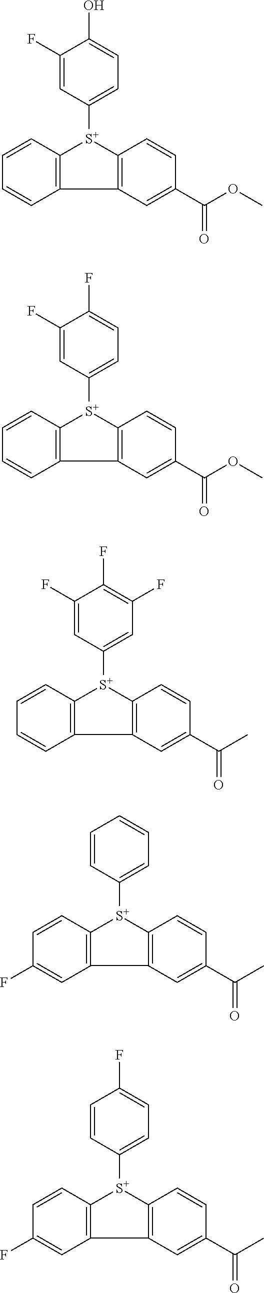 [SMILES: COC(=O)c1ccc2c(c1)c1ccccc1[s+]2-c1ccc(O)c(F)c1 ; COC(=O)c1ccc2c(c1)c1ccccc1[s+]2-c1ccc(F)c(F)c1 ; CC(=O)c1ccc2c(c1)c1ccccc1[s+]2-c1cc(F)c(F)c(F)c1 ; CC(=O)c1ccc2c(c1)c1cc(F)ccc1[s+]2-c1ccccc1 ; CC(=O)c1ccc2c(c1)c1cc(F)ccc1[s+]2-c1ccc(F)cc1]

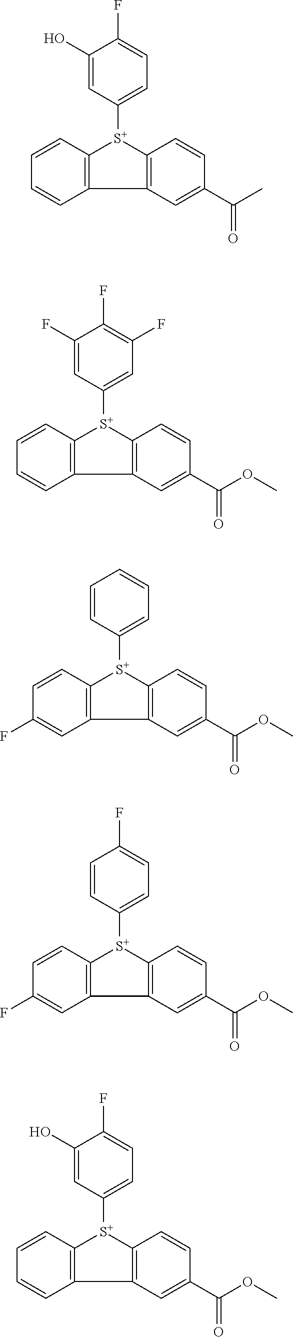 [SMILES: CC(=O)c1ccc2c(c1)c1ccccc1[s+]2-c1ccc(F)c(O)c1 ; COC(=O)c1ccc2c(c1)c1ccccc1[s+]2-c1cc(F)c(F)c(F)c1 ; COC(=O)c1ccc2c(c1)c1cc(F)ccc1[s+]2-c1ccccc1 ; COC(=O)c1ccc2c(c1)c1cc(F)ccc1[s+]2-c1ccc(F)cc1 ; COC(=O)c1ccc2c(c1)c1ccccc1[s+]2-c1ccc(F)c(O)c1]

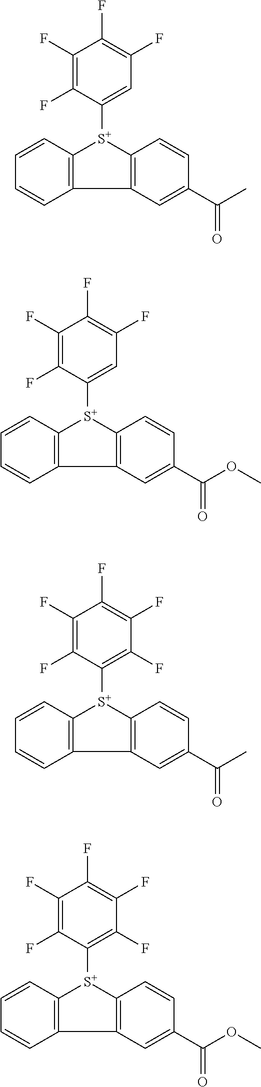 [SMILES: CC(=O)c1ccc2c(c1)c1ccccc1[s+]2-c1cc(F)c(F)c(F)c1F ; COC(=O)c1ccc2c(c1)c1ccccc1[s+]2-c1cc(F)c(F)c(F)c1F ; CC(=O)c1ccc2c(c1)c1ccccc1[s+]2-c1c(F)c(F)c(F)c(F)c1F ; COC(=O)c1ccc2c(c1)c1ccccc1[s+]2-c1c(F)c(F)c(F)c(F)c1F]

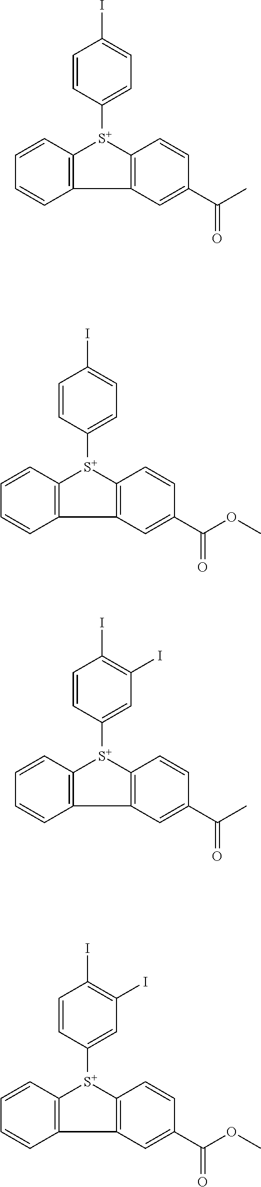 [SMILES: CC(=O)c1ccc2c(c1)c1ccccc1[s+]2-c1ccc(I)cc1 ; COC(=O)c1ccc2c(c1)c1ccccc1[s+]2-c1ccc(I)cc1 ; CC(=O)c1ccc2c(c1)c1ccccc1[s+]2-c1ccc(I)c(I)c1 ; COC(=O)c1ccc2c(c1)c1ccccc1[s+]2-c1ccc(I)c(I)c1]

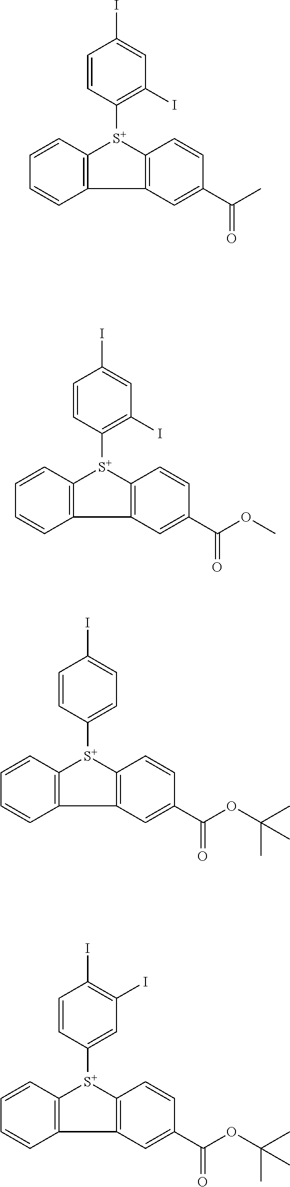 [SMILES: CC(=O)c1ccc2c(c1)c1ccccc1[s+]2-c1ccc(I)cc1I ; COC(=O)c1ccc2c(c1)c1ccccc1[s+]2-c1ccc(I)cc1I ; CC(C)(C)OC(=O)c1ccc2c(c1)c1ccccc1[s+]2-c1ccc(I)cc1 ; CC(C)(C)OC(=O)c1ccc2c(c1)c1ccccc1[s+]2-c1ccc(I)c(I)c1]

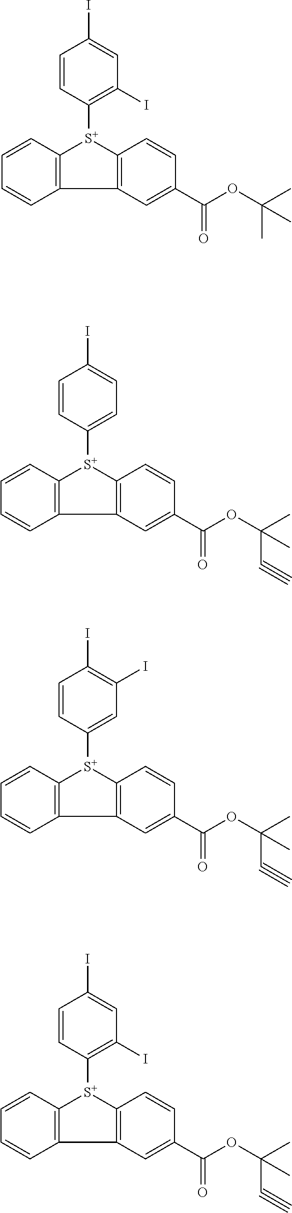 [SMILES: CC(C)(C)OC(=O)c1ccc2c(c1)c1ccccc1[s+]2-c1ccc(I)cc1I ; C#CC(C)(C)OC(=O)c1ccc2c(c1)c1ccccc1[s+]2-c1ccc(I)cc1 ; C#CC(C)(C)OC(=O)c1ccc2c(c1)c1ccccc1[s+]2-c1ccc(I)c(I)c1 ; C#CC(C)(C)OC(=O)c1ccc2c(c1)c1ccccc1[s+]2-c1ccc(I)cc1I]

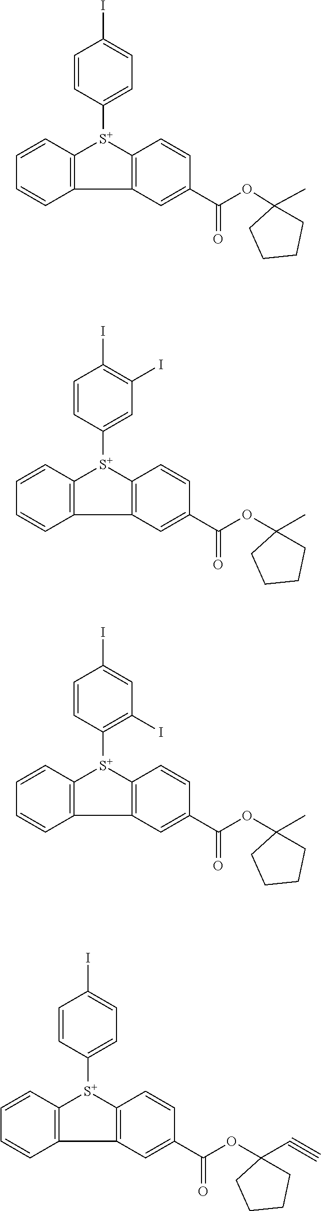 [SMILES: CC1(OC(=O)c2ccc3c(c2)c2ccccc2[s+]3-c2ccc(I)cc2)CCCC1 ; CC1(OC(=O)c2ccc3c(c2)c2ccccc2[s+]3-c2ccc(I)c(I)c2)CCCC1 ; CC1(OC(=O)c2ccc3c(c2)c2ccccc2[s+]3-c2ccc(I)cc2I)CCCC1 ; C#CC1(OC(=O)c2ccc3c(c2)c2ccccc2[s+]3-c2ccc(I)cc2)CCCC1]

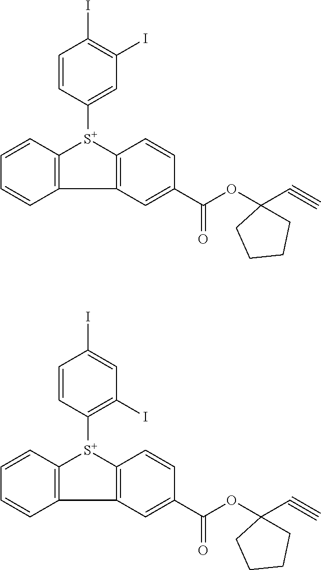 [SMILES: C#CC1(OC(=O)c2ccc3c(c2)c2ccccc2[s+]3-c2ccc(I)c(I)c2)CCCC1 ; C#CC1(OC(=O)c2ccc3c(c2)c2ccccc2[s+]3-c2ccc(I)cc2I)CCCC1]

Examples of the iodonium cation represented by formula M⁺ are shown below, but not limited thereto.

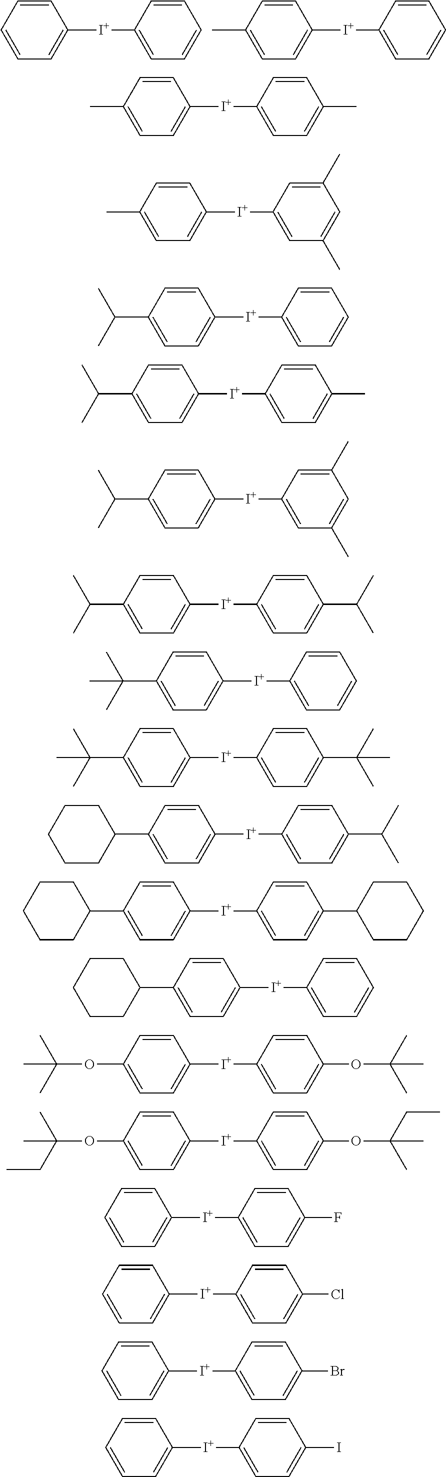

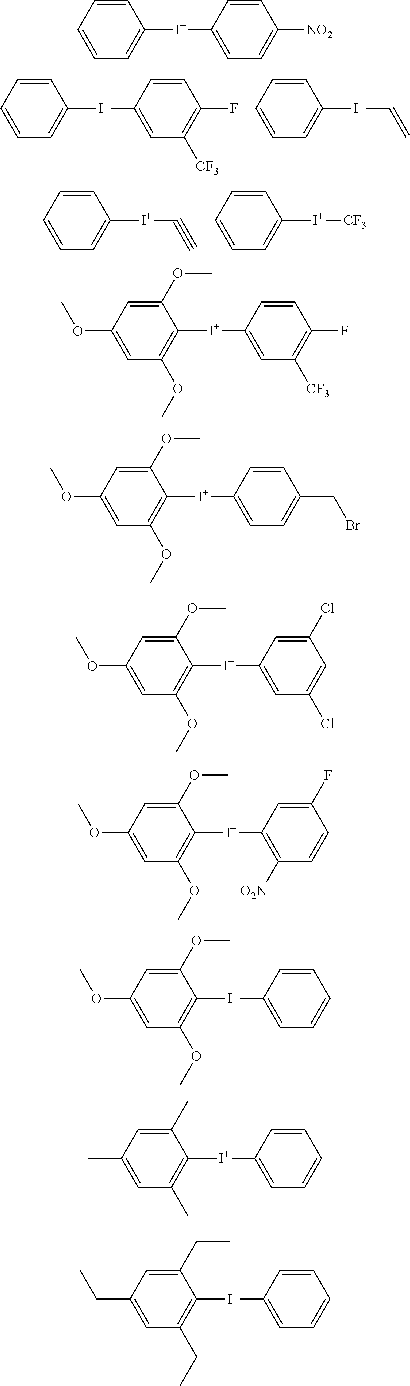

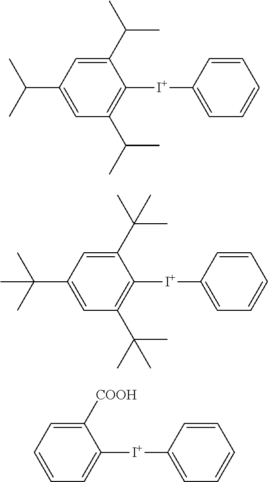 [SMILES: CC(C)c1cc(C(C)C)c([I+]c2ccccc2)c(C(C)C)c1 ; CC(C)(C)c1cc(C(C)(C)C)c([I+]c2ccccc2)c(C(C)(C)C)c1 ; O=C(O)c1ccccc1[I+]c1ccccc1]

Examples of the method for synthesizing a bisonium salt represented by formula (1) include salt exchange between a sulfonium salt or an iodonium salt containing a halide anion and an ammonium salt containing a divalent anion having an arylsulfonate anion structure linked to an aromatic group having an iodine atom or a bromine atom and a carboxylate anion structure bonded to the aromatic group having an iodine atom or a bromine atom, via a linking group having 1 or more carbon atoms.

In the resist composition, the bisonium salt is preferably present in an amount of 0.01 to 1,000 parts by weight, more preferably 0.05 to 500 parts by weight per 100 parts by weight of the base polymer to be described below, in view of sensitivity and acid diffusion-suppressing effect.

### [Base Polymer]

In one preferred embodiment, the resist composition comprises a base polymer. When the resist composition is of positive tone, a base polymer comprising repeat units having an acid labile group is used. The repeat units having an acid labile group are preferably repeat units having the formula (a1) or repeat units having formula (a2). These repeat units are also referred to as repeat units (a1) or (a2).

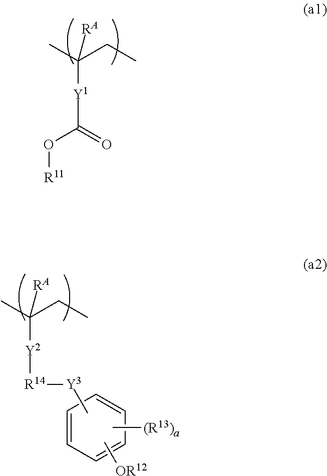

In formulae (a1) and (a2), R^{A} is each independently hydrogen or methyl. Y¹ is a single bond, a phenylene group, a naphthylene group, or a C₁-C₁₂ linking group containing at least one selected from an ester bond, an ether bond and a lactone ring, the phenylene group, the naphthylene group and the linking group may have at least one selected from a hydroxy group, a C₁-C₈ saturated hydrocarbyloxy group and a C₂-C₈ saturated hydrocarbylcarbonyloxy group, Y² is a single bond or an ester bond, Y³ is a single bond, an ether bond or an ester bond, R¹¹ and R¹² are each independently an acid labile group, R¹³ is a C₁-C₄ saturated hydrocarbyl group, a halogen atom, a C₂-C₅ saturated hydrocarbylcarbonyl group, a cyano group, or C₂-C₅ saturated hydrocarbyloxycarbonyl group, R¹⁴ is a single bond or a C₁-C₆ alkanediyl group, the alkanediyl group may contain an ether bond or an ester bond, and a is an integer of 0 to 4.

Examples of the monomer from which repeat units a1 are derived are shown below, but not limited thereto. Herein R^{A} and R¹¹ are as defined above.

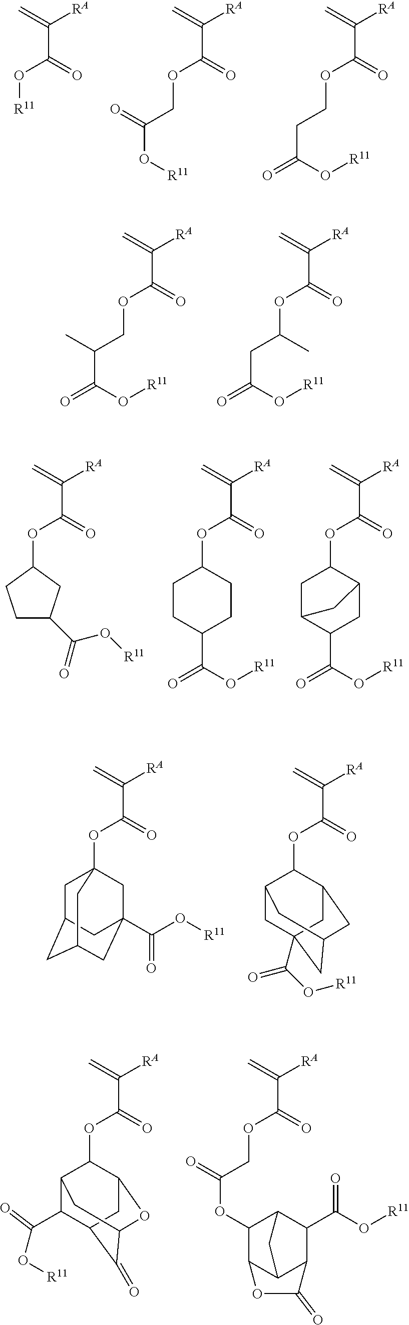

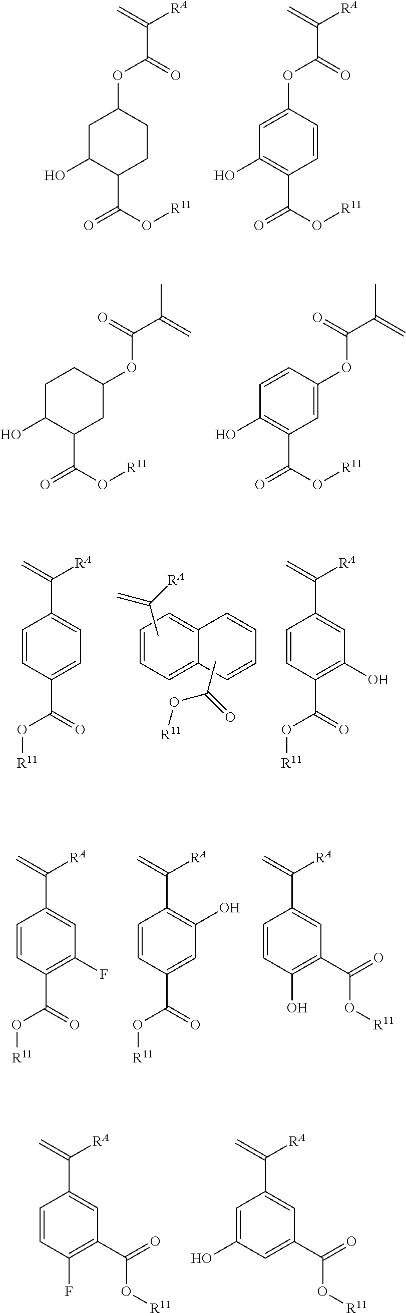

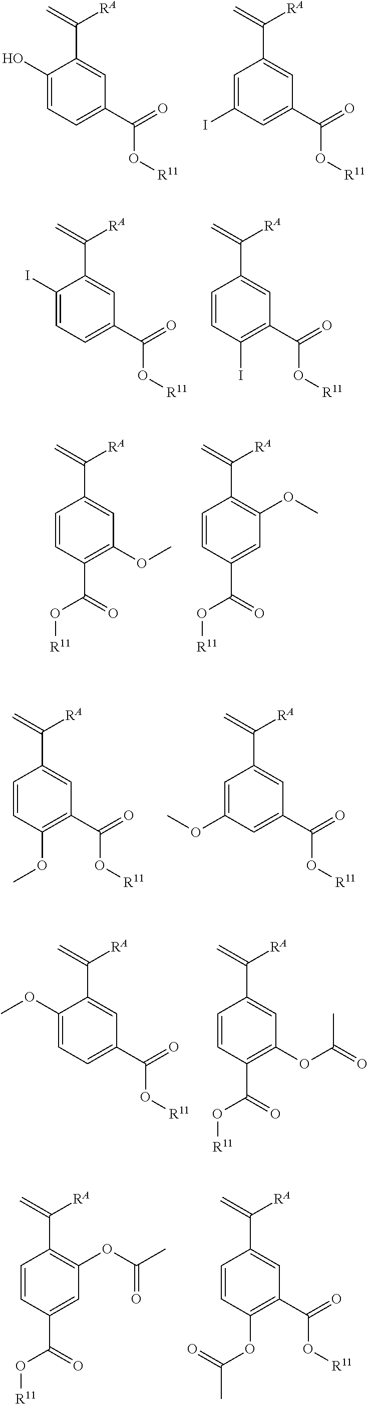

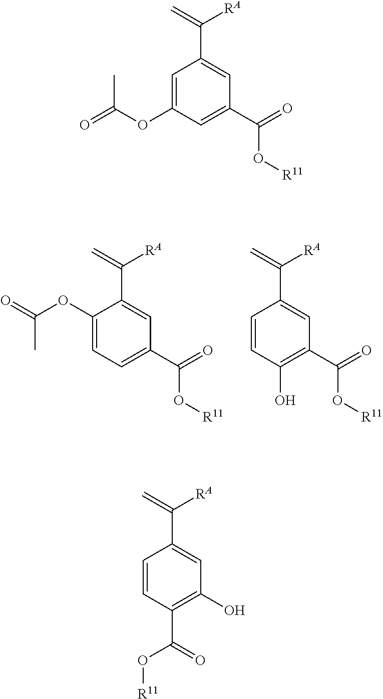

Specific examples of the monomer from which repeat units a2 are derived are shown below, but not limited thereto. Herein R^{A} and R¹² are as defined above.

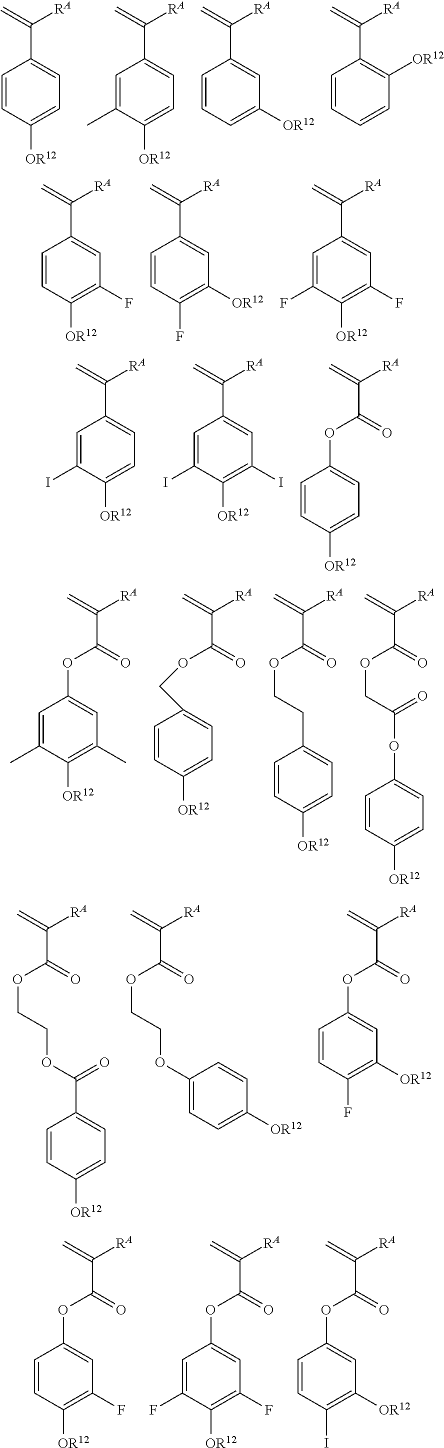

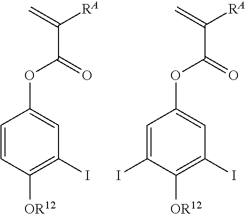

Examples of the acid labile group represented by R¹¹ and R¹² in repeat units a1 and a2 include those described in JP-A 2013-80033 and JP-A 2013-83821.

Typically, examples of the acid labile groups include those having any of following formulae (AL-1) to (AL-3).

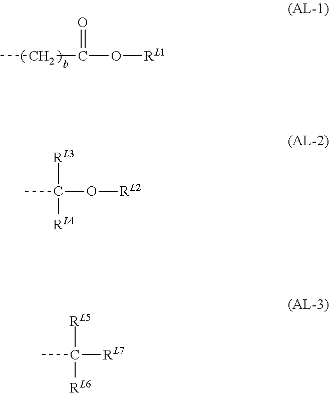

Herein the broken line designates a point of attachment.

In formulae (AL-1) and (AL-2), R^{L1} and R^{L2} are each independently a C₁-C₄₀ hydrocarbyl group which may contain a heteroatom such as oxygen, sulfur, nitrogen, or fluorine. The hydrocarbyl group may be saturated or unsaturated and straight, branched or cyclic. Preferred are C₁-C₄₀, especially C₁-C₂₀ saturated hydrocarbyl groups.

In formula (AL-1), b is an integer of 0 to 10, preferably an integer of 1 to 5.

In formula (AL-2), R^{L3} and RIA are each independently a hydrogen atom or a C₁-C₂₀ hydrocarbyl group which may contain a heteroatom such as oxygen, sulfur, nitrogen, or fluorine. The hydrocarbyl group may be saturated or unsaturated and straight, branched or cyclic. Preferred are C₁-C₂₀ saturated hydrocarbyl groups. Any two of R^{L2}, R^{L3}, and RIA may bond together to form a ring, typically an alicyclic ring, with a carbon atom or carbon and oxygen atoms to which they are bonded, the ring containing 3 to 20 carbon atoms. The ring is preferably a ring containing 4 to 16 carbon atoms, and particularly preferably an alicyclic ring.

In formula (AL-3), R^{L5}, R^{L6}, and R^{L7} are each independently a C₁-C₂₀ hydrocarbyl group which may contain a heteroatom such as oxygen, sulfur, nitrogen, or fluorine. The hydrocarbyl group may be saturated or unsaturated and straight, branched or cyclic. Preferred are C₁-C₂₀ saturated hydrocarbyl groups. Any two of R^{L5}, R^{L6}, and R^{L7} may bond together to form a ring, typically an alicyclic ring, with a carbon atom to which they are bonded, the ring containing 3 to 20 carbon atoms. The ring is preferably a ring containing 4 to 16 carbon atoms, and particularly preferably an alicyclic ring.

The base polymer may further comprise repeat units (b) having a phenolic hydroxy group as an adhesive group. Examples of the monomer from which repeat units b are derived are shown below, but not limited thereto. R^{A} is as defined above.

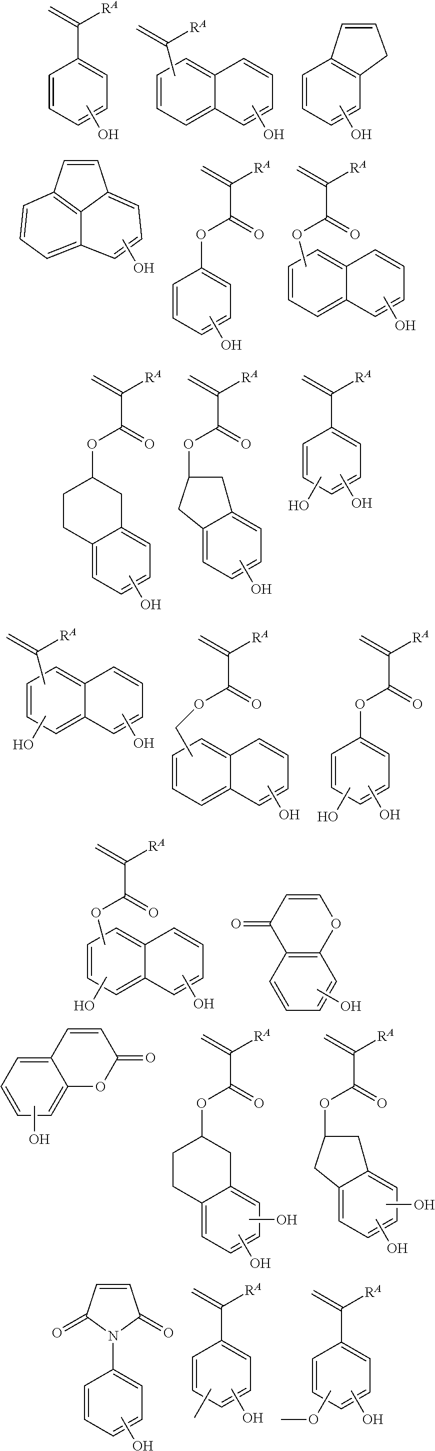

Further, repeat units (c) having another adhesive group selected from hydroxy (other than the foregoing phenolic hydroxy), lactone ring, sultone ring, ether bond, ester bond, sulfonic ester bond, carbonyl, sulfonyl, cyano and carboxy groups may also be incorporated in the base polymer. Examples of the monomer from which repeat units c are derived are shown below, but not limited thereto. R^{A} is as defined above.

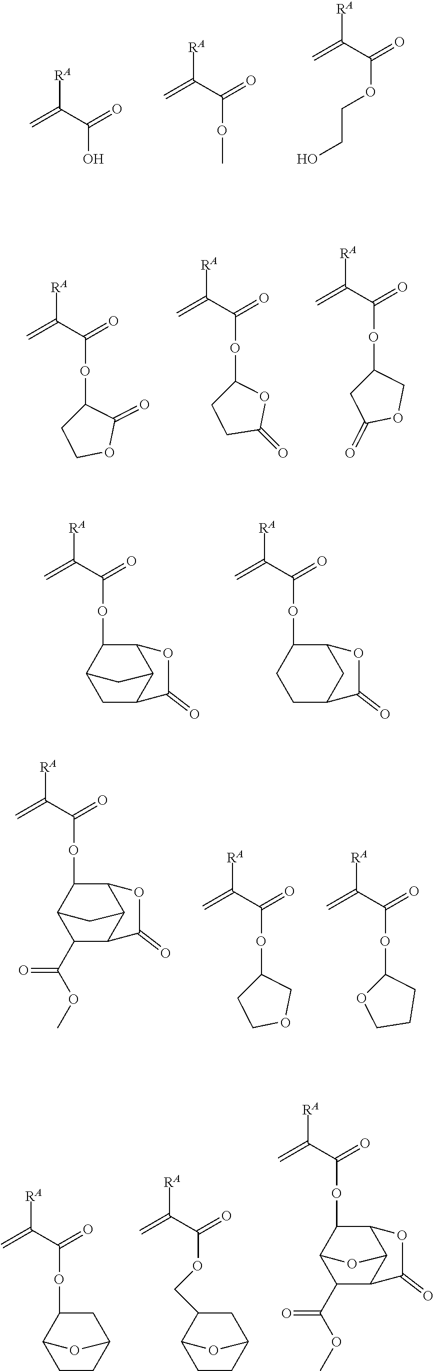

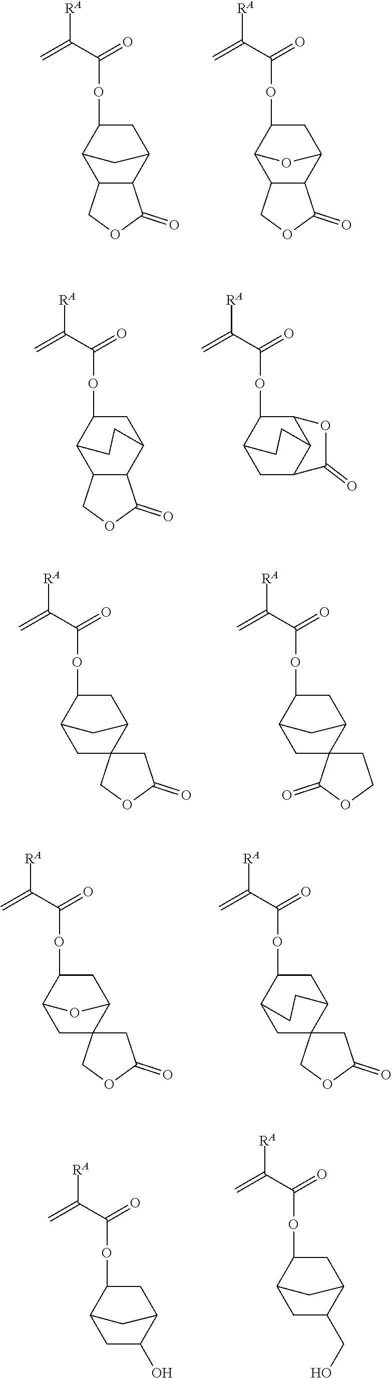

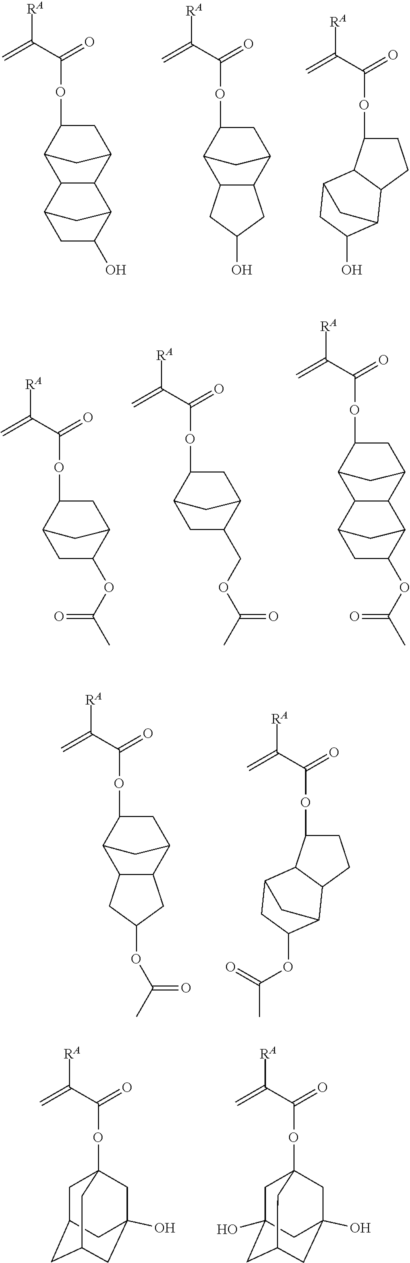

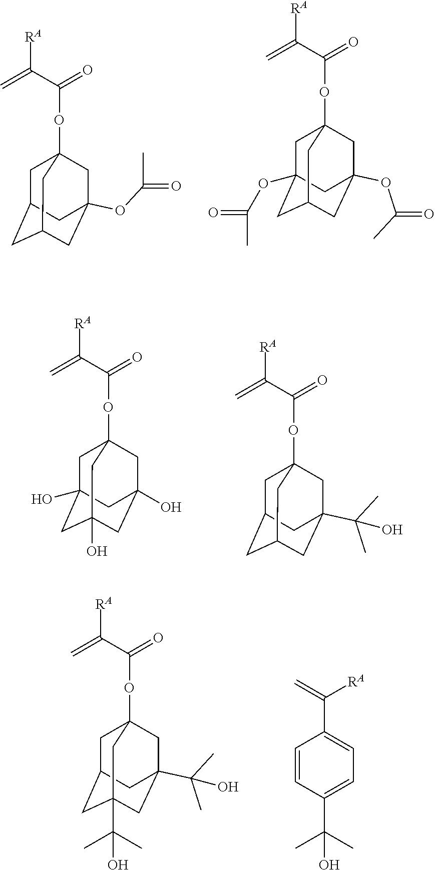

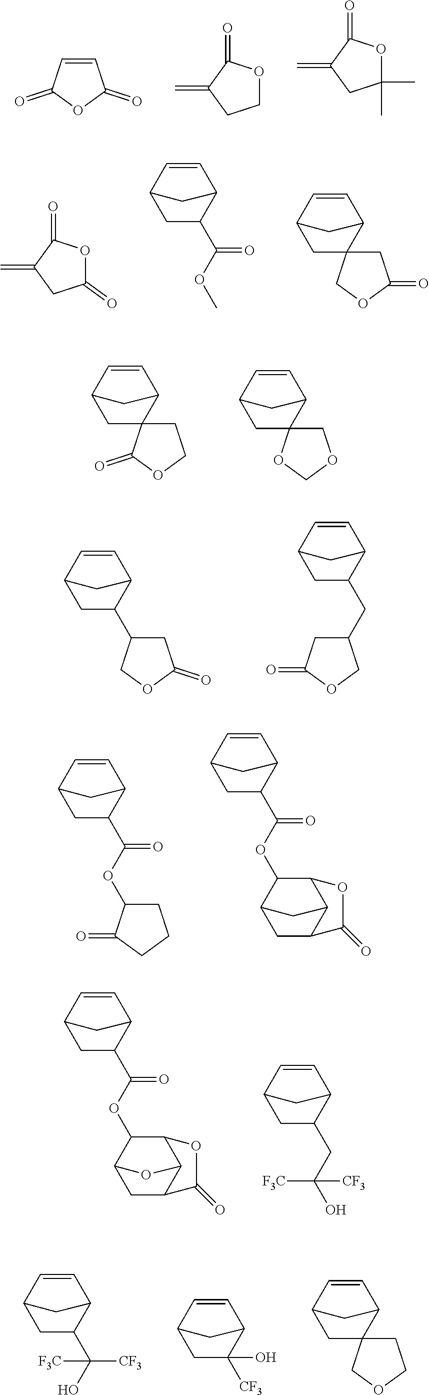

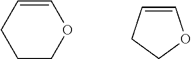

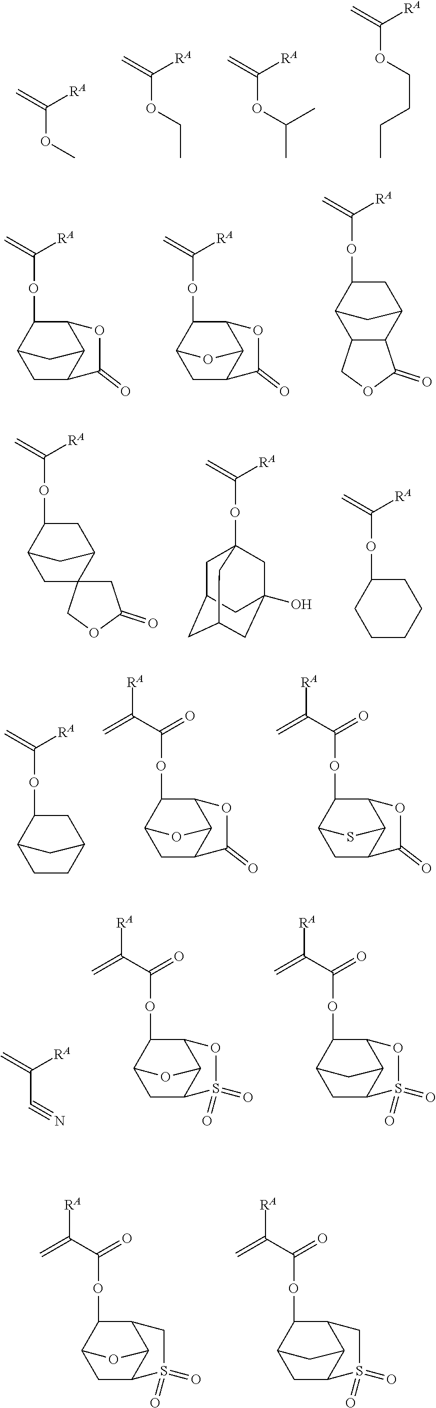

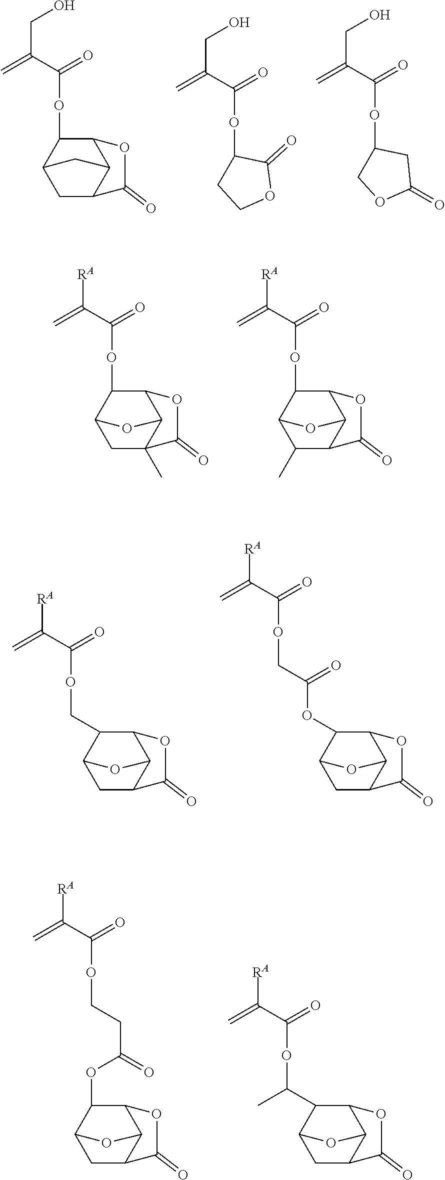

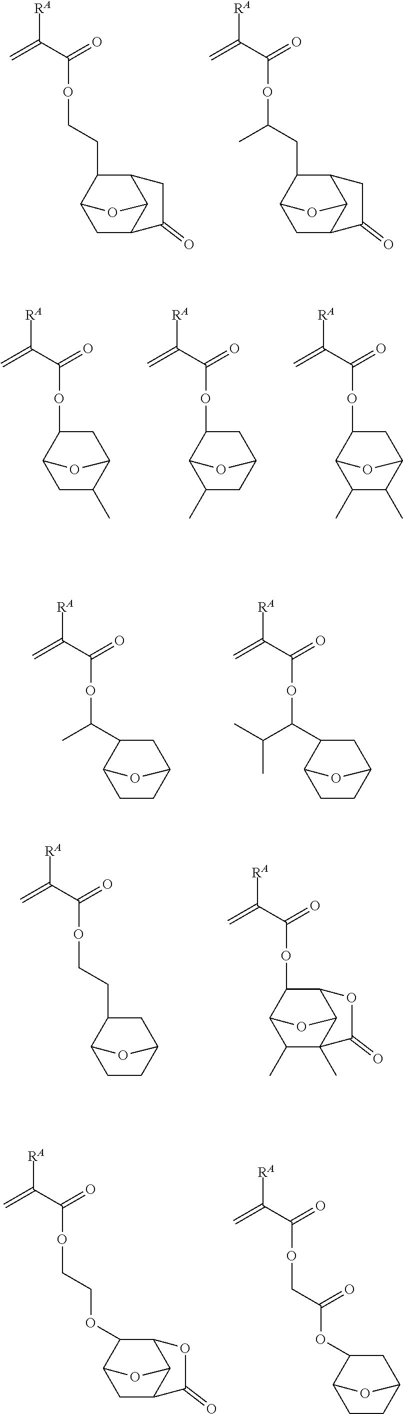

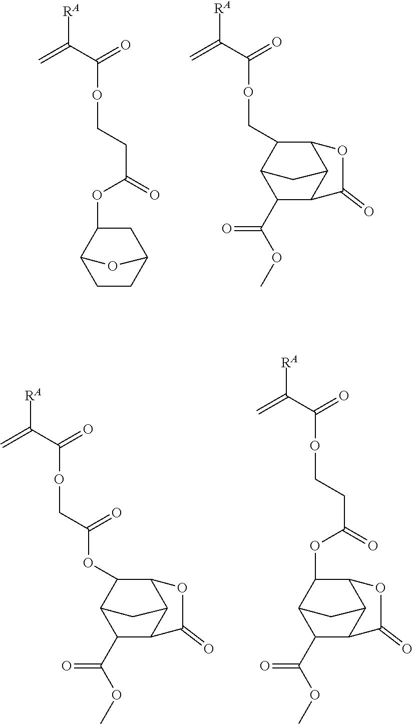

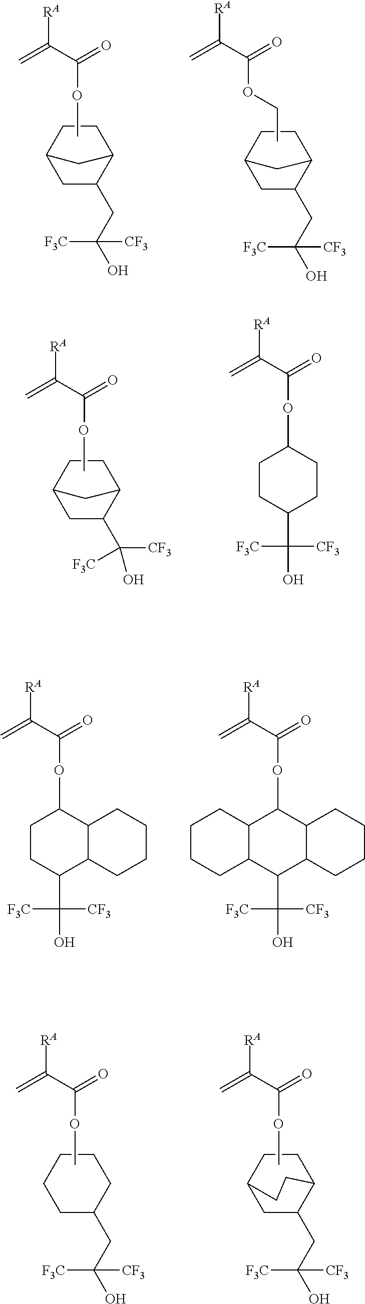

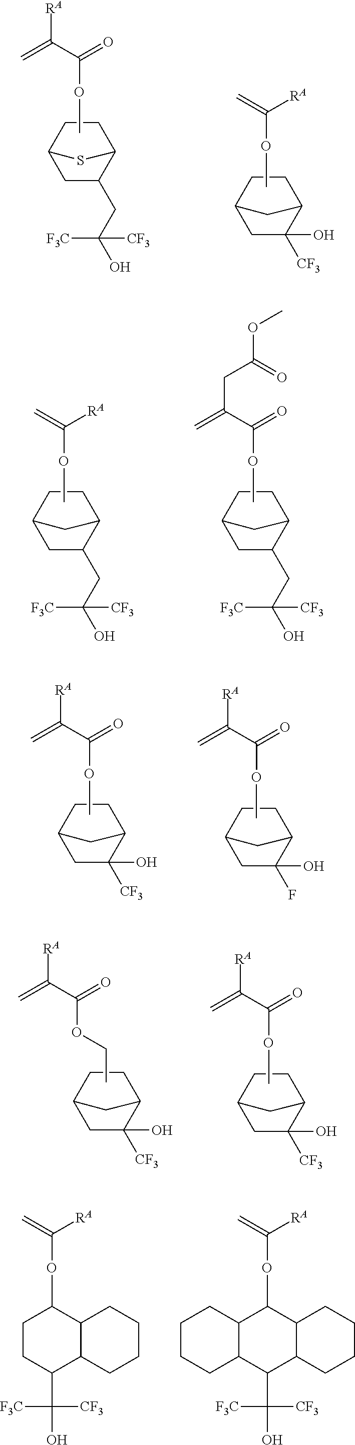

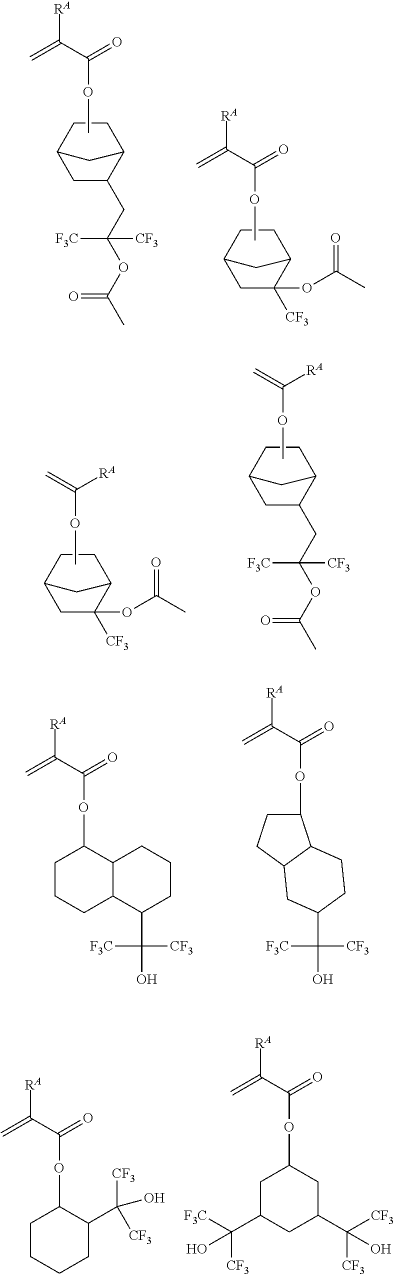

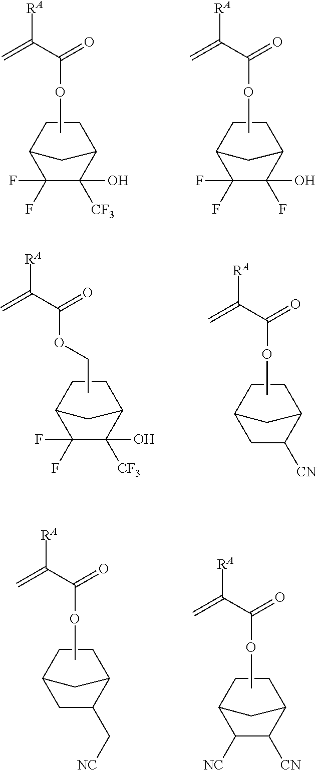

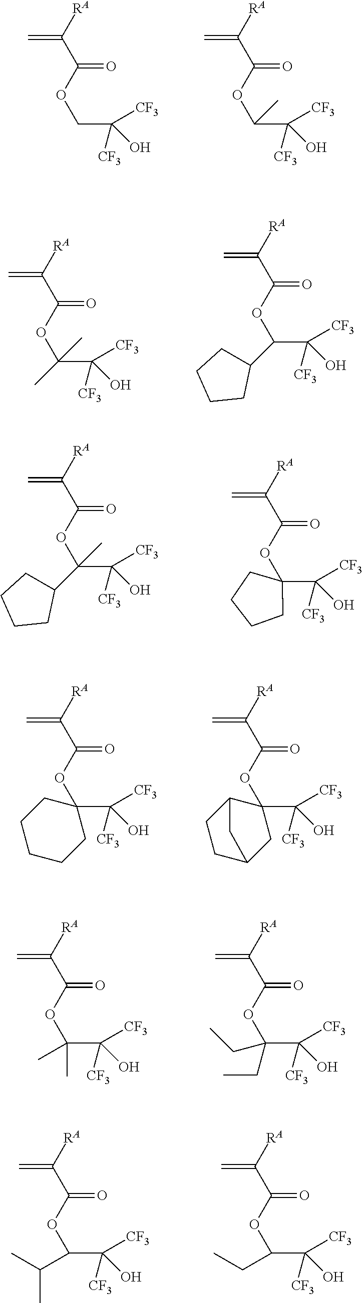

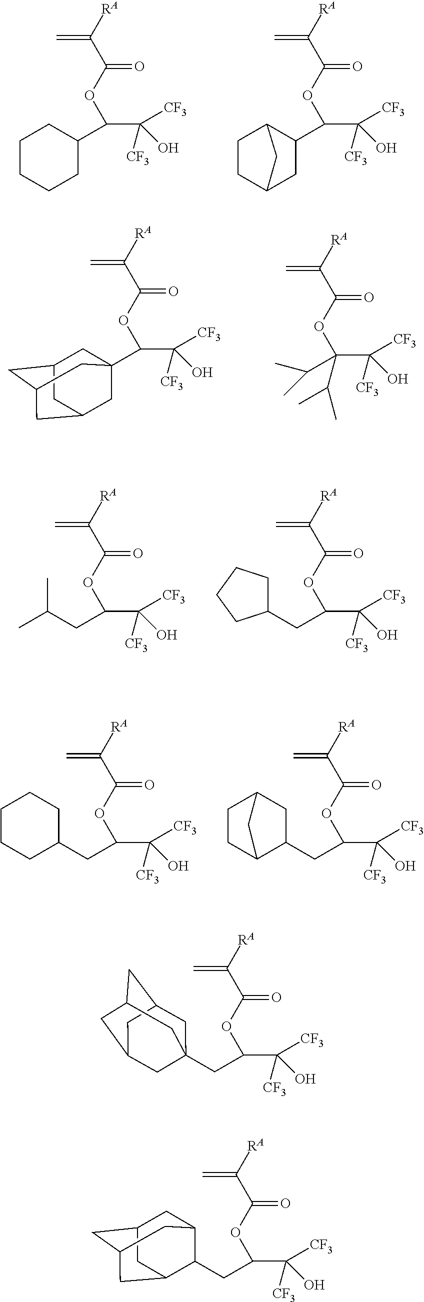

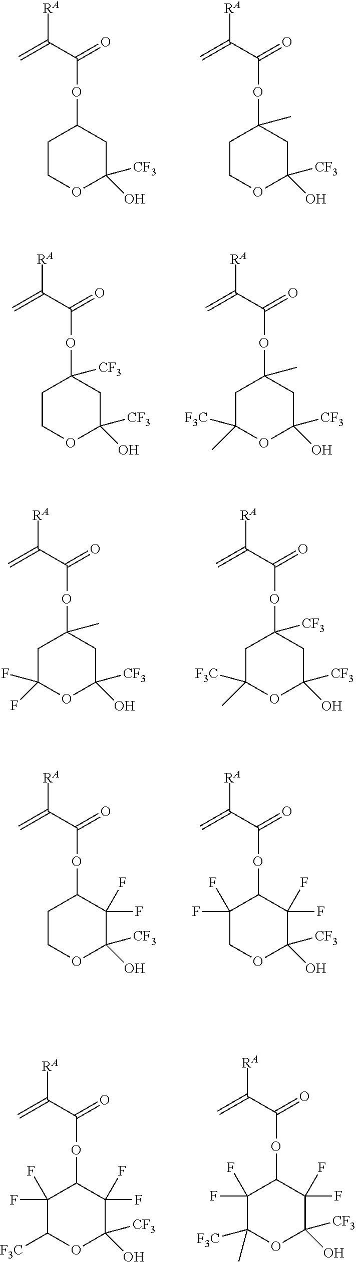

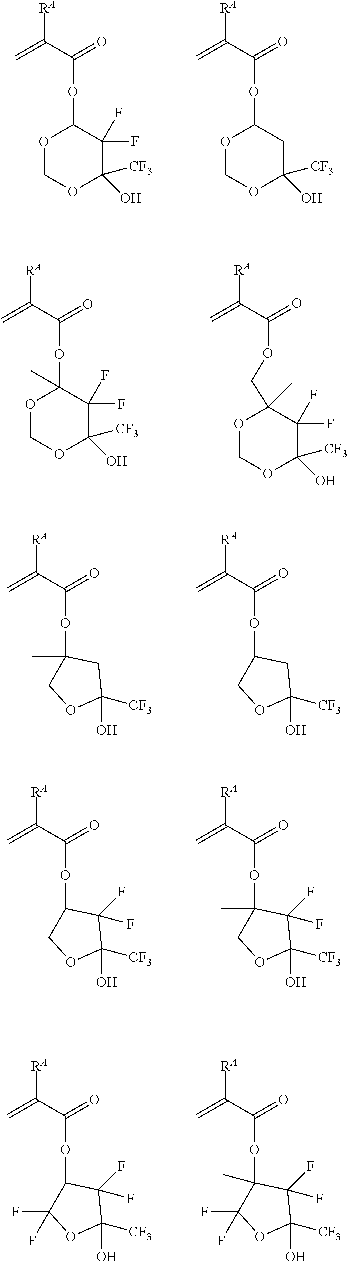

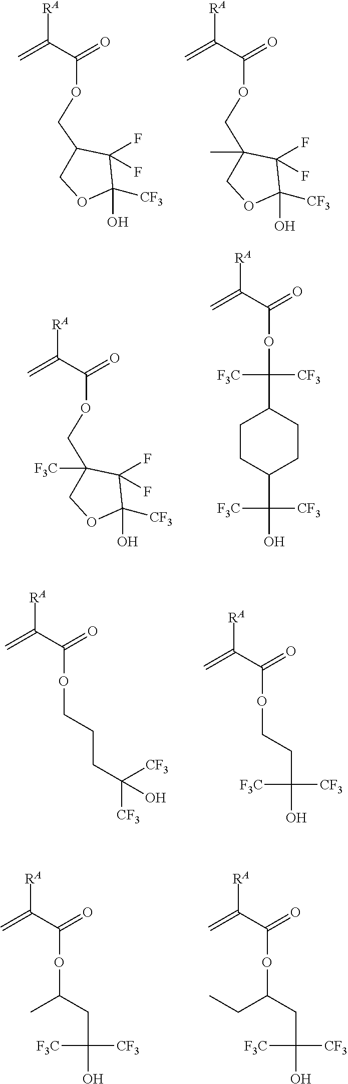

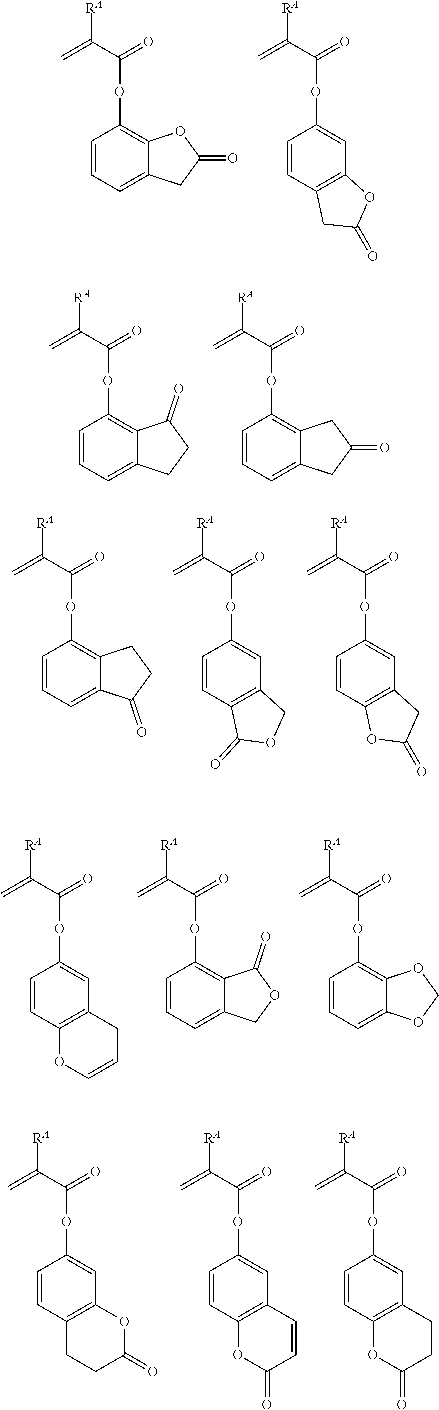

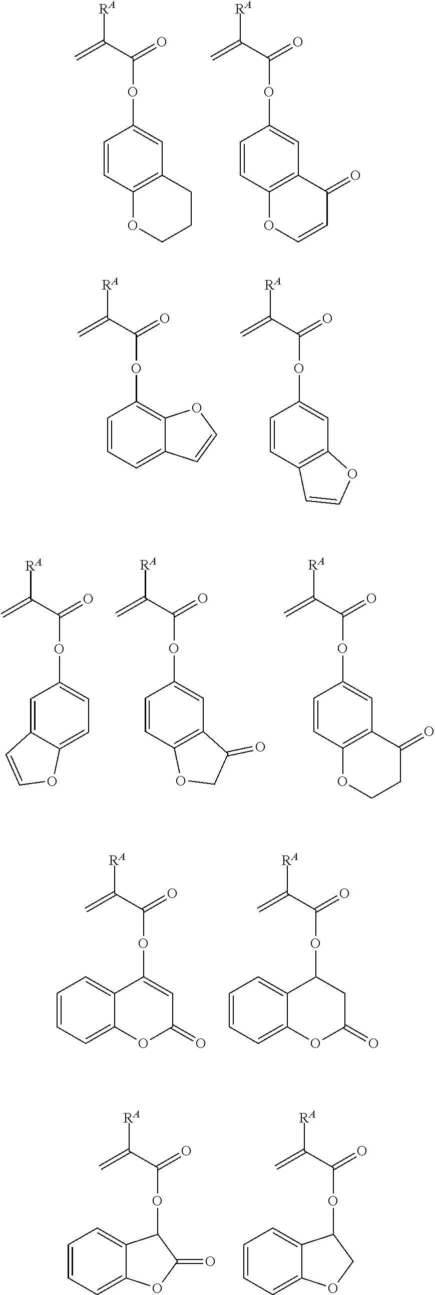

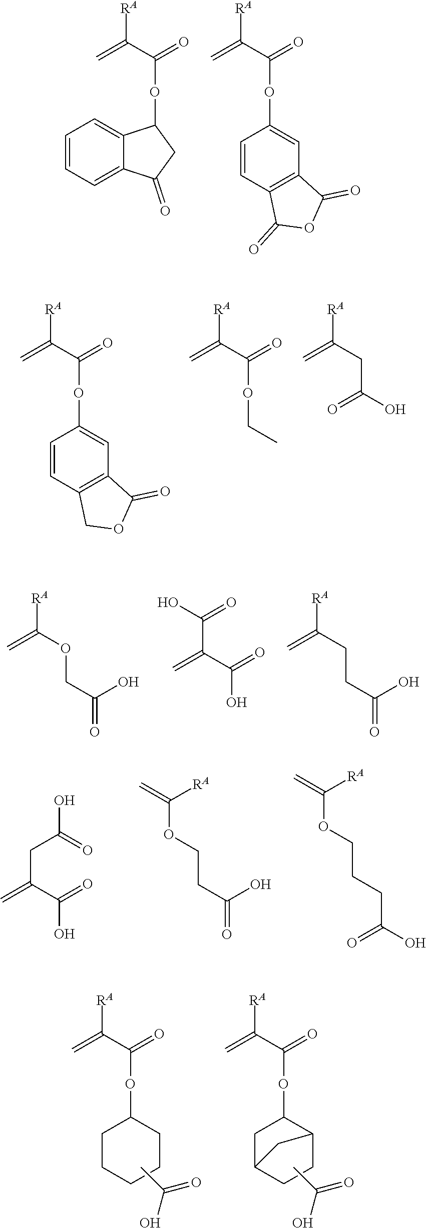

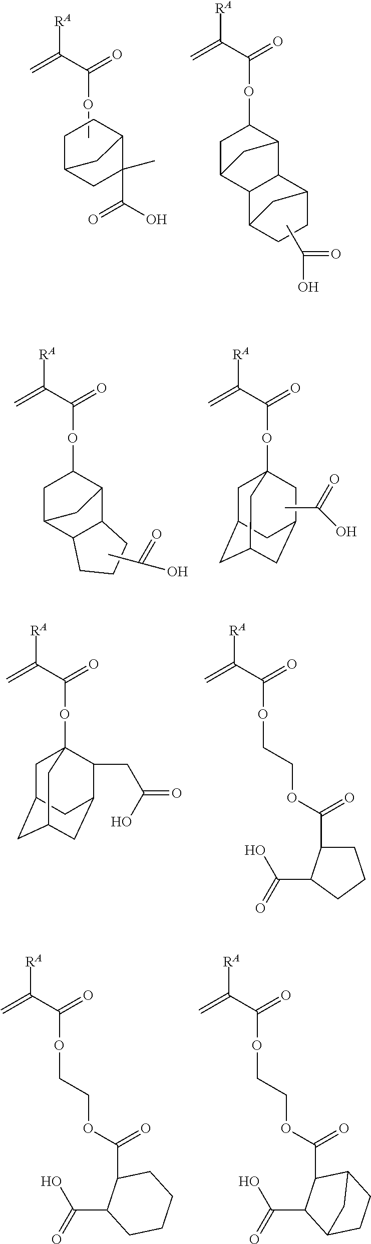

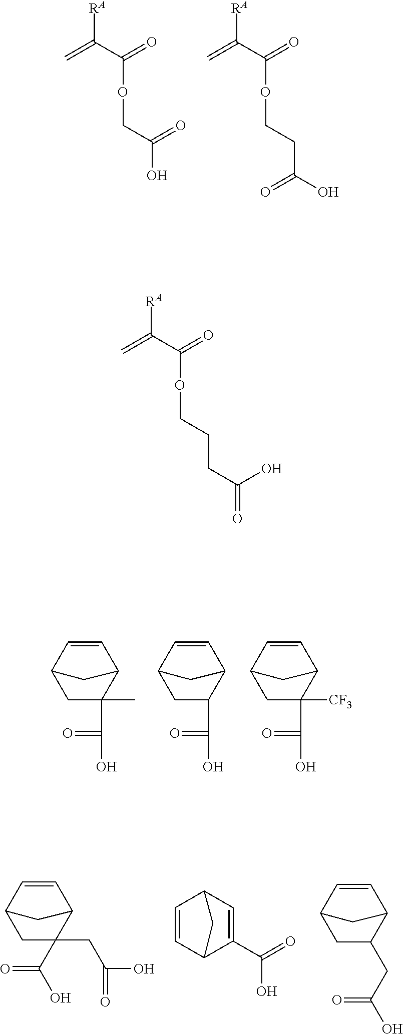

In another preferred embodiment, the base polymer may further comprise repeat units (d) derived from indene, benzofuran, benzothiophene, acenaphthylene, chromone, coumarin, and norbornadiene, or derivatives thereof. Examples of the monomer from which the repeat units d are derived are shown below, but not limited thereto.

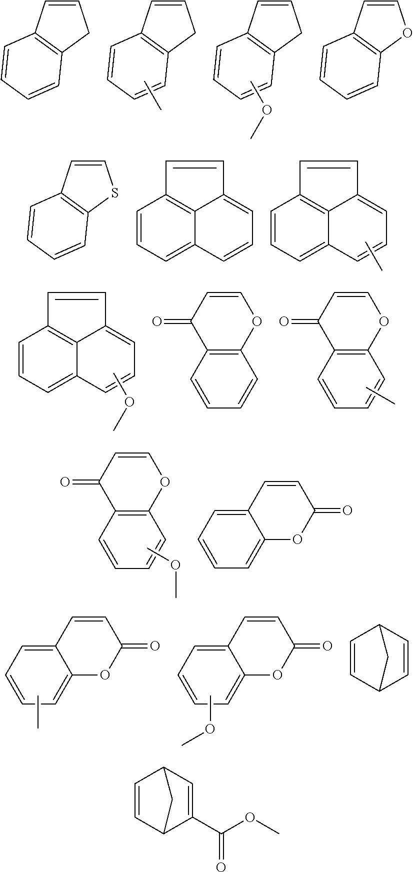

The base polymer may further include repeat units (e) which are derived from styrene, vinylnaphthalene, vinylanthracene, vinylpyrene, methyleneindene, vinylpyridine, vinylcarbazole, or derivatives thereof.

In a further embodiment, the base polymer may further comprise repeat units (f) derived from an onium salt having a polymerizable unsaturated bond. JP-A 2005-84365 discloses a sulfonium or iodonium salt having a polymerizable olefin, capable of generating a specific sulfonic acid. JP-A 2006-178317 discloses a sulfonium salt having a sulfonic acid directly attached to the backbone.

Examples of the preferred repeat units f include repeat units having following formula (f1) (hereinafter, the repeat units are also referred to as repeat units f1), repeat units having following formula (f2) (hereinafter, the repeat units are also referred to as repeat units f2), and repeat units having following formula (f3) (hereinafter, the repeat units are also referred to as repeat units f3). The repeat units f1 to f3 may each be used alone or in combination of two or more kinds thereof.

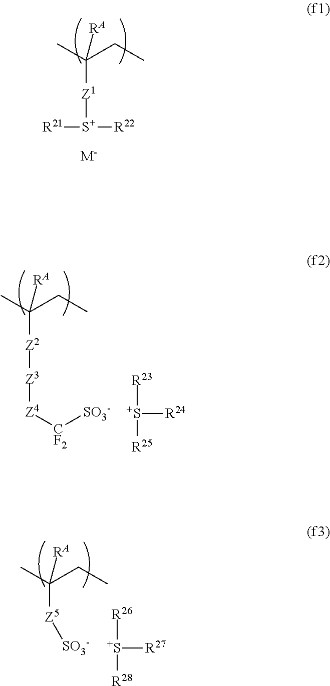

In formulae (f1) to (f3), R^{A} is each independently hydrogen or methyl. Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹—, or —C(═O)—NH—Z¹¹—. Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group. Z² is a single bond or ester bond, Z³ is a single bond, —Z³¹—C(═O)—O—, —Z³¹—O—, or —Z³¹—O—C(═O)—. Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom. Z⁴ is methylene, 2,2,2-trifluoro-1,1-ethanediyl or carbonyl, Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—. Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a hydroxy group, or a halogen atom.

In formulae (f1) to (f3), R²¹ to R²⁸ are each independently halogen or a C₁-C₂₀ hydrocarbyl group which may contain a heteroatom. Examples of the halogen atom include fluorine, chlorine, bromine and iodine atoms. The hydrocarbyl group may be saturated or unsaturated and straight, branched or cyclic. Examples of thereof are as exemplified above as hydrocarbyl groups R⁴ to R⁸ in formulae (2) and (3). In the hydrocarbyl group, some or all hydrogen atoms may be substituted by a moiety containing a heteroatom such as oxygen, sulfur, nitrogen or halogen and some constituent —CH₂— may be replaced by a moiety containing a heteroatom such as oxygen, sulfur or nitrogen, so that the group may contain hydroxy, fluorine, chlorine, bromine, iodine, cyano, nitro, carbonyl, ether bond, ester bond, sulfonic ester bond, carbonate bond, lactone ring, sultone ring, carboxylic anhydride (—C(═O)—O—C(═O)—), or haloalkyl moiety. A pair of R²³ and R²⁴, or R²⁶ and R²⁷ may bond together to form a ring with the sulfur atom to which they are attached. Examples of the ring are as exemplified above for formula (2) where R⁴ and R⁵ bond together to form a ring with a sulfur atom to which they are attached.

In formula (f1), M⁻ is a non-nucleophilic counter ion. Examples of the non-nucleophilic counter ion include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; and methide ions such as tris(trifluoromethylsulfonyl)methide and tris(perfluoroethylsulfonyl)methide.

Examples of the non-nucleophilic counter ion include sulfonate ions having a fluorine atom substituted at the α-position as represented by following formula (f1-1) and sulfonate ions having a fluorine atom substituted at the α-position and a trifluoromethyl group substituted at the β-position as represented by following formula (f1-2).

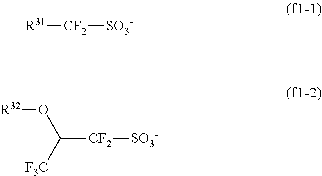

In formula (f1-1), R³¹ is a hydrogen atom or a C₁-C₂₀ hydrocarbyl group which may contain at least one selected from an ether bond, an ester bond, a carbonyl group, a lactone ring and a fluorine atom.

In formula (f1-2), R³² is a hydrogen atom, a C₁-C₃₀ hydrocarbyl group or C₂-C₃₀ hydrocarbylcarbonyl group which may contain at least one selected from an ether bond, an ester bond, a carbonyl group and a lactone ring.

The hydrocarbyl group R³¹ or R³², and the hydrocarbyl moiety in the hydrocarbylcarbonyloxy group R³¹ or R³² may be saturated or unsaturated and straight, branched or cyclic. Examples thereof include alkyl groups such as methyl, ethyl, propyl, isopropyl, butyl, isobutyl, sec-butyl, tert-butyl, pentyl, neopentyl, hexyl, heptyl, 2-ethylhexyl, nonyl, undecyl, tridecyl, pentadecyl, heptadecyl and icocyl groups; cyclic saturated hydrocarbyl groups such as cyclopentyl, cyclohexyl, 1-adamantyl, 2-adamantyl, 1-adamantylmethyl, norbornyl, norbornylmethyl, tricyclodecanyl, tetracyclodecanyl, tetracyclodecanyllmethyl and dicyclohexylmethyl groups; alkenyl groups such as an allyl group; cyclic unsaturated hydrocarbyl groups such as a 3-cyclohexenyl group; aryl groups such as a phenyl, 1-naphthyl and 2-naphthyl groups; and aralkyl groups such as benzyl and diphenylmethyl groups.

In those groups, some or all of the hydrogen atoms may be substituted by a moiety containing a heteroatom such as oxygen, sulfur, nitrogen or halogen, and some of carbon atoms in those groups may be replaced by a moiety containing a heteroatom such as oxygen, sulfur or nitrogen, so that the group may contain a hydroxy moiety, cyano moiety, carbonyl moiety, ether bond, ester bond, sulfonic ester bond, carbonate group, lactone ring, sultone ring, carboxylic anhydride, or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

Examples of the cation in the monomer from which the repeat units f1 are derived include those shown below, but are not limited thereto. R^{A} is as defined above.

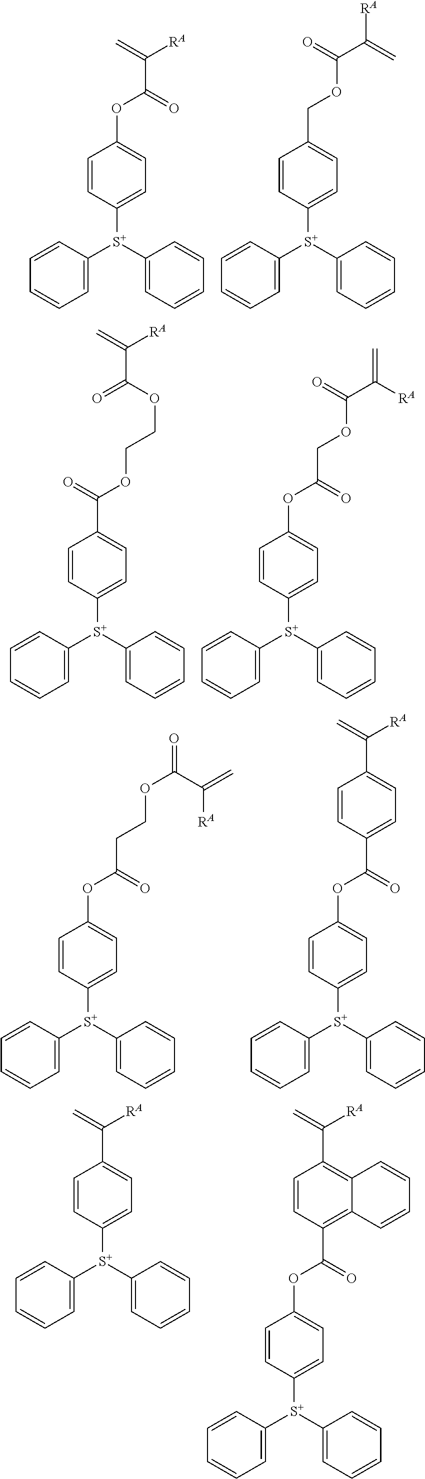

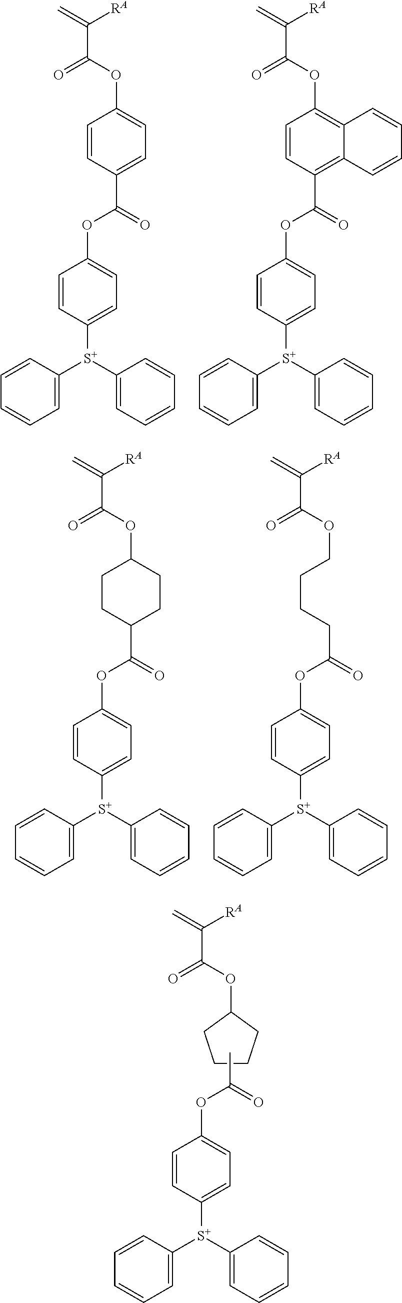

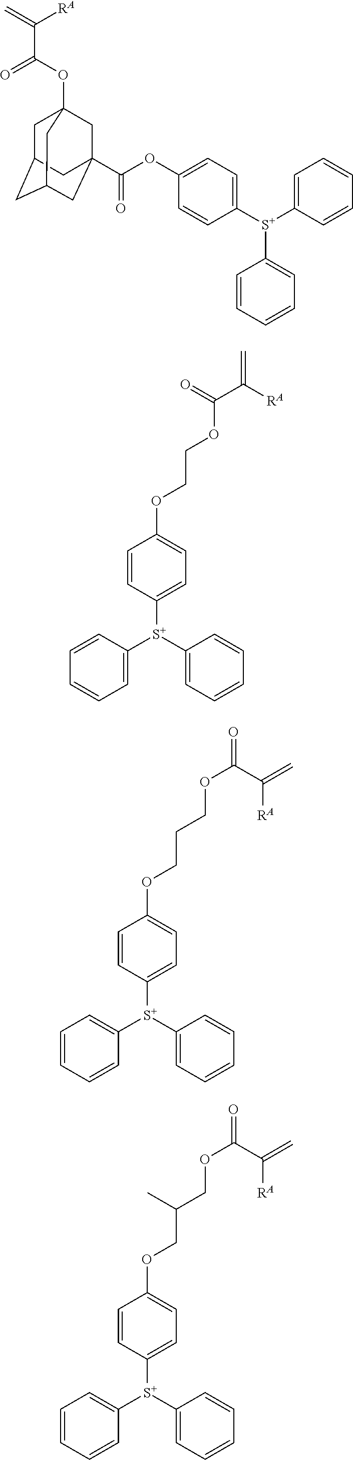

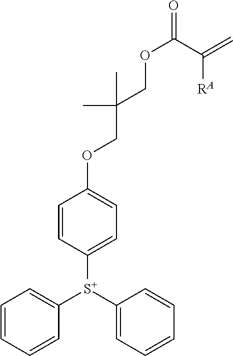

Examples of the cation in the monomer from which the repeat units f2 or f3 are derived are as exemplified for the sulfonium cation represented by M⁺ in the description of formula (1).

Examples of the monomer from which the repeat units f2 are derived are shown below, but not limited thereto. R^{A} is as defined above.

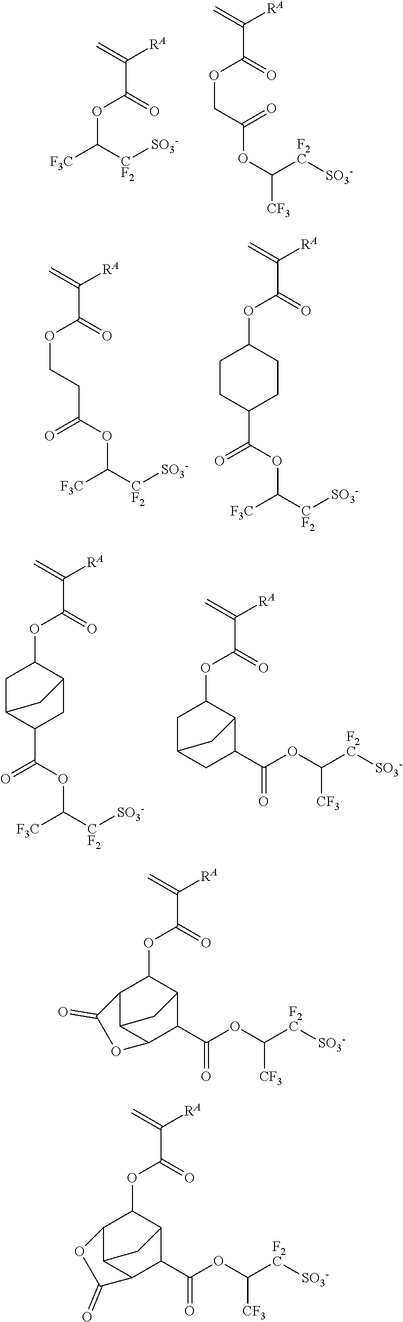

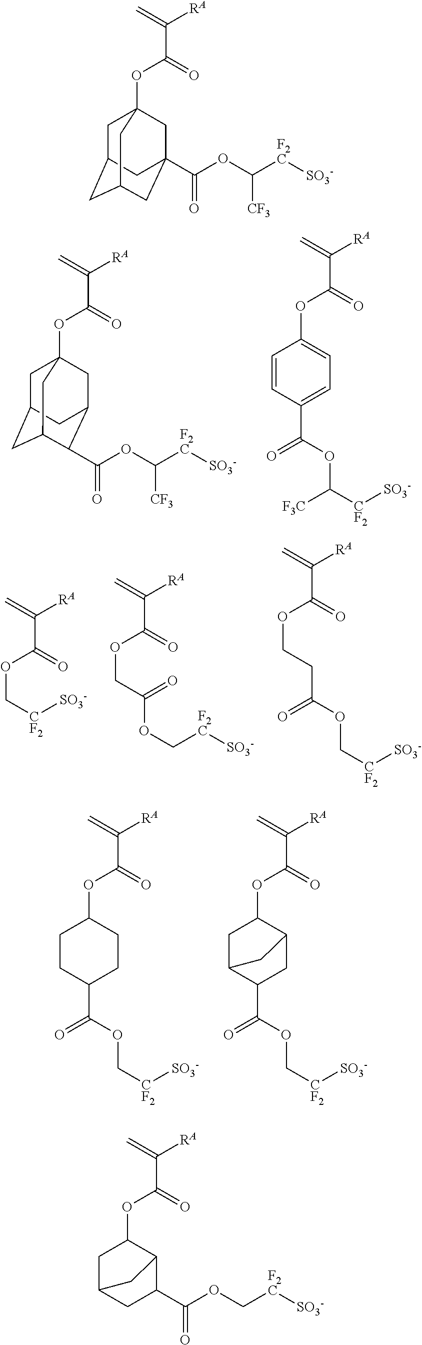

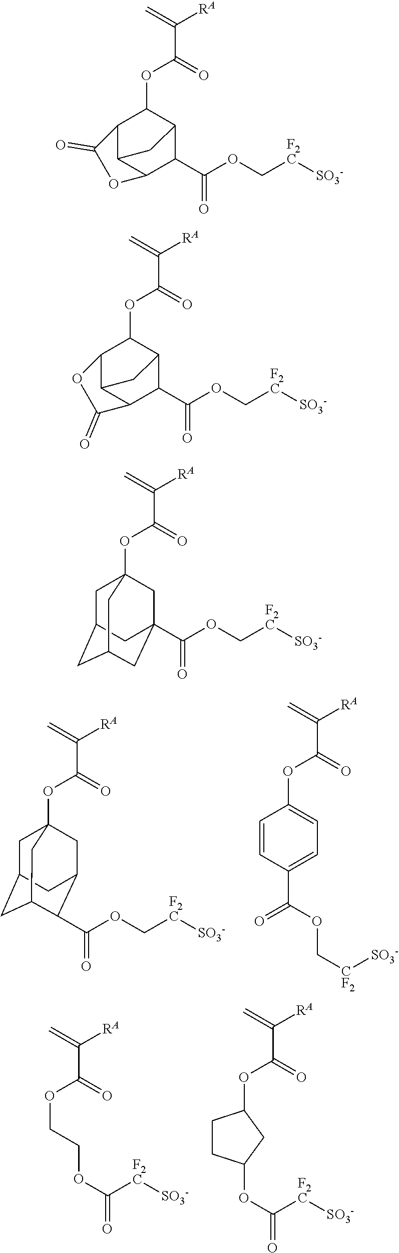

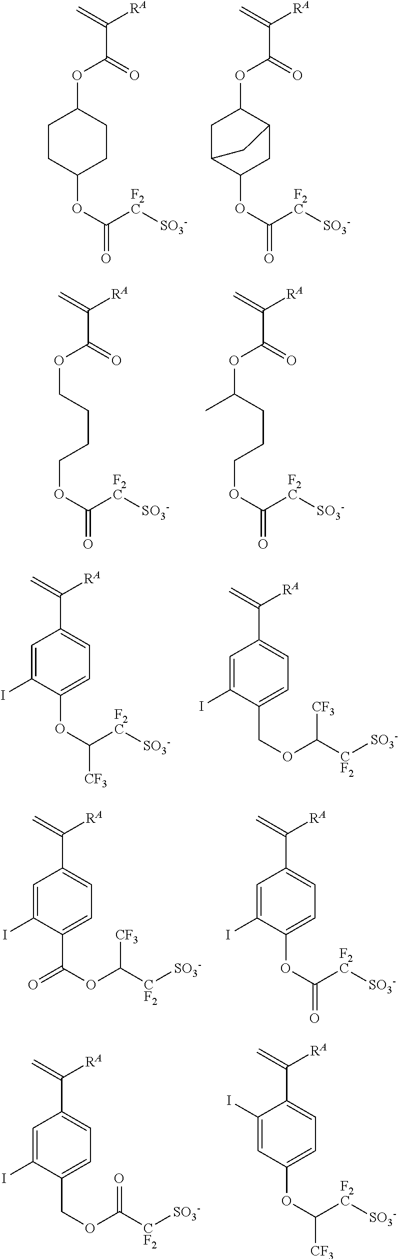

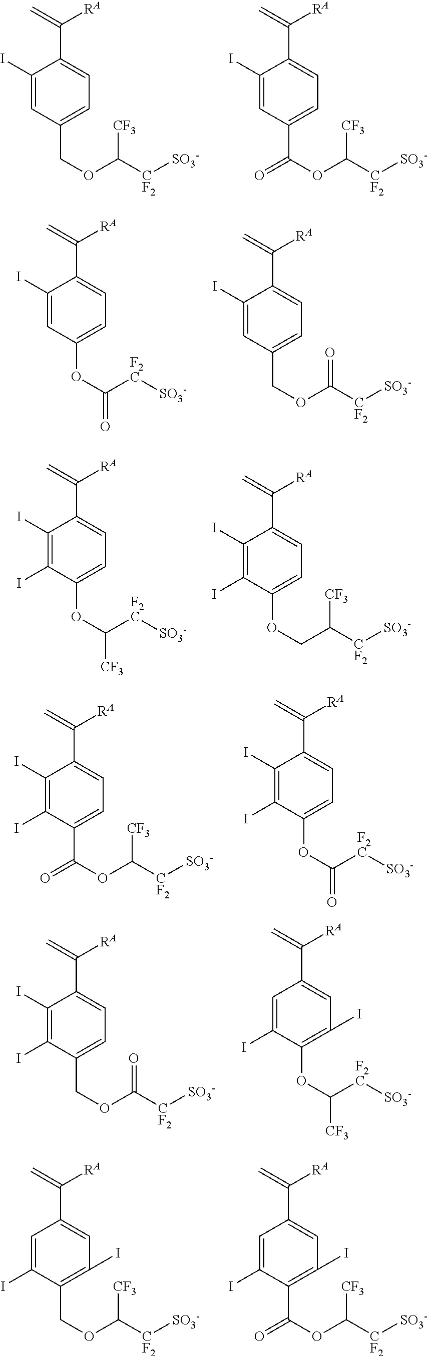

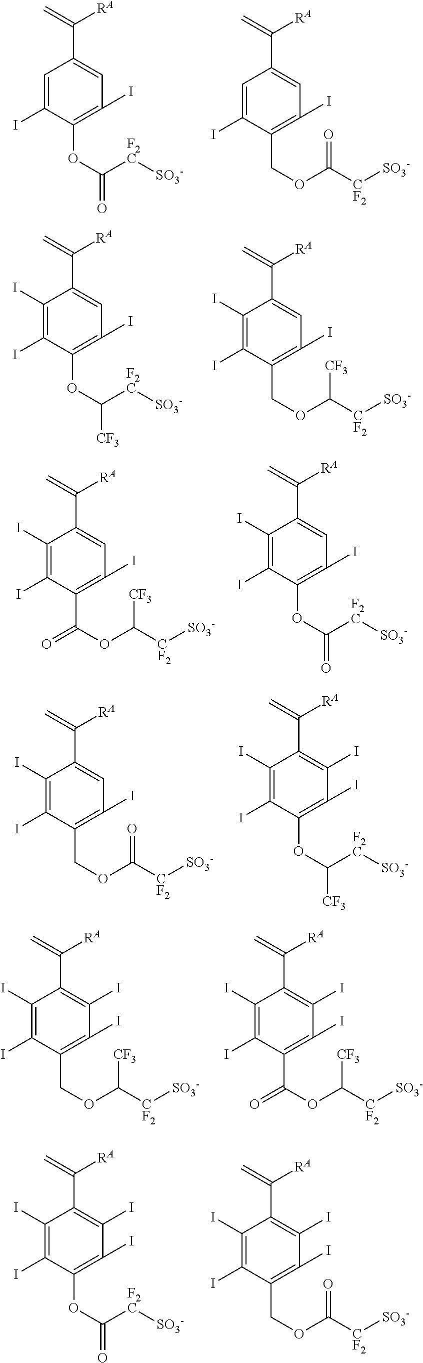

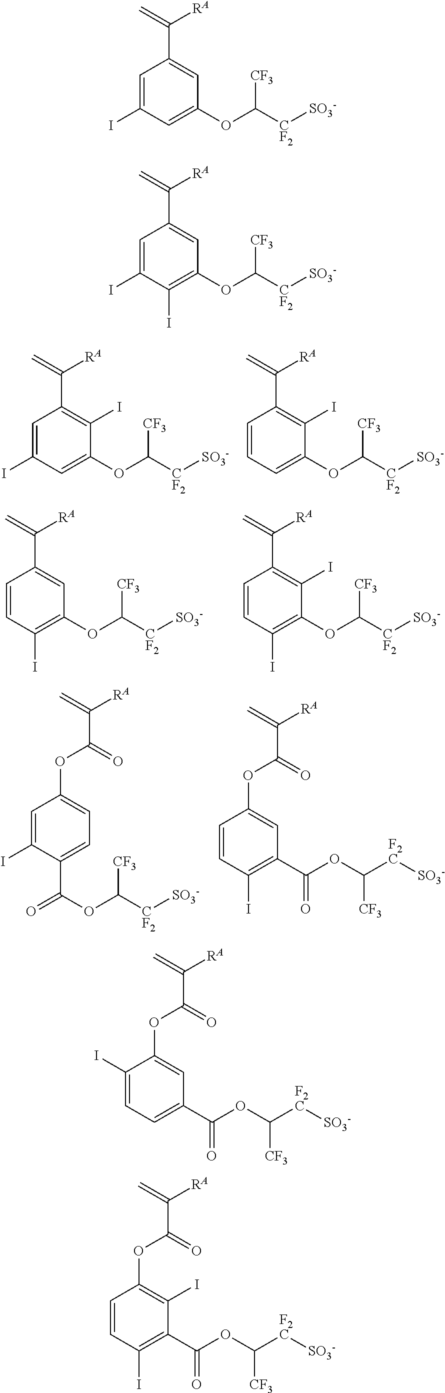

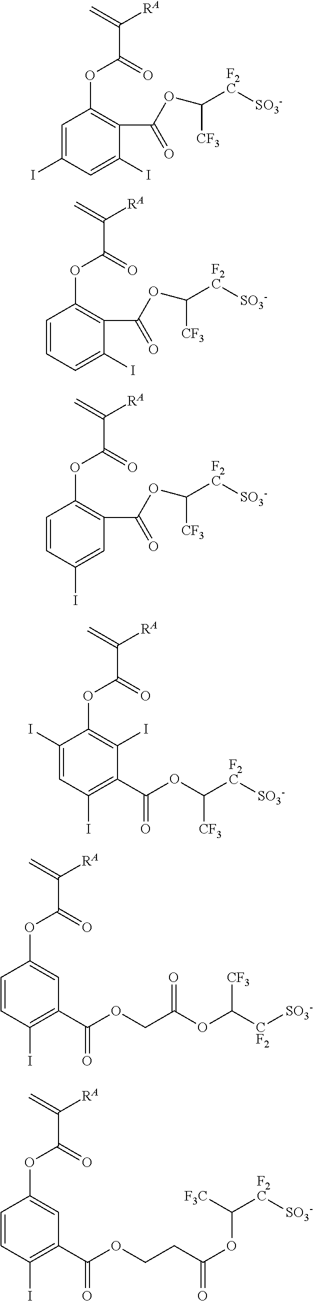

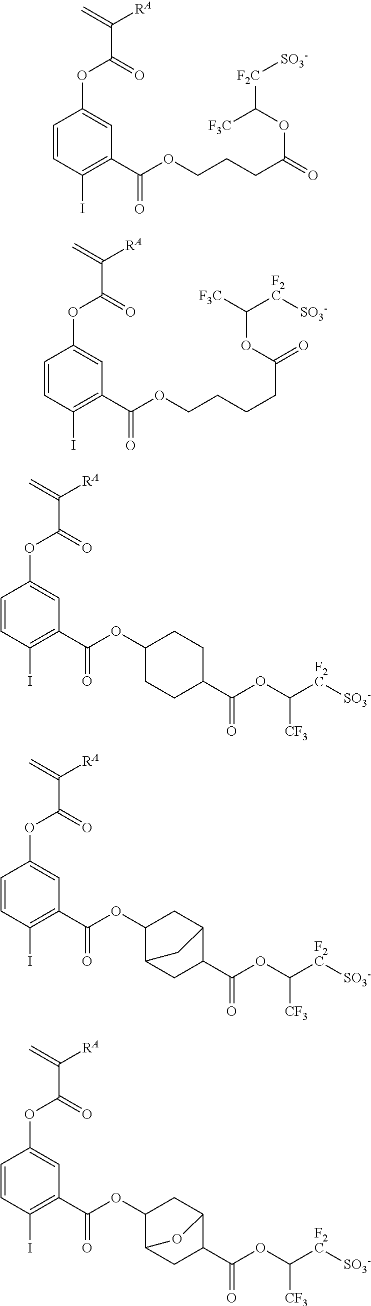

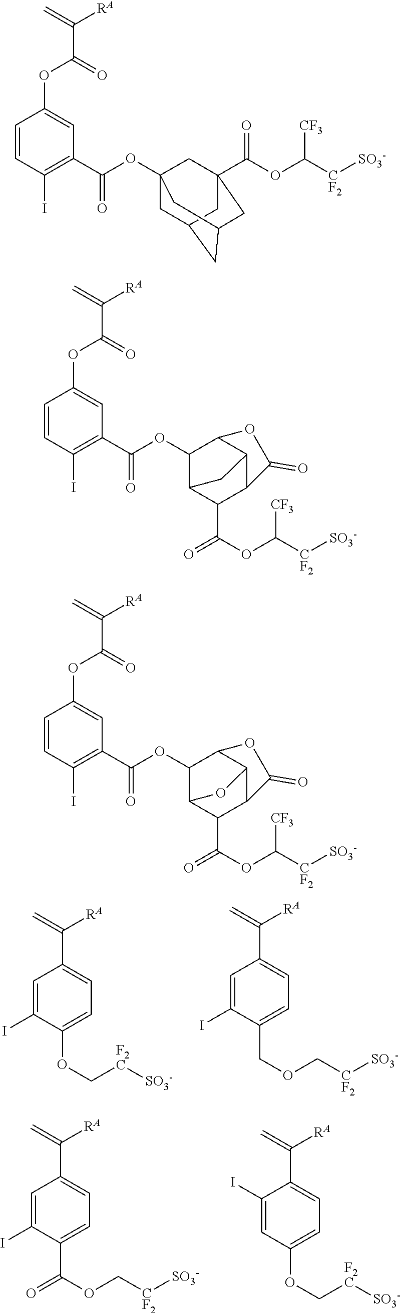

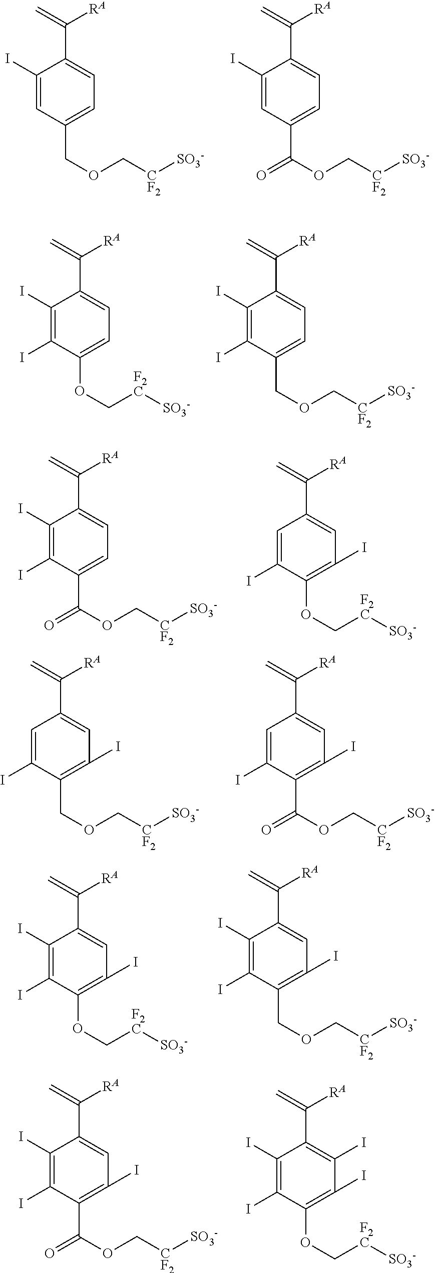

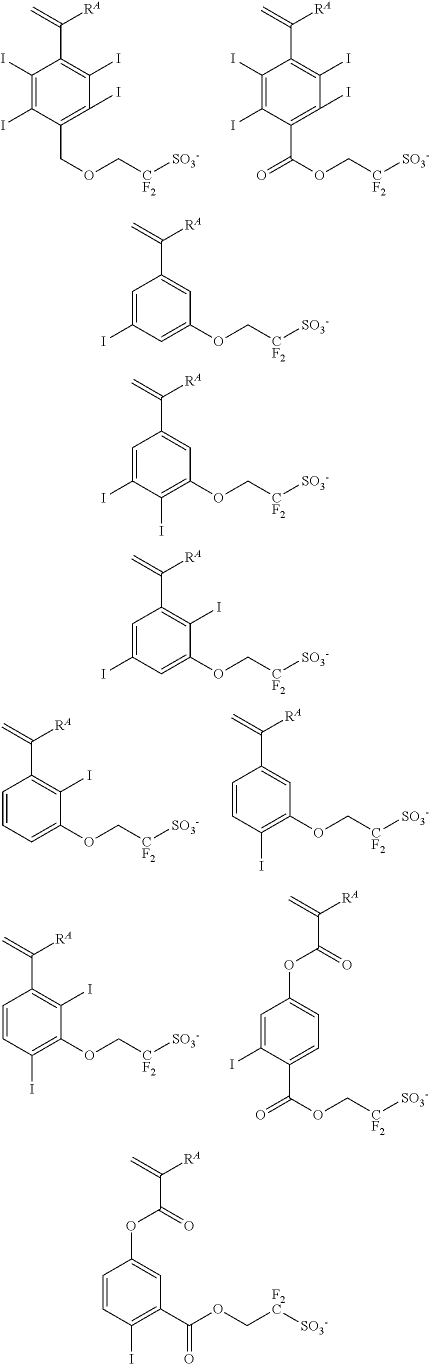

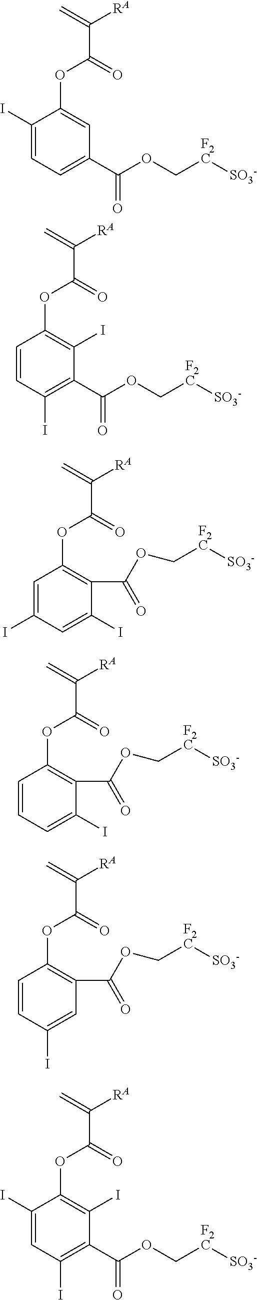

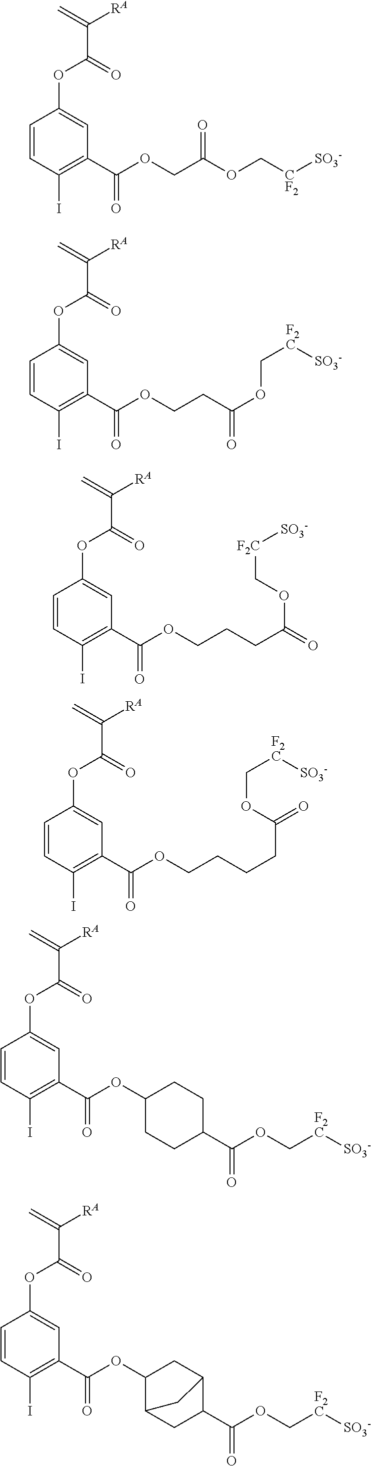

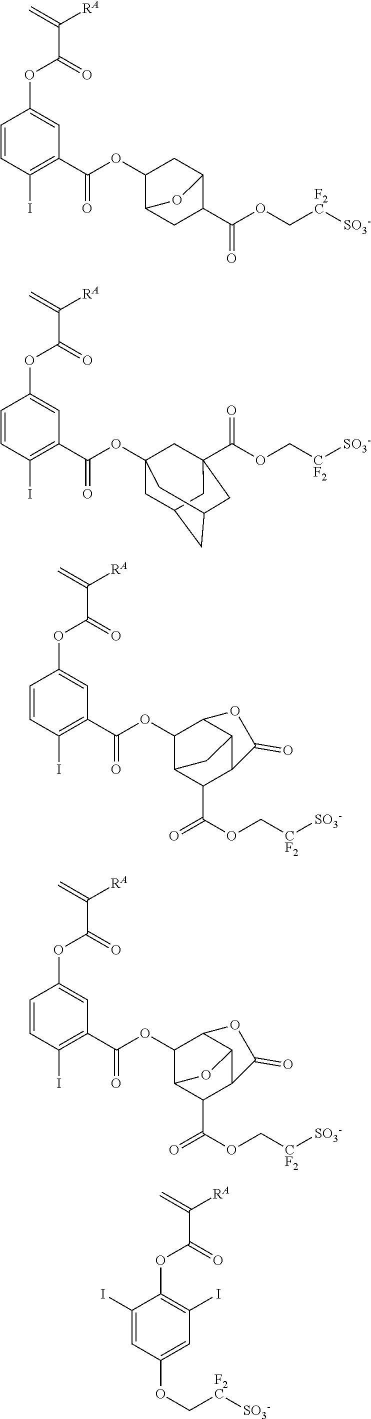

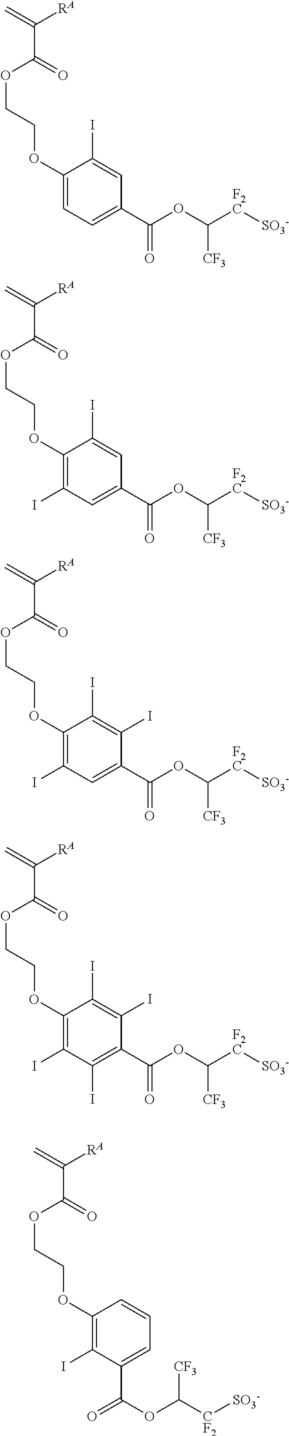

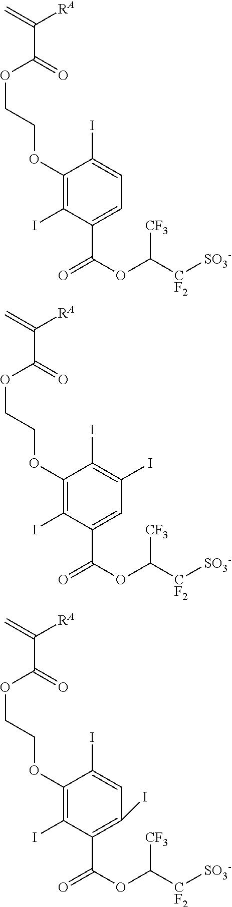

Examples of the monomer from which the repeat units f3 are derived are shown below, but not limited thereto. R^{A} is as defined above.

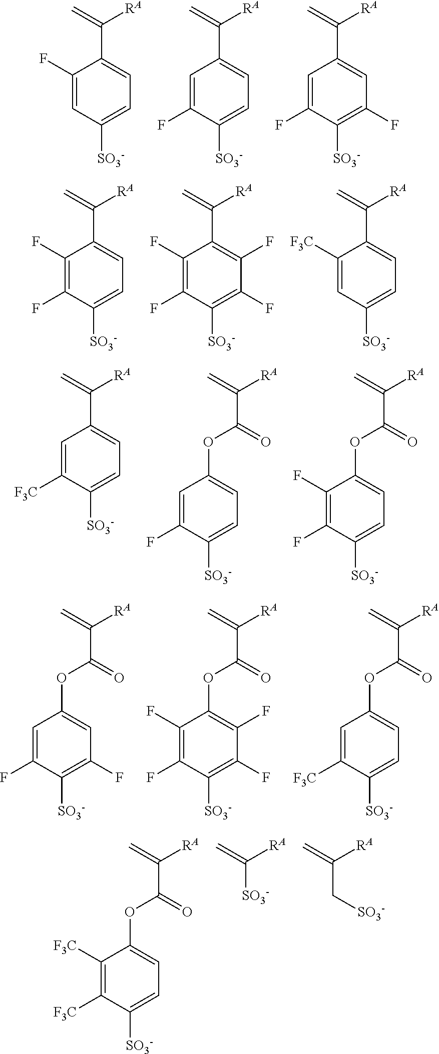

The repeat units f1 to f3 function as an acid generator. The attachment of an acid generator to the polymer main chain is effective in restraining acid diffusion, thereby preventing a reduction of resolution due to blur by acid diffusion. In addition, the LWR and CDU are improved since the acid generator is uniformly distributed.

The base polymer for formulating the positive resist composition comprises repeat units (a1) or (a2) having an acid labile group as essential component and additional repeat units (b), (c), (d), (e), and (f) as optional components. A fraction of units (a1), (a2), (b), (c), (d), (e), and (f) is: preferably 0≤a1<1.0, 0≤a2<1.0, 0<a1+a2<1.0, 0≤b≤0.9, 0≤c≤0.9, 0≤d≤0.8, 0≤e≤0.8, and 0≤f≤0.5; more preferably 0≤a1≤0.9, 0≤a2≤0.9, 0.1≤a1+a2≤0.9, 0≤b≤0.8, 0≤c≤0.8, 0≤d≤0.7, 0≤e≤0.7, and 0≤f≤0.4; and even more preferably 0≤a1≤0.8, 0≤a2≤0.8, 0.1≤a1+a2≤0.8, 0≤b≤0.75, 0≤c≤0.75, 0≤d≤0.6, 0≤e≤0.6, and 0≤f≤0.3. Notably, f=f1+f2+f3, meaning that repeat unit (f) is at least one of repeat units (f1) to (f3). In addition, a1+a2+b+c+d+e+f=1.0.

For the base polymer for formulating the negative resist composition, an acid labile group is not necessarily essential. The base polymer comprises repeat units (b), and optionally repeat units (c), (d), (e), and/or (f). A fraction of these units is: preferably 0<b≤1.0, 0≤c≤0.9, 0≤d≤0.8, 0≤e≤0.8, and 0≤f≤0.5; more preferably 0.2≤b≤1.0, 0≤c≤0.8, 0≤d≤0.7, 0≤e≤0.7, and 0≤f≤0.4; and even more preferably 0.3≤b≤1.0, 0≤c≤0.75, 0≤d≤0.6, 0≤e≤0.6, and 0≤f≤0.3. Notably, f=f1+f2+f3, meaning that repeat unit (f) is at least one of repeat units (f1) to (f3). In addition, b+c+d+e+f=1.0.

The base polymer may be synthesized by any desired methods, for example, by dissolving one or more monomers selected from the monomers corresponding to the foregoing repeat units in an organic solvent, adding a radical polymerization initiator thereto, and heating for polymerization.

Examples of the organic solvent which can be used for polymerization include toluene, benzene, tetrahydrofuran (THF), diethyl ether, and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. The temperature during polymerization is preferably 50 to 80° C. The reaction time is preferably 2 to 100 hours, and more preferably 5 to 20 hours.

When a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene.

For alkaline hydrolysis, a base such as aqueous ammonia or triethylamine may be used. Preferably the reaction temperature is −20° C. to 100° C., more preferably 0° C. to 60° C. The reaction time is 0.2 to 100 hours, more preferably 0.5 to 20 hours.

The base polymer preferably has a weight average molecular weight (Mw) in the range of 1,000 to 500,000, and more preferably 2,000 to 30,000, as measured by gel permeation chromatography (GPC) versus polystyrene standards using a THF solvent. A Mw in the range ensures that the resist film has heat resistance and high solubility in alkaline developer.

If a base polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

It is understood that a blend of two or more polymers which differ in compositional ratio, Mw or Mw/Mn is acceptable.

### [Organic Solvent]

An organic solvent may be added to the resist composition. The organic solvent used herein is not particularly limited as long as the foregoing and other components are soluble therein. Examples of the organic solvent are described in JP-A 2008-111103, paragraphs [0144]-[0145] (U.S. Pat. No. 7,537,880). Exemplary solvents include ketones such as cyclohexanone, cyclopentanone, methyl-2-n-pentyl ketone and 2-heptanone; alcohols such as 3-methoxybutanol, 3-methyl-3-methoxybutanol, 1-methoxy-2-propanol, 1-ethoxy-2-propanol and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate and propylene glycol mono-tert-butyl ether acetate; and lactones such as γ-butyrolactone, which may be used alone or in admixture.

The organic solvent is preferably added to the resist composition of the present invention in an amount of 100 to 10,000 parts by weight, and more preferably 200 to 8,000 parts by weight per 100 parts by weight of the base polymer. The organic solvent may be used alone or as a mixture of two or more kinds thereof.

### [Quencher]

The resist composition may further comprise a quencher. As used herein, the “quencher” refers to a compound capable of trapping the acid generated from the acid generator for thereby preventing the acid from diffusing to the unexposed region.

The quencher is typically selected from conventional basic compounds. Conventional basic compounds include primary, secondary, and tertiary aliphatic amines, mixed amines, aromatic amines, heterocyclic amines, nitrogen-containing compounds with carboxy group, nitrogen-containing compounds with sulfonyl group, nitrogen-containing compounds with hydroxy group, nitrogen-containing compounds with hydroxyphenyl group, alcoholic nitrogen-containing compounds, amide derivatives, imide derivatives, and carbamate derivatives. Also included are primary, secondary, and tertiary amine compounds, specifically amine compounds having a hydroxy, ether bond, ester bond, lactone ring, cyano, or sulfonic ester bond as described in JP-A 2008-111103, paragraphs [0146]-[0164], and compounds having a carbamate bond as described in JP 3790649. Addition of a basic compound may be effective for further suppressing the diffusion rate of acid in the resist film or correcting the pattern profile.

Suitable quenchers also include onium salts such as sulfonium salts, iodonium salts and ammonium salts of sulfonic acids which are not fluorinated at α-position, carboxylic acids or fluorinated alkoxides, as described in JP-A 2008-158339. While an α-fluorinated sulfonic acid, imide acid, and methide acid are necessary to deprotect the acid labile group of carboxylic acid ester, an α-non-fluorinated sulfonic acid, carboxylic acid or fluorinated alcohol is released by salt exchange with the onium salt. The α-non-fluorinated sulfonic acid, carboxylic acid and fluorinated alcohol function as a quencher because they do not induce deprotection reaction.

Exemplary such quenchers include a compound (onium salt of α-non-fluorinated sulfonic acid) having the formula (4), a compound (onium salt of carboxylic acid) having the formula (5), and a compound (onium salt of alkoxide) having the formula (6).

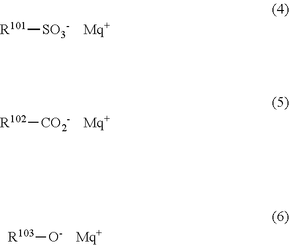

In formula (4), R¹⁰¹ is hydrogen or a C₁-C₄₀ hydrocarbyl group which may contain a heteroatom, exclusive of the hydrocarbyl group in which the hydrogen bonded to the carbon atom at α-position of the sulfo group is substituted by fluorine or fluoroalkyl moiety.

The C₁-C₄₀ hydrocarbyl group may be saturated or unsaturated and straight, branched or cyclic. Examples thereof include C₁-C₄₀ alkyl groups such as methyl, ethyl, n-propyl, isopropyl, n-butyl, sec-butyl, tert-butyl, n-pentyl, tert-pentyl, n-hexyl, n-octyl, 2-ethylhexyl, n-nonyl, n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}] decyl, adamantyl, and adamantylmethyl; C₂-C₄₀ alkenyl groups such as vinyl, allyl, propenyl, butenyl and hexenyl; C₃-C₄₀ cyclic unsaturated aliphatic hydrocarbyl groups such as cyclohexenyl; C₆-C₄₀ aryl groups such as phenyl, naphthyl, alkylphenyl groups (e.g., 2-methylphenyl, 3-methylphenyl, 4-methylphenyl, 4-ethylphenyl, 4-tert-butylphenyl, 4-n-butylphenyl), di- or tri-alkylphenyl groups (e.g., 2,4-dimethylphenyl and 2,4,6-triisopropylphenyl), alkylnaphthyl groups (e.g., methylnaphthyl and ethylnaphthyl), dialkylnaphthyl groups (e.g., dimethylnaphthyl and diethylnaphthyl); and C₇-C₄₀ aralkyl groups such as benzyl, 1-phenylethyl and 2-phenylethyl.

In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety. Examples of heteroatom-containing hydrocarbyl groups include heteroaryl groups such as thienyl, 4-hydroxyphenyl, alkoxyphenyl groups such as 4-methoxyphenyl, 3-methoxyphenyl, 2-methoxyphenyl, 4-ethoxyphenyl, 4-tert-butoxyphenyl, 3-tert-butoxyphenyl; alkoxynaphthyl groups such as methoxynaphthyl, ethoxynaphthyl, n-propoxynaphthyl and n-butoxynaphthyl; dialkoxynaphthyl groups such as dimethoxynaphthyl and diethoxynaphthyl; and aryloxoalkyl groups, typically 2-aryl-2-oxoethyl groups such as 2-phenyl-2-oxoethyl, 2-(1-naphthyl)-2-oxoethyl and 2-(2-naphthyl)-2-oxoethyl.

In formula (5), R¹⁰² is a C₁-C₄₀ hydrocarbyl group which may contain a heteroatom. Examples of the hydrocarbyl group R¹⁰² are as exemplified above for the hydrocarbyl group R¹⁰¹. Also included are fluorinated alkyl groups such as trifluoromethyl, trifluoroethyl, 2,2,2-trifluoro-1-methyl-1-hydroxyethyl, 2,2,2-trifluoro-1-(trifluoromethyl)-1-hydroxyethyl, and fluorinated aryl groups such as pentafluorophenyl and 4-trifluoromethylphenyl.

In formula (6), R¹⁰³ is a C₁-C₈ saturated hydrocarbyl group containing at least 3 fluorine atoms or a C₆-C₁₀ aryl group containing at least 3 fluorine atoms, the hydrocarbyl and aryl groups optionally having a nitro moiety.

In formulae (4), (5) and (6), Mq⁺ is an onium cation. The onium cation is preferably a sulfonium, iodonium or ammonium cation, with the sulfonium cation being more preferred. Examples of the sulfonium cation are as exemplified for the sulfonium cation represented by M⁺ in the description of formula (1).

A sulfonium salt of iodized benzene ring-containing carboxylic acid having the formula (7) is also useful as the quencher.

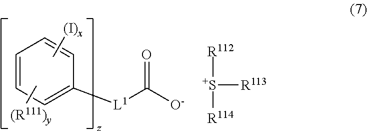

In formula (7), x is an integer of 1 to 5. y is an integer of 0 to 3. z is an integer of 1 to 3.

In formula (7), R¹¹¹ is hydroxy, fluorine, chlorine, bromine, amino, nitro, cyano, or a C₁-C₆ saturated hydrocarbyl, C₁-C₆ saturated hydrocarbyloxy, C₂-C₆ saturated hydrocarbylcarbonyloxy, or C₁-C₄ saturated hydrocarbylsulfonyloxy group, in which some or all hydrogen atoms may be substituted by halogen atom, or —N(R^{111A})—C(═O)—R^{111B}, or —N(R^{111A})—C(═O)—O—R^{111B}. X^{111A} is a hydrogen atom or a C₁-C₆ saturated hydrocarbyl group. R^{111B} is a C₁-C₆ saturated hydrocarbyl group, or a C₂-C₈ unsaturated hydrocarbyl group. Groups R¹¹¹ may be identical or different when y and/or z is 2 or more.

In formula (7), L1 is a single bond, or a C₁-C₂₀ (z+1)-valent linking group which may contain an ether bond, carbonyl, ester bond, amide bond, sultone ring, lactam ring, carbonate bond, halogen atom, hydroxy or carboxy moiety or a mixture thereof. The saturated hydrocarbyl, saturated hydrocarbyloxy, saturated hydrocarbylcarbonyloxy and saturated hydrocarbylsulfonyloxy groups may be straight, branched or cyclic.

In formula (7), R¹¹², R¹¹³ and R¹¹⁴ are each independently halogen atom or a C₁-C₂₀ hydrocarbyl group which may contain a heteroatom. The hydrocarbyl group may be saturated or unsaturated and straight, branched or cyclic. Examples of thereof are as exemplified above as hydrocarbyl groups R⁴ to R⁸ in formulae (2) and (3).

Examples of the compound having formula (7) include those described in U.S. Pat. No. 10,295,904 (JP-A 2017-219836) and US20210188770 (JP-A 2021-91666).

Also useful are quenchers of polymer type as described in U.S. Pat. No. 7,598,016 (JP-A 2008-239918). The polymeric quencher segregates at the resist film surface and thus enhances the rectangularity of resist pattern. When a protective film is applied as is often the case in the immersion lithography, the polymeric quencher is also effective for preventing a film thickness loss of resist pattern or rounding of pattern top.

Other useful quenchers include sulfonium salts of betaine structure as described in JP 6848776 and JP-A 2020-37544, fluorine-free methide acids as described in JP-A 2020-55797, sulfonium salts of sulfonamide as described in JP 5807552, sulfonium salts of iodized sulfonamide as described in JP-A 2019-211751, phenol, halogen, and acid generators that generate carbonic acid.

The quencher is preferably added in an amount of 0 to 5 parts, more preferably 0 to 4 parts by weight per 100 parts by weight of the base polymer. The quencher may be used alone or in admixture.

### [Other Components]

In addition to the foregoing components, the resist composition may contain other components such as an acid generator other than the salt having formula (1) (hereinafter, an acid generator is also referred to as the other acid generator), surfactant, dissolution inhibitor, crosslinker, water repellency improver and acetylene alcohol.

The other acid generator is typically a compound (PAG) capable of generating an acid upon exposure to actinic ray or radiation. Although the PAG used herein may be any compound capable of generating an acid upon exposure to high-energy radiation, those compounds capable of generating sulfonic acid, imide acid (imidic acid) or methide acid are preferred. Suitable PAGs include sulfonium salts, iodonium salts, sulfonyldiazomethane, N-sulfonyloxyimide, and oxime-O-sulfonate acid generators. Exemplary PAGs are described in JP-A 2008-111103, paragraphs [0122]-[0142] (U.S. Pat. No. 7,537,880), JP-A 2018-5224, and JP-A 2018-25789. The other acid generator is preferably used in an amount of 0 to 200 parts, more preferably 0.1 to 100 parts by weight per 100 parts by weight of the base polymer.

Exemplary surfactants are described in JP-A 2008-111103, paragraphs [0165]-[0166]. Inclusion of a surfactant may improve or control the coating characteristics of the resist composition. The surfactant is preferably added in an amount of 0.0001 to 10 parts by weight per 100 parts by weight of the base polymer. The surfactant may be used alone or in admixture.

The inclusion of a dissolution inhibitor in the positive resist composition of the present invention may lead to an increased difference in dissolution rate between exposed and unexposed areas and a further improvement in resolution. Examples of the dissolution inhibitor include a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in U.S. Pat. No. 7,771,914 (JP-A 2008-122932, paragraphs [0155]-[0178]).

The dissolution inhibitor is preferably added in an amount of 0 to 50 parts, more preferably 5 to 40 parts by weight per 100 parts by weight of the base polymer. In the case of negative resist compositions, a negative pattern may be formed by adding a crosslinker to reduce the dissolution rate of exposed area.

In the case of negative resist compositions, a negative pattern may be formed by adding a crosslinker to reduce the dissolution rate of exposed area. Examples of the crosslinker include epoxy compounds, melamine compounds, guanamine compounds, glycoluril compounds and urea compounds having substituted thereon at least one group selected from among methylol, alkoxymethyl and acyloxymethyl groups, isocyanate compounds, azide compounds, and compounds having a double bond such as an alkenyloxy group. These compounds may be used as an additive or introduced into a polymer side chain as a pendant. Hydroxy-containing compounds may also be used as the crosslinker.

Examples of the epoxy compound include tris(2,3-epoxypropyl) isocyanurate, trimethylolmethane triglycidyl ether, trimethylolpropane triglycidyl ether, and triethylolethane triglycidyl ether.

Examples of the melamine compound include hexamethylol melamine, hexamethoxymethyl melamine, hexamethylol melamine compounds having 1 to 6 methylol groups methoxymethylated and mixtures thereof, hexamethoxyethyl melamine, hexaacyloxymethyl melamine, hexamethylol melamine compounds having 1 to 6 methylol groups acyloxymethylated and mixtures thereof.

Examples of the guanamine compound include tetramethylol guanamine, tetramethoxymethyl guanamine, tetramethylol guanamine compounds having 1 to 4 methylol groups methoxymethylated and mixtures thereof, tetramethoxyethyl guanamine, tetraacyloxyguanamine, tetramethylol guanamine compounds having 1 to 4 methylol groups acyloxymethylated and mixtures thereof.

Examples of the glycoluril compound include tetramethylol glycoluril, tetramethoxyglycoluril, tetramethoxymethyl glycoluril, tetramethylol glycoluril compounds having 1 to 4 methylol groups methoxymethylated and mixtures thereof, tetramethylol glycoluril compounds having 1 to 4 methylol groups acyloxymethylated and mixtures thereof. Examples of the urea compound include tetramethylol urea, tetramethoxymethyl urea, tetramethylol urea compounds having 1 to 4 methylol groups methoxymethylated and mixtures thereof, and tetramethoxyethyl urea.

Examples of the isocyanate compound include tolylene diisocyanate, diphenylmethane diisocyanate, hexamethylene diisocyanate and cyclohexane diisocyanate.

Examples of the azide compound include 1,1′-biphenyl-4,4′-bisazide, 4,4′-methylidenebisazide, and 4,4′-oxybisazide.

Examples of the alkenyl ether group-containing compound include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylol propane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylol propane trivinyl ether.

In the negative resist composition, the crosslinker is preferably added in an amount of 0.1 to 50 parts, more preferably 1 to 40 parts by weight per 100 parts by weight of the base polymer. To the resist composition, a water repellency improver may also be added for improving the water repellency on surface of a resist film.

The water repellency improver may be used in the topcoatless immersion lithography. Suitable water repellency improvers include polymers having a fluoroalkyl group and polymers having a specific structure with a 1,1,1,3,3,3-hexafluoro-2-propanol residue and are described in JP-A 2007-297590 and JP-A 2008-111103, for example. The water repellency improver to be added to the resist composition should be soluble in alkaline developers and organic solvent developers. The water repellency improver of specific structure with a 1,1,1,3,3,3-hexafluoro-2-propanol residue is well soluble in the developer. A polymer having an amino group or amine salt copolymerized as repeat units may serve as the water repellent additive and is effective for preventing evaporation of acid during PEB, thus preventing any hole pattern opening failure after development. An appropriate amount of the water repellency improver is 0 to 20 parts, preferably 0.5 to 10 parts by weight per 100 parts by weight of the base polymer. Also, an acetylene alcohol may be blended in the resist composition.

Specific examples of the acetylene alcohol include those described in paragraphs [0179]-[0182] of JP-A 2008-122932. The acetylene alcohol is preferably added to the resist composition of the present invention in an amount of 0 to 5 parts by weight per 100 parts by weight of the base polymer. The acetylene alcohol may be used alone or in combination of two or more kinds thereof.

### [Process]

The resist composition is used in the fabrication of various integrated circuits. Examples of the pattern forming process include a process including the steps of: applying the above-described resist composition onto a substrate to form a resist film on the substrate, exposing the resist film to high-energy radiation, and developing the exposed resist film in a developer.

The inventive resist composition is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying or doctor coating. The resulting resist film is generally 0.01 to 2 μm thick. The coating is prebaked on a hotplate preferably at a temperature of 60 to 150° C. for 10 seconds to 30 minutes, more preferably at 80 to 120° C. for 30 seconds to 20 minutes.

The resulting resist film is generally 0.01 to 2 μm thick. Specific examples of the high-energy radiation include UV, deep-UV, EB, EUV of wavelength 3-15 nm, i-line, x-ray, soft x-ray, excimer laser light, γ-ray or synchrotron radiation. When UV, deep-UV, EUV, X-rays, soft X-rays, excimer laser, γ-rays, or synchrotron radiation is used as the high-energy radiation, the resist film is exposed thereto directly or through a mask having a desired pattern preferably at a dose of about 1 to 200 mJ/cm², and more preferably about 10 to 100 mJ/cm². When EB is used as the high-energy radiation, the resist film is exposed thereto directly or through a mask having a desired pattern preferably at a dose of about 0.1 to 300 μC/cm², and more preferably about 0.5 to 200 μC/cm². It is appreciated that the inventive resist composition is suited in micropatterning using KrF excimer laser, ArF excimer laser, EB, EUV, x-ray, soft x-ray, γ-ray or synchrotron radiation, especially in micropatterning using EB or EUV.

After the exposure, the resist film may be baked (PEB) on a hotplate or in an oven preferably at 30 to 150° C. for 10 seconds to 30 minutes, more preferably at 50 to 120° C. for 30 seconds to 20 minutes.

After the exposure or PEB, the resist film is developed in a developer in the form of an aqueous base solution for 3 seconds to 3 minutes, preferably 5 seconds to 2 minutes by conventional techniques such as dip, puddle and spray techniques. A typical developer is a 0.1 to 10 wt %, preferably 2 to 5 wt % aqueous solution of tetramethylammonium hydroxide (TMAH), tetraethylammonium hydroxide, tetrapropylammonium hydroxide, or tetrabutylammonium hydroxide. In the case of positive tone, the resist film in the exposed area is dissolved in the developer whereas the resist film in the unexposed area is not dissolved. In this way, the desired positive pattern is formed on the substrate. In the case of negative tone, inversely the resist film in the exposed area is insolubilized whereas the resist film in the unexposed area is dissolved away.

In an alternative embodiment, a negative pattern can be obtained from the positive resist composition comprising a base polymer containing acid labile groups by effecting organic solvent development. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvents may be used alone or in admixture.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the C₆-C₁₂ alkene include hexene, heptene, octene, cyclohexene, methylcyclohexene, dimethylcyclohexene, cycloheptene, and cyclooctene. Examples of the C₆-C₁₂ alkyne include hexyne, heptyne, and octyne.

Examples of the aromatic solvent include toluene, xylene, ethylbenzene, isopropylbenzene, tert-butylbenzene and mesitylene.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation.

Acid generator and quenchers PAG-PDQ-1 to PAG-PDQ-15 in the form of bisonium salts used in resist compositions have the structure shown below.

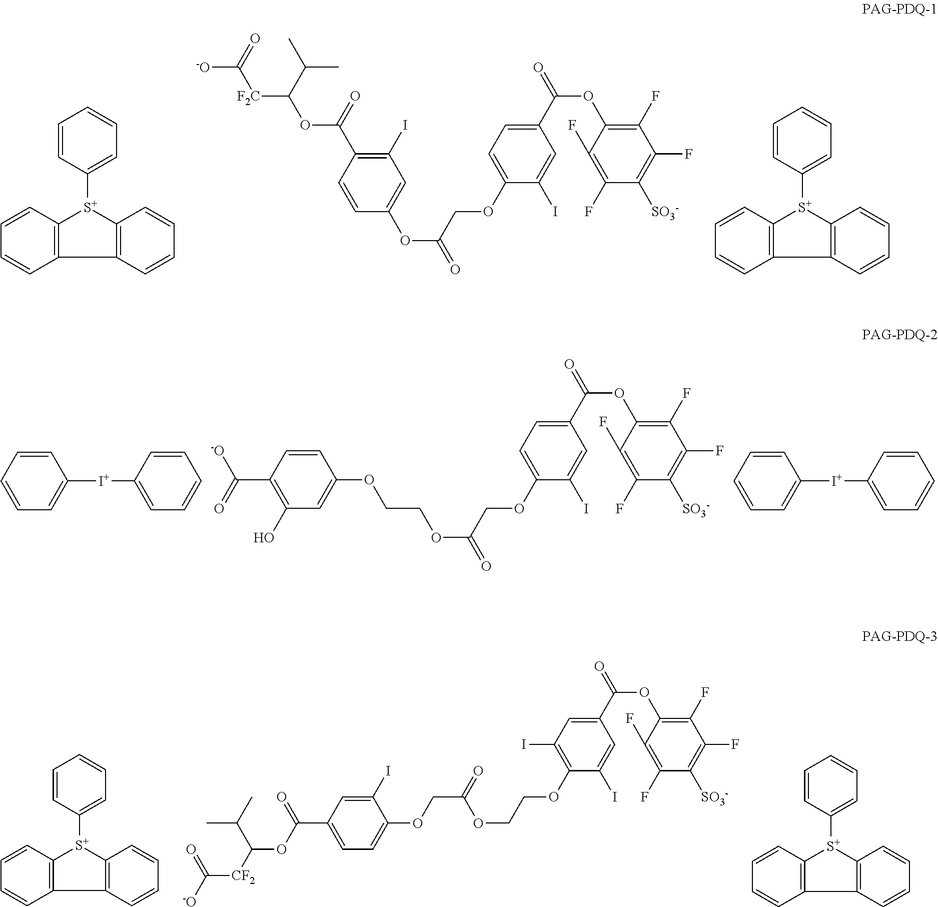

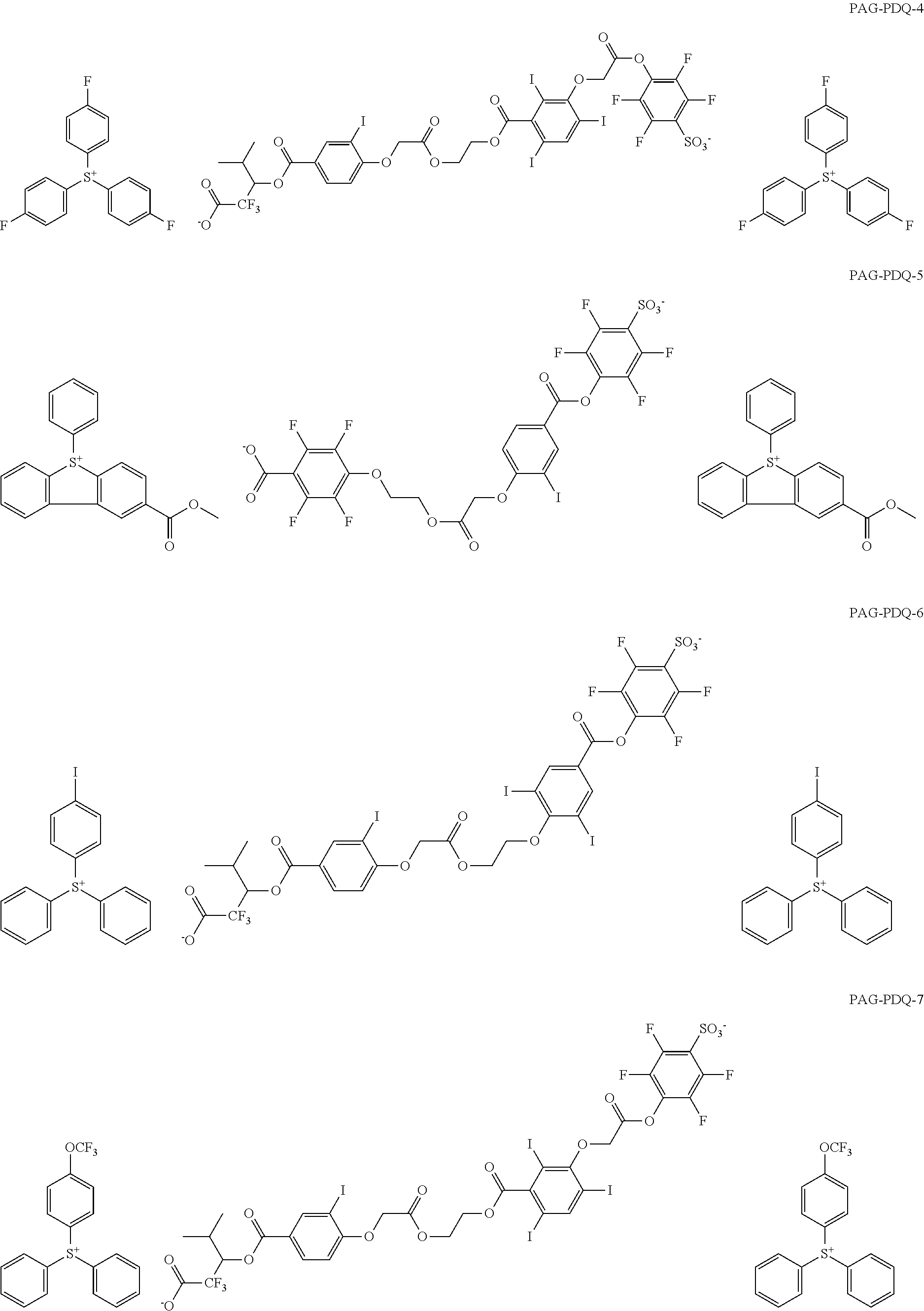

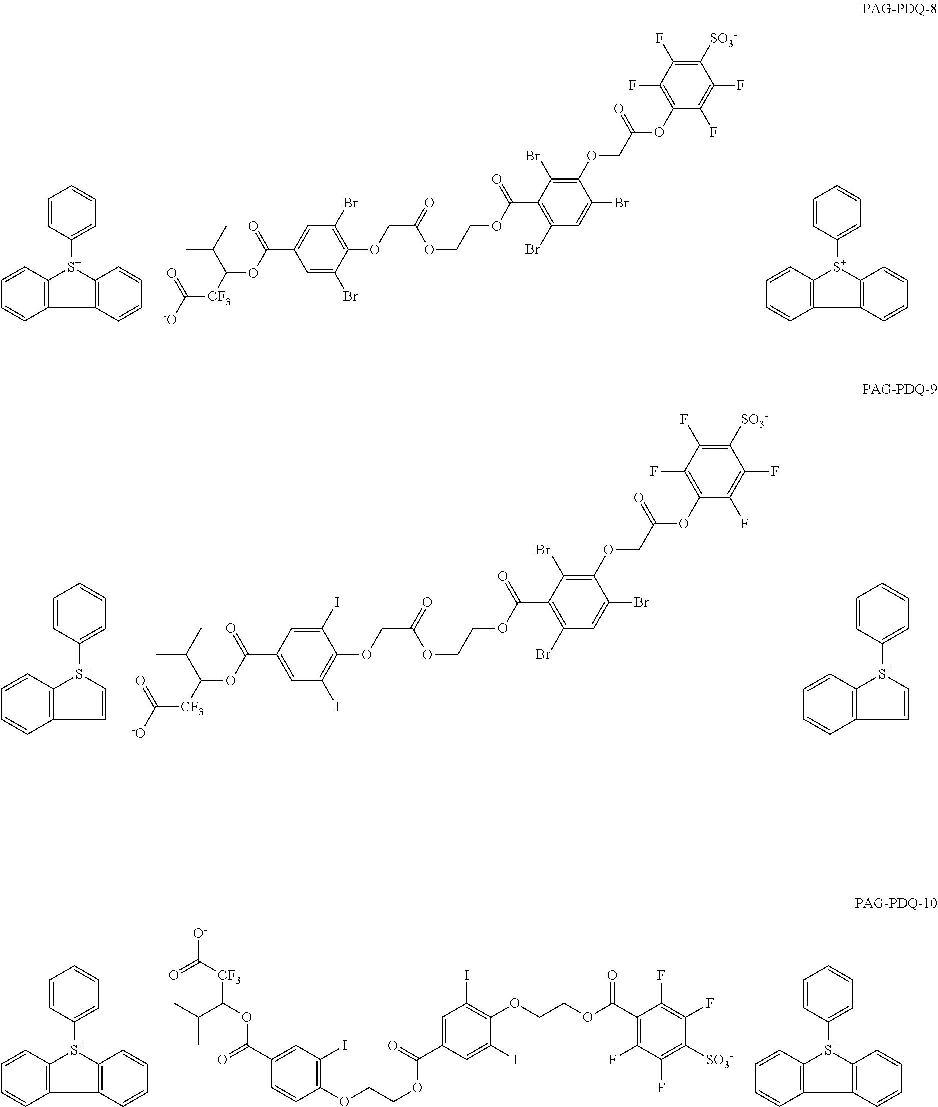

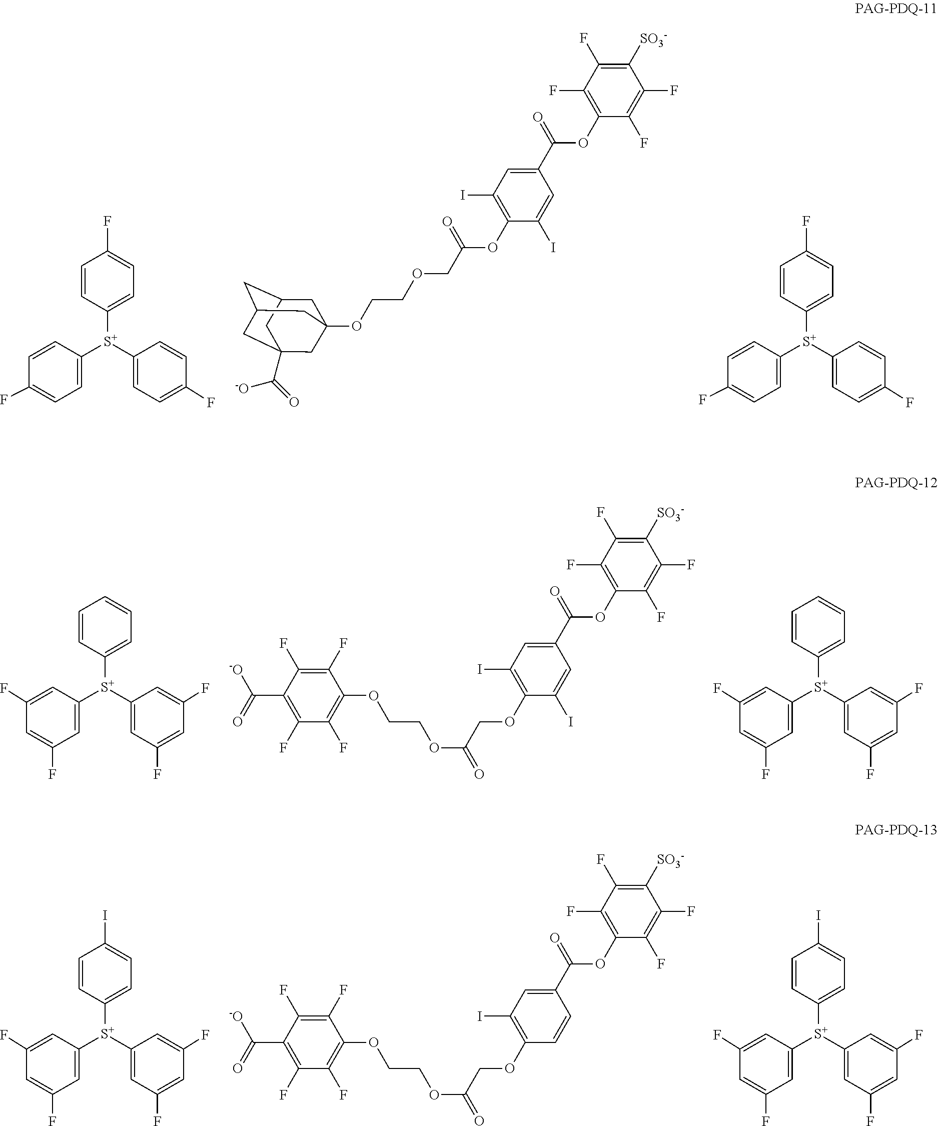

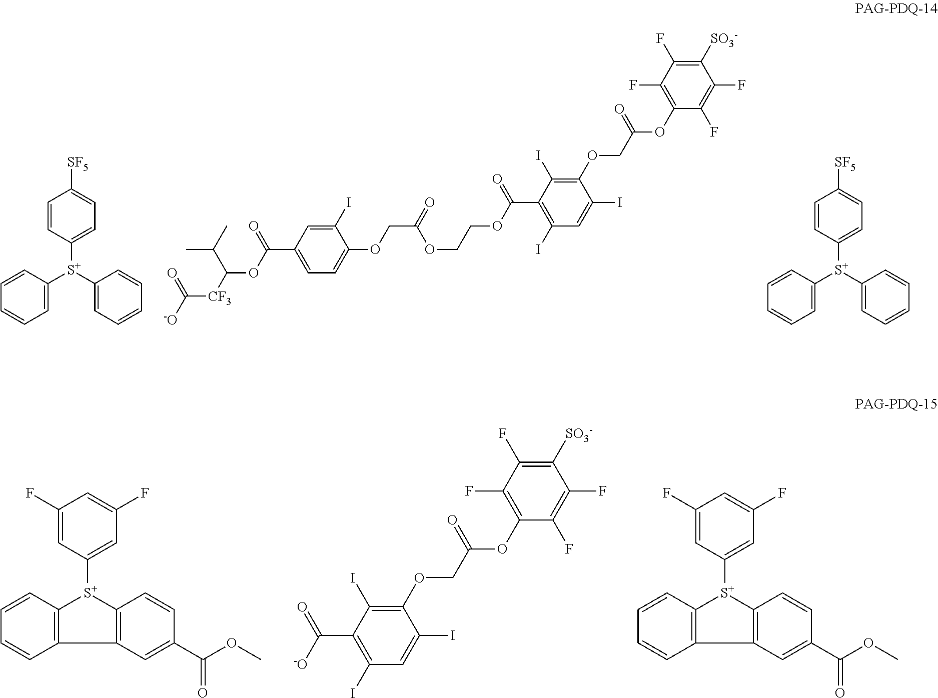

### [Synthesis Example] Synthesis of Base Polymer (Polymers P-1 to P-4)

Base polymers (Polymers P-1 to P-4) of the structure shown below were synthesized by combining selected monomers, effecting copolymerization reaction in THF solvent, pouring the reaction solution into methanol, washing the solid precipitate with hexane, isolating, and drying. The base polymers were analyzed for composition by 1H-NMR spectroscopy and for Mw and Mw/Mn by GPC versus polystyrene standards using THE solvent.

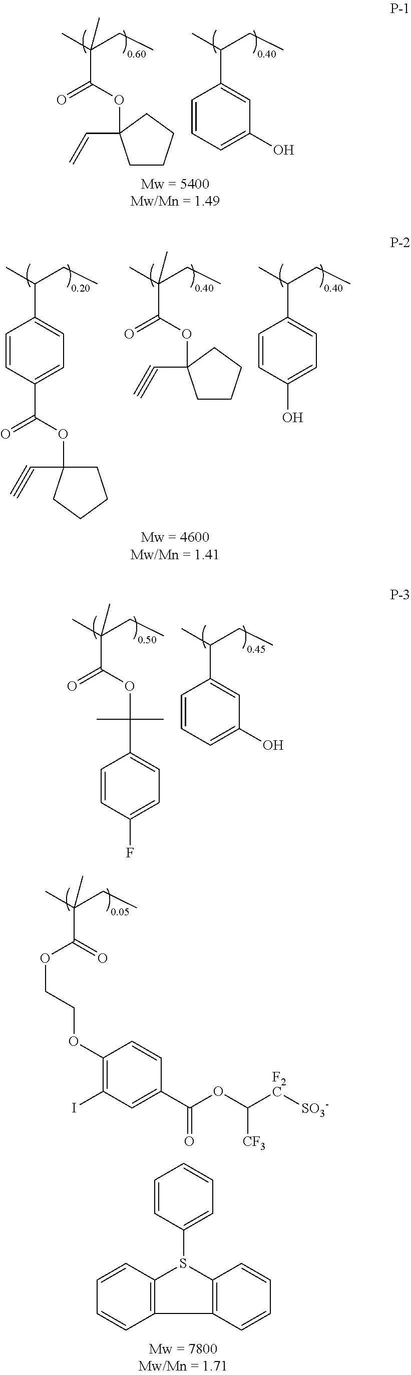

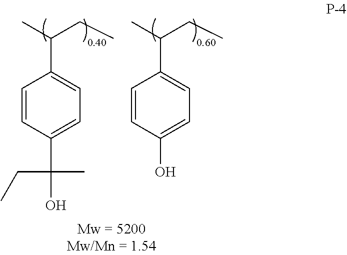

### [Examples 1 to 21 and Comparative Examples 1 to 3] Preparation and Evaluation of Resist Compositions

### (1) Preparation of Resist Compositions

A solution obtained by dissolving the components according to the composition shown in Table 1 was filtered through a filter with a pore size of 0.2 μm to prepare a resist composition.

The components in Table 1 are identified below.

### Organic Solvents:

PGMEA (propylene glycol monomethyl ether acetate)
EL (ethyl lactate)
DAA (diacetone alcohol)
Comparative acid generators: cPAG-1 to cPAG-PDQ-1

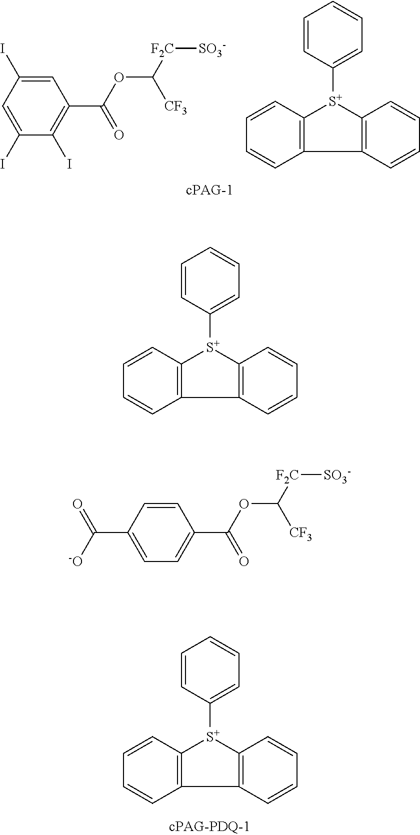

Blending acid generators: bPAG-1

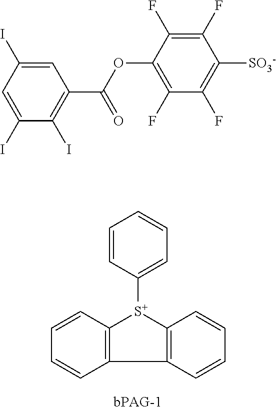

Comparative Quencher: cPDQ-1

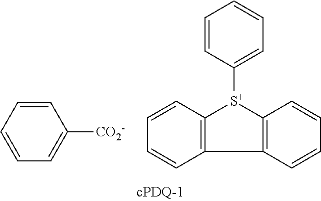

### (2) EUV Lithography Test

Each of the resist compositions in Table 1 was spin coated on a silicon substrate having a 20-nm coating of silicon-containing spin-on hard mask SHB-A940 (Shin-Etsu Chemical Co., Ltd., Si content 43 wt %) and prebaked on a hotplate at 105° C. for 60 seconds to form a resist film of 40 nm thick. Using an EUV scanner (NXE3400, ASML Holding N.V.) (NA 0.33, ˜ 0.9/0.7, dipole illumination), the resist film was exposed. The resist film was baked (PEB) on a hotplate at the temperature shown in Tables 1 for 60 seconds and developed in a 2.38 wt % TMAH aqueous solution for 30 seconds to form a line-and-space pattern having a pitch of 32 nm and a line width of 16 nm. The resist compositions of Examples 1 to 20 and Comparative Examples 1 and 2 were of positive tone, and the resist compositions of Example 21 and Comparative Example 3 were of negative tone.

The resist pattern was observed under CD-SEM (CG6300, Hitachi High-Technologies Corp.). The exposure dose that provides a line pattern having a size of 16 nm±1.6 nm is reported. The edge roughness (LWR) at this exposure dose was measured. The results are shown in Table 1.

TABLE 1

| | | Polymer | Additive | Organic solvent | PEB | Sensitivity | LWR |
|---|---|---|---|---|---|---|---|
| | | (pbw) | (pbw) | (pbw) | (° C.) | (mJ/cm²) | (nm) |
| Example | 1 | P-1 | PAG-PDQ-1 | PGMEA (500) | 85 | 43 | 2.3 |
| | | (100) | (21.8) | EL (2500) | | | |
| | 2 | P-1 | PAG-PDQ-2 | PGMEA (500) | 85 | 40 | 2.6 |
| | | (100) | (19.4) | EL (2500) | | | |
| | 3 | P-1 | PAG-PDQ-3 | PGMEA (500) | 85 | 41 | 2.4 |
| | | (100) | (24.5) | EL (2500) | | | |
| | 4 | P-1 | PAG-PDQ-4 | PGMEA (2500) | 85 | 43 | 2.4 |
| | | (100) | (29.0) | DAA (500) | | | |
| | 5 | P-1 | PAG-PDQ-5 | PGMEA (2500) | 85 | 44 | 2.5 |
| | | (100) | (22.9) | DAA (500) | | | |
| | 6 | P-1 | PAG-PDQ-6 | PGMEA (2500) | 85 | 41 | 2.3 |
| | | (100) | (30.0) | DAA (500) | | | |
| | 7 | P-1 | PAG-PDQ-7 | PGMEA (2500) | 85 | 39 | 2.5 |
| | | (100) | (29.9) | DAA (500) | | | |
| | 8 | P-1 | PAG-PDQ-8 | PGMEA (2500) | 85 | 40 | 2.3 |
| | | (100) | (27.3) | DAA (500) | | | |
| | 9 | P-1 | PAG-PDQ-9 | PGMEA (2500) | 85 | 43 | 2.3 |
| | | (100) | (27.2) | DAA (500) | | | |
| | 10 | P-1 | PAG-PDQ-10 | PGMEA (2500) | 85 | 42 | 2.3 |
| | | (100) | (24.8) | DAA (500) | | | |
| | 11 | P-1 | PAG-PDQ-11 | PGMEA (2500) | 85 | 43 | 2.4 |
| | | (100) | (24.6) | DAA (500) | | | |
| | 12 | P-1 | PAG-PDQ-12 | PGMEA (2500) | 85 | 43 | 2.4 |
| | | (100) | (23.7) | DAA (500) | | | |
| | 13 | P-1 | PAG-PDQ-13 | PGMEA (2500) | 85 | 42 | 2.5 |
| | | (100) | (25.6) | DAA (500) | | | |
| | 14 | P-1 | PAG-PDQ-14 | PGMEA (2500) | 85 | 43 | 2.4 |
| | | (100) | (31.2) | DAA (500) | | | |
| | 15 | P-1 | PAG-PDQ-15 | PGMEA (2500) | 85 | 45 | 2.3 |
| | | (100) | (30.2) | DAA (500) | | | |
| | 16 | P-1 | PAG-PDQ-2 (19.4) | PGMEA (500) | 85 | 37 | 2.8 |
| | | (100) | cPAG-1 (1.5) | EL (2500) | | | |
| | 17 | P-1 | PAG-PDQ-2 (19.4) | PGMEA (500) | 85 | 42 | 2.6 |
| | | (100) | cPDQ-1 (1.2) | EL (2500) | | | |
| | 18 | P-1 | PAG-PDQ-2 (19.4) | PGMEA (500) | 85 | 38 | 2.6 |
| | | (100) | bPAG-1 (1.6) | EL (2500) | | | |
| | 19 | P-2 | PAG-PDQ-1 | PGMEA (2500) | 85 | 43 | 2.6 |
| | | (100) | (21.8) | DAA (500) | | | |
| | 20 | P-3 | PAG-PDQ-1 | PGMEA (2500) | 90 | 33 | 2.5 |
| | | (100) | (21.8) | DAA (500) | | | |
| | 21 | P-4 | PAG-PDQ-1 | PGMEA (2500) | 125 | 45 | 3.7 |
| | | (100) | (21.8) | DAA (500) | | | |
| Comparative | 1 | P-1 | cPAG-1 (14.5) | PGMEA (2500) | 85 | 45 | 3.2 |
| Example | | (100) | cPDQ-1 (5.7) | DAA (500) | | | |
| | 2 | P-1 | cPAG-PDQ-1 | PGMEA (1000) | 85 | 46 | 3.4 |
| | | (100) | (13.5) | DAA (500) | | | |
| | | | | EL (1500) | | | |
| | 3 | P-4 | cPAG-1 (14.5) | PGMEA (2500) | 120 | 50 | 4.6 |
| | | (100) | cPDQ-1 (5.7) | DAA (500) | | | |

It is demonstrated in Table 1 that the inventive resist compositions comprising a bisonium salt containing a divalent anion having an arylsulfonate anion structure linked to an aromatic group having an iodine atom or a bromine atom and a carboxylate anion structure bonded to the aromatic group having an iodine atom or a bromine atom, via a linking group having 1 or more carbon atoms, and an onium cation have a high sensitivity, and good LWR.

Japanese Patent Application No. 2023-175361 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a bisonium salt containing a divalent anion having an arylsulfonate anion structure linked to an aromatic group having an iodine atom or a bromine atom and a carboxylate anion structure bonded to the aromatic group having an iodine atom or a bromine atom, via a linking group having 1 or more carbon atoms, and an onium cation.

2. The resist composition of claim 1, wherein the bisonium salt has the formula 1: 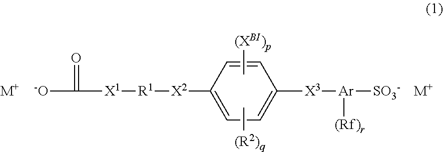
wherein p is an integer of 1 to 4, q is an integer of 0 to 3, r is an integer of 1 to 6,
X^{BI} is a bromine atom or an iodine atom,
X¹ is a C₁-C₁₈ hydrocarbylene group, which may contain at least one selected from an oxygen atom, a nitrogen atom, a sulfur atom and a halogen atom,
X² is a single bond, an ether bond, an ester bond, a sulfonic acid ester bond, an amide bond, a urethane bond, a urea bond, or a carbonate bond or a C₁-C₆ alkanediyl group, the alkanediyl group may contain at least one selected from an ether bond and an ester bond,
X³ is a single bond, an ether bond, an ester bond, or a C₁-C₆ alkanediyl group, the alkanediyl group may contain at least one selected from an ether bond and an ester bond,
R¹ is a single bond or a C₁-C₁₂ hydrocarbylene group, the hydrocarbylene group may contain at least one selected from an oxygen atom, a nitrogen atom, a sulfur atom and a halogen atom,
with the proviso that —X¹—R¹—X²— has at least one carbon atom,
R² is a hydroxy group, a carboxy group, a fluorine atom, a chlorine atom, an amino group, a C₁-C₂₀ hydrocarbyl group, a C₁-C₂₀ hydrocarbyloxy group, a C₂-C₂₀ hydrocarbyloxycarbonyl group, a C₂-C₂₀ hydrocarbylcarbonyloxy group, —N(R^{2A})—C(═O)—R^{2B}, —N(R^{2A})—C(═O)—O—R^{2B} or —N(R^{2A})—S(═O)₂—R^{2B}, and the hydrocarbyl group, the hydrocarbyloxy group, the hydrocarbyloxycarbonyl group and the hydrocarbylcarbonyloxy group may contain at least one selected from a fluorine atom, a chlorine atom, a bromine atom, an iodine atom, a hydroxy group, an amino group, an ester bond and an ether bond,
R^{2A} is a hydrogen atom, or a C₁-C₆ saturated hydrocarbyl group, the saturated hydrocarbyl group may contain a halogen atom, a hydroxy group, a C₁-C₆ saturated hydrocarbyloxy group, a C₂-C₆ saturated hydrocarbylcarbonyl group or a C₂-C₆ saturated hydrocarbylcarbonyloxy group,
R^{2B} is a C₁-C₁₆ aliphatic hydrocarbyl group or a C₆-C₁₂ aryl group, which may contain a halogen atom, a hydroxy group, a C₁-C₆ saturated hydrocarbyloxy group, a C₂-C₆ saturated hydrocarbylcarbonyl group or a C₂-C₆ saturated hydrocarbylcarbonyloxy group,
Ar is a C₆-C₁₀ (r+2)-valent aromatic hydrocarbon group,
Rf is a hydrogen atom, a C₁-C₁₀ saturated hydrocarbyl group, a nitro group, a cyano group, a fluorine atom, an iodine atom, a trifluoromethyl group or a trifluoromethoxy group, and
M⁺ is a sulfonium cation or an iodonium cation.

3. The resist composition of claim 2, wherein X¹ is a C₁-C₁₈ hydrocarbylene group containing an iodine atom or a bromine atom.

4. The resist composition of claim 1, further comprising a base polymer.

5. The resist composition of claim 4, wherein the base polymer comprises repeat units having the formula (a1) or (a2): 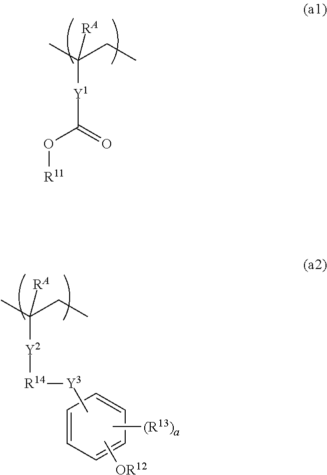
wherein R^{A} is each independently hydrogen or methyl,
Y¹ is a single bond, a phenylene group, a naphthylene group, or a C₁-C₁₂ linking group containing at least one selected from an ester bond, an ether bond and a lactone ring, the phenylene group, the naphthylene group and the linking group may have at least one selected from a hydroxy group, a C₁-C₈ saturated hydrocarbyloxy group and a C₂-C₈ saturated hydrocarbylcarbonyloxy group,
Y² is a single bond or an ester bond,
Y³ is a single bond, an ether bond or an ester bond,
R¹¹ and R¹² are each independently an acid labile group,
R¹³ is a C₁-C₄ saturated hydrocarbyl group, a halogen atom, a C₂-C₅ saturated hydrocarbylcarbonyl group, a cyano group, or C₂-C₅ saturated hydrocarbyloxycarbonyl group,
R¹⁴ is a single bond or a C₁-C₆ alkanediyl group, the alkanediyl group may contain an ether bond or an ester bond, and
a is an integer of 0 to 4.

6. The resist composition of claim 5 which is a chemically amplified positive resist composition.

7. The resist composition of claim 4, wherein the base polymer does not contain an acid labile group.

8. The resist composition of claim 7 which is a chemically amplified negative resist composition.

9. The resist composition of claim 1, further comprising an organic solvent.

10. The resist composition of claim 1, further comprising a quencher.

11. The resist composition of claim 1, further comprising an acid generator.

12. The resist composition of claim 1, further comprising a surfactant.

13. A pattern forming process comprising the steps of applying the resist composition of claim 1 onto a substrate to form a resist film thereon, exposing the resist film to high-energy radiation, and developing the exposed resist film in a developer.

14. The pattern forming process of claim 13, wherein the high-energy radiation is ArF excimer laser having a wavelength 193 nm, KrF excimer laser having a wavelength 248 nm, an electron beam, or EUV having a wavelength 3 to 15 nm.
